(19) United States
(12) Patent Application Publication
(10) Pub. No.: US 2025/0204170 A1
(43) Pub. Date: Jun. 19, 2025

(54) DISPLAY PANEL AND PREPARATION METHOD FOR DISPLAY PANEL

(71) Applicants: Hefei Visionox Technology Co., Ltd., Hefei (CN); Visionox Technology Inc., Jiangsu (CN)

(72) Inventors: Yuan YAO, Hefei (CN); Aihua XUE, Hefei (CN); Yuting FU, Hefei (CN); Tianchao ZHANG, Hefei (CN); Yongzhong ZHANG, Hefei (CN)

(73) Assignees: Hefei Visionox Technology Co., Ltd., Hefei (CN); Visionox Technology Inc., Jiangsu (CN)

(21) Appl. No.: 19/063,555

(22) Filed: Feb. 26, 2025

Related U.S. Application Data
(63) Continuation of application No. PCT/CN2024/100935, filed on Jun. 24, 2024.

(30) Foreign Application Priority Data
Jul. 28, 2023 (CN) 202310944339.6
Dec. 15, 2023 (CN) 202311733473.8
Mar. 27, 2024 (CN) 202410364325.1

(51) Int. Cl. H10K 59/122; H10K 59/12; H10K 59/80

(52) U.S. Cl. CPC H10K 59/122; H10K 59/1201; H10K 59/873

(57) ABSTRACT

A display panel, a preparation method for a display panel, and a display device. The display panel includes: a substrate; an isolation structure disposed on a side of the substrate and enclosing and forming isolation openings, the isolation structure including a first isolation portion and a second isolation portion, the second isolation portion having a protruding portion protruding from the first isolation portion towards the isolation opening; light emitting devices, at least a part of a structure of the light emitting device is located within the isolation opening; a first encapsulation structure disposed on a side of the light emitting device away from the substrate, the first encapsulation structure including a first sub-portion, a second sub-portion and a third sub-portion.

### CROSS-REFERENCE TO RELATED APPLICATION

The present application is a continuation of International Patent Application No. PCT/CN2024/100935, filed on Jun. 24, 2024, and titled “DISPLAY PANEL, PREPARATION METHOD FOR DISPLAY PANEL, AND DISPLAY DEVICE”, which claims priority to Chinese Patent Application No. 202410364325.1, filed on Mar. 27, 2024, and titled “DISPLAY PANEL AND DISPLAY DEVICE”, Chinese Patent Application No. 202311733473.8, filed on Dec. 15, 2023, and titled “DISPLAY PANEL, PREPARATION METHOD FOR DISPLAY PANEL, AND DISPLAY DEVICE”, and Chinese Patent Application No. 202310944339.6, filed on Jul. 28, 2023, and titled “DISPLAY PANEL AND DISPLAY DEVICE”, all of which are hereby incorporated by reference in their entireties.

### TECHNICAL FIELD

The present application relates to the technical field of display, and particularly to a display panel, and a preparation method for a display panel.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the performance of current OLED display products needs to be improved.

### SUMMARY

Embodiments of the present application provide a display panel, a preparation method for a display panel, and a display device, which are designed to enhance the encapsulation effect of the display panel.

Embodiments of a first aspect of the present application provide a display panel, including: a substrate; an isolation structure disposed on a side of the substrate and enclosing and forming a plurality of isolation openings, the isolation structure including a first isolation portion and a second isolation portion located on a side of the first isolation portion away from the substrate, the second isolation portion having a protruding portion protruding from the first isolation portion towards the isolation opening; a plurality of light emitting devices, at least a part of a structure of the light emitting device is located within the isolation opening; a first encapsulation structure disposed on a side of the light emitting device away from the substrate, the first encapsulation structure including a first sub-portion, a second sub-portion and a third sub-portion, the first sub-portion covering on the side of the light emitting device away from the substrate, the second sub-portion covering on a side of the first isolation portion facing the isolation opening, the third sub-portion being at least partially located on a side of the second isolation portion facing the substrate and being at least partially attached on the protruding portion, the first sub-portion, the second sub-portion and the third sub-portion enclosing and forming a gap space, and the third sub-portion being at least partially connected with the first sub-portion to form a connection portion.

The embodiments of the first aspect of the present application also provide a display panel, including: a substrate; an isolation structure disposed on a side of the substrate and enclosing and forming a plurality of isolation openings, the isolation structure including a first isolation portion and a second isolation portion located on a side of the first isolation portion away from the substrate, the second isolation portion having a protruding portion protruding from the first isolation portion towards the isolation opening; a plurality of light emitting devices, at least a part of a structure of the light emitting device is located within the isolation opening, the light emitting device including a light emitting unit and a first electrode located on a side of the light emitting unit away from the substrate; a first encapsulation structure disposed on a side of the light emitting device away from the substrate, the first encapsulation structure including a first sub-portion, a second sub-portion and a third sub-portion, the first sub-portion covering on the side of the light emitting device away from the substrate, the second sub-portion covering on a side of the first isolation portion facing the isolation opening, the third sub-portion being at least partially located on a side of the second isolation portion facing the substrate and being at least partially attached on the protruding portion, the first sub-portion, the second sub-portion and the third sub-portion enclosing and forming a gap space, and the first sub-portion and the third sub-portion in at least a part of the isolation openings being at least partially spaced apart and forming a communication opening, wherein a minimum size of the communication opening in a thickness direction of the display panel is less than or equal to a product of a sum of thicknesses of the light emitting unit and the first electrode of at least a part of the light emitting devices and a sealing coefficient.

The embodiments of the first aspect of the present application also provide a display panel, including: a substrate; an isolation structure disposed on a side of the substrate and enclosing and forming an isolation opening; a light emitting device, at least a part of the light emitting device is located within the isolation opening; a first encapsulation structure disposed on a side of the light emitting device away from the substrate, the first encapsulation structure including a first sub-portion and a second sub-section, the first sub-portion being disposed in the isolation opening and on the side of the light emitting device away from the substrate, the second sub-section being disposed on a side of the isolation structure facing the isolation opening, a surface of the first sub-portion away from the substrate being at least partially connected with a surface of the second sub-section away from the isolation structure to enclose and form a gap space.

Embodiments of a second aspect of the present application further provide a preparation method for a display panel, including:
preparing an isolation structure on a substrate, the isolation structure enclosing and forming isolation openings, the isolation openings including a first opening and a second opening, the isolation structure including a first isolation portion and a second isolation portion located on a side of the first isolation portion away from the substrate, the second isolation portion having a protruding portion protruding from the first isolation portion towards the isolation opening;
preparing a first device material layer and a first encapsulation material layer in sequence;
etching and removing the first encapsulation material layer and the first device material layer outside the first opening, to form a first light emitting device corresponding to the first opening and a first encapsulation unit located on a side of the first light emitting device away from the substrate, the first encapsulation unit including a first sub-portion, a second sub-portion and a third sub-portion, the first sub-portion covering on the side of the light emitting device away from the substrate, the second sub-portion covering on a side of the first isolation portion facing the isolation opening, the third sub-portion being at least partially located on a side of the second isolation portion facing the substrate and being at least partially attached on the protruding portion, the first sub-portion, the second sub-portion and the third sub-portion of the first encapsulation unit enclosing and forming a gap space, and the gap space of the first encapsulation unit having a communication opening;
preparing a second device material layer and a second encapsulation material layer in sequence, the second device material layer including a light emitting unit material layer and a first electrode material layer, the first electrode material layer of the second device material layer being continuously located on a side of the first encapsulation unit away from the substrate and sealing the communication opening of the first encapsulation unit;
etching and removing the second encapsulation material layer outside the second opening by a first etching mode, and then etching and removing the second device material layer by a second etching mode, so as to form a second light emitting device corresponding to the second opening and a second encapsulation unit located on a side of the second light emitting device away from the substrate.

Embodiments of a third aspect of the present application provide a display device including the display panel of any of the above embodiments or the display panel prepared by the preparation method of any of the above embodiments.

In the display panel provided by the embodiments of the present application, the display panel includes the substrate, the isolation structure, the light emitting devices, and the first encapsulation structure. The isolation structure is disposed on a side of the substrate and encloses and forms the plurality of isolation openings, at least a part of a structure of the light emitting device is located within the isolation opening, and the isolation structure can be used to divide the sub-pixels of the display panel. The isolation structure includes the first isolation portion and the second isolation portion located on the side of the first isolation portion away from the substrate, the second isolation portion has the protruding portion protruding from the first isolation portion towards the isolation opening. Therefore, when preparing the light emitting device of the display panel, at least a part of the material of the light emitting device can be directly evaporated on the whole surface, the protruding portion of the second isolation portion can block at least a part of the material for preparing the light emitting device, so as to separate the material of the light emitting devices in the adjacent sub-pixels, thereby facilitating the formation of the plurality of light emitting devices that are spaced apart and located within the isolation openings. Therefore, there is no need to set the mask with high precision when preparing the light emitting devices of the display panel, for example, there is no need to set setting the fine metal mask (FMM) when evaporating the material of the light emitting device. Thus, the production and preparation cost of the display panel can be better reduced.

The first encapsulation structure is disposed on the side of the light emitting device away from the substrate, and the first encapsulation structure may be used to encapsulate the light emitting device. The first encapsulation structure includes the first sub-portion, the second sub-portion and the third sub-portion, the first sub-portion covers on the side of the light emitting device away from the substrate, the second sub-portion covers on the side of the first isolation portion facing the isolation opening, the third sub-portion is at least partially located on the side of the second isolation portion facing the substrate and is at least partially attached on the protruding portion, so that the first encapsulation structure may have a large size to better extend the encapsulation path of the first encapsulation structure.

The first sub-portion, the second sub-portion and the third sub-portion enclose and form the gap space, which can reduce the interference influence of the first sub-portion, the second sub-portion and the third sub-portion when forming the first encapsulation structure. Therefore, the first sub-portion can be better formed on the side of the light emitting device away from the substrate, the second sub-portion can be better formed on the side of the first isolation portion facing the isolation opening, and the third sub-portion can be better formed on the side of the second isolation portion facing the substrate, thereby better improving the encapsulation effect of the first encapsulation structure on the display panel.

By setting the third sub-portion being at least partially connected with the first sub-portion to form the connection portion, the first sub-section can play a better supporting role on the second sub-section, and the second sub-section is not easy to be separated from the isolation structure, thereby better improving the encapsulation effect of the first encapsulation structure on the display panel. Further, when the subsequent film layer is prepared on the first encapsulation structure, the material of the subsequent film layer can be better continuous at the connection portion, which can facilitate the formation of the subsequent film layer or facilitate the patterning of the subsequent film layer. Therefore, the subsequent film layer can better cover the first encapsulation structure, and the subsequent film layer can provide certain protection to the first encapsulation structure.

### BRIEF DESCRIPTION OF THE DRAWINGS

The features, advantages and technical effects of the exemplary embodiments of the present application will be described below with reference to the accompanying drawings, in which the accompanying drawings are not drawn to actual scale.

FIG. 1 is a local structure schematic diagram of a display panel provided by an embodiment of the present application;

FIG. 2 is a local sectional diagram of a display panel provided by an embodiment of the present application;

FIG. 3 is a local sectional diagram of a display panel provided by another embodiment of the present application;

FIG. 4 is a local sectional diagram of a display panel provided by another embodiment of the present application;

FIG. 5 is a structure schematic diagram of a connection portion provided by an embodiment of the present application;

FIG. 6 is a structure schematic diagram of a connection portion provided by another embodiment of the present application;

FIG. 7 is a local sectional diagram of a display panel provided by another embodiment of the present application;

FIG. 8 is a local sectional diagram of a display panel provided by another embodiment of the present application;

FIG. 9 is a structure schematic diagram of a connection portion provided by another embodiment of the present application;

FIG. 10 is a local structure schematic diagram of a first encapsulation structure provided by an embodiment of the present application;

FIG. 11 is a local sectional diagram of a display panel provided by another embodiment of the present application;

FIG. 12 is a local sectional diagram of a display panel provided by another embodiment of the present application;

FIG. 13 is a local sectional diagram of a display panel provided by another embodiment of the present application;

FIG. 14 is a local sectional diagram of a display panel provided by another embodiment of the present application;

FIG. 15 is a local sectional diagram of a display panel provided by another embodiment of the present application;

FIG. 16 is a local sectional diagram of a display panel provided by another embodiment of the present application;

FIG. 17 is a local sectional diagram of a display panel provided by another embodiment of the present application;

FIG. 18 is a local sectional diagram of a display panel provided by another embodiment of the present application;

FIG. 19 is a local sectional diagram of a display panel provided by another embodiment of the present application;

FIG. 20 is a local sectional diagram of a display panel provided by another embodiment of the present application;

FIG. 21 is a local structure schematic diagram of an isolation structure provided by an embodiment of the present application;

FIG. 22 is a local sectional diagram of a display panel provided by another embodiment of the present application;

FIG. 23 is a local sectional diagram of a display panel provided by another embodiment of the present application;

FIG. 24 is a structure schematic diagram of a first sub-section provided by an embodiment of the present application;

FIG. 25 is a structure schematic diagram of a first sub-section provided by another embodiment of the present application;

FIG. 26 is a structure schematic diagram of a first sub-section provided by another embodiment of the present application;

FIG. 27 is a local sectional diagram of a display panel provided by another embodiment of the present application;

FIG. 28 is a local sectional diagram of a display panel provided by another embodiment of the present application;

FIG. 29 is a local sectional diagram of a display panel provided by another embodiment of the present application;

FIG. 30 is a local sectional diagram of a display panel provided by another embodiment of the present application;

FIG. 31 is a local sectional diagram of a display panel provided by another embodiment of the present application;

FIG. 32 is a local sectional diagram of a display panel provided by another embodiment of the present application;

FIG. 33 is a local schematic diagram of an isolation structure provided by another embodiment of the present application;

FIG. 34 is a local sectional diagram of a display panel provided by another embodiment of the present application;

FIG. 35 is a local sectional diagram of a display panel provided by another embodiment of the present application;

FIG. 36 is a local sectional diagram of a display panel provided by another embodiment of the present application;

FIG. 37 to FIG. 46 are preparation process schematic diagrams of a preparation method for a display panel provided by an embodiment of the present application;

FIG. 47 is a local sectional diagram of a display panel provided by another embodiment of the present application;

FIG. 48 is a local sectional diagram of a display panel provided by another embodiment of the present application;

FIG. 49 is a local sectional diagram of a display panel provided by another embodiment of the present application;

FIG. 50 is a plane structure schematic diagram of a display panel provided by an embodiment of the present application;

FIG. 51 is an enlarged diagram of a region S1 of the display panel shown in FIG. 50;

FIG. 52 is a sectional diagram of the display panel along M-N shown in FIG. 51;

FIG. 53 is an enlarged diagram of a partial region of the display panel shown in FIG. 52;

FIG. 54 is a structure schematic diagram of another display panel used as a contrast embodiment provided by an embodiment of the present application;

FIG. 55A to FIG. 55D are process diagrams of a preparation method for forming the display panel shown in FIG. 5 provided by an embodiment of the present application;

FIG. 56 is a schematic diagram of a position relationship between a part of the film layers of the display panel and an evaporation source provided by an embodiment of the present application;

FIG. 57 is a sectional diagram of a partial region of a display panel provided by an embodiment of the present application;

FIG. 58 is a flowchart diagram of a preparation method for a display panel provided by an embodiment of the present application;

FIG. 59 to FIG. 62 are preparation process schematic diagrams of a preparation method for a display panel provided by another embodiment of the present application;

FIG. 63 is a flowchart diagram of a preparation method for a display panel provided by another embodiment of the present application;

FIG. 64 to FIG. 70 are preparation process schematic diagrams of a preparation method for a display panel provided by another embodiment of the present application.

### DETAILED DESCRIPTION

The characteristics and exemplary embodiments of the various aspects of the present application will be described in detail below. In the detailed description below, many specific details are presented in order to provide a comprehensive understanding of the present application. However, it is obvious to those skilled in the art that the present application may be implemented without some of these specific details. The following description of the embodiments is merely intended to provide a better understanding of the present application by showing examples of the present application. In the drawings and the following description, at least some of the publicly known structures and techniques are not shown in order to avoid unnecessary ambiguity in the present application; and, for clarity, the size of the partial structure may be exaggerated. Furthermore, the features, the structures, or the characteristics described below may be combined in one or more embodiments in any suitable manner.

The embodiments of the present application provide a display panel, a preparation method for a display panel, and a display device, and the embodiments of the display panel, the preparation method for the display panel, and the display device will be described below in combination with the attached drawings.

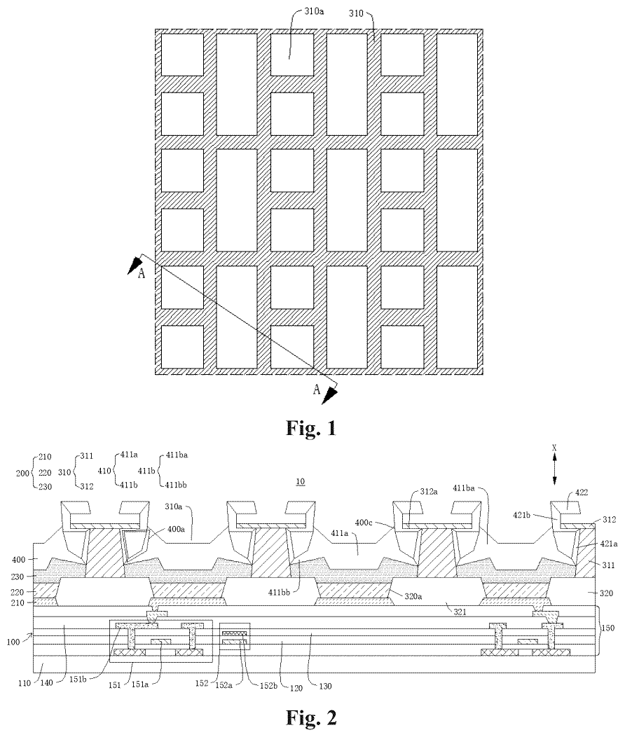

FIG. 1 is a local structure schematic diagram of a display panel 10 provided by an embodiment of the present application, and FIG. 2 is a local sectional diagram of a display panel 10 provided by an embodiment of the present application, here, the X direction may be a thickness direction of the display panel 10. Optionally, FIG. 2 may be a local sectional diagram of an embodiment at A-A in FIG. 1.

The embodiments of the first aspect of the present application provide a display panel 10, including: a substrate 100; an isolation structure 310 disposed on a side of the substrate 100 and enclosing and forming a plurality of isolation openings 310a, the isolation structure 310 including a first isolation portion 311 and a second isolation portion 312 located on a side of the first isolation portion 311 away from the substrate 100, the second isolation portion 312 having a protruding portion 312a protruding from the first isolation portion 311 towards the isolation opening 310a; a plurality of light emitting devices 200, at least a part of a structure of the light emitting device 200 is located within the isolation opening 310a; a first encapsulation structure 400 disposed on a side of the light emitting device 200 away from the substrate 100, the first encapsulation structure 400 including a first sub-portion 410, a second sub-portion 421a and a third sub-portion 421b, the first sub-portion 410 covering on the side of the light emitting device 200 away from the substrate 100, the second sub-portion 321a covering on a side of the first isolation portion 311 facing the isolation opening 310a, the third sub-portion 421b being at least partially located on a side of the second isolation portion 312 facing the substrate 100 and being at least partially attached on the protruding portion 312a, the first sub-portion 410, the second sub-portion 421a and the third sub-portion 421b enclosing and forming a gap space 400a, and the third sub-portion 421b being at least partially connected with the first sub-portion 410 to form a connection portion 400c.

In the display panel 10 provided by the embodiments of the present application, the display panel 10 includes the substrate 100, the isolation structure 310, the light emitting devices 200, and the first encapsulation structure 400. The isolation structure 310 is disposed on a side of the substrate 100 and encloses and forms a plurality of isolation openings 310a, at least a part of the light emitting device 200 is located within the isolation opening 310a, and the isolation structure 310 can be used to divide the sub-pixels of the display panel 10.

Optionally, as shown in FIG. 1, the isolation structure 310 may be in a grid shape to facilitate the division of the sub-pixels of the display panel 10 by the isolation structure 310. Specifically, the hollow region in the isolation structure 310 in the grid shape may be the isolation openings 310a.

The isolation structure 310 includes the first isolation portion 311 and the second isolation portion 312 located on the side of the first isolation portion 311 away from the substrate 100, the second isolation portion 312 has the protruding portion 312a protruding from the first isolation portion 311 towards the isolation opening 310a. Therefore, when preparing the light emitting device 200 of the display panel 10, at least a part of the material of the light emitting device 200 can be directly evaporated on the whole surface, the protruding portion 312a of the second isolation portion 312 can block at least a part of the material for preparing the light emitting device 200, so as to separate the material of the light emitting devices 200 in the adjacent sub-pixels, thereby facilitating the formation of the plurality of light emitting devices 200 that are spaced apart and located within the isolation openings 310a. Therefore, there is no need to set the mask with high precision when preparing the light emitting devices 200 of the display panel 10, for example, there is no need to set setting the fine metal mask (FMM) when evaporating the material of the light emitting device 200. Thus, the production and preparation cost of the display panel 10 can be better reduced.

The first encapsulation structure 400 is disposed on the side of the light emitting device 200 away from the substrate 100, and the first encapsulation structure 400 may be used to encapsulate the light emitting device 200. The first encapsulation structure 400 includes the first sub-portion 410, the second sub-portion 421a and the third sub-portion 421b, the first sub-portion 410 covers on the side of the light emitting device 200 away from the substrate 100, the second sub-portion 421a covers on the side of the first isolation portion 311 facing the isolation opening 310a, the third sub-portion 421b is at least partially located on the side of the second isolation portion 312 facing the substrate 100 and is at least partially attached on the protruding portion 312a, so that the first encapsulation structure 400 may have a large size to better extend the encapsulation path of the first encapsulation structure 400.

Optionally, in the embodiments of the present application, one covering the other may mean that the two are in direct contact with each other; or, it may mean that the two are not in direct contact, and other film layer structures may be sandwiched between the two. For example, other film layers may be provided between the second sub-portion 421a and the first isolation portion 311, and other film layers may be provided between the third sub-portion 421b and the second isolation portion 312.

Optionally, the first sub-portion 410, the second sub-portion 421a and the third sub-portion 421b may be connected sequentially. Specifically, a side of the first sub-portion 410 facing the first isolation portion 311 may be connected to a side of the second sub-portion 421a close to the substrate 100, and a side of the second sub-portion 421a close to the second isolation portion 312 may be connected to a side of the third sub-portion 421b close to the first isolation portion 311.

The first sub-portion 410, the second sub-portion 421a and the third sub-portion 421b enclose and form the gap space 400a, which can reduce the interference influence of the first sub-portion 410, the second sub-portion 421a and the third sub-portion 421b when forming the first encapsulation structure 400. Therefore, the first sub-portion 410 can be better formed on the side of the light emitting device 200 away from the substrate 100, the second sub-portion 421a can be better formed on the side of the first isolation portion 311 facing the isolation opening 310a, and the third sub-portion 421b can be better formed on the side of the second isolation portion 312 facing the substrate 100, thereby better improving the encapsulation effect of the first encapsulation structure 400 on the display panel 10.

By setting the third sub-portion 421b being at least partially connected with the first sub-portion 410 to form the connection portion 400c, the first sub-section can play a better supporting role on the second sub-section, and the second sub-section is not easy to be separated from the isolation structure 310, thereby better improving the encapsulation effect of the first encapsulation structure 400 on the display panel 10. Further, when the subsequent film layer is prepared on the first encapsulation structure 400, the material of the subsequent film layer can be better continuous at the connection portion 400c, which can facilitate the formation of the subsequent film layer or facilitate the patterning of the subsequent film layer. Therefore, the subsequent film layer can better cover the first encapsulation structure 400, and the subsequent film layer can provide certain protection to the first encapsulation structure 400.

In some embodiments of the present application, the light emitting device 200 may include a light emitting unit 220 and a first electrode 230, and the first electrode 230 may be located on a side of the light emitting unit 220 away from the substrate 100.

Optionally, the light emitting unit 220 may include a hole inject layer (HIL), a hole transport layer (HTL), a light emitting layer, an electron inject layer (EIL), and an electron transport layer (ETL).

Optionally, the light emitting device 200 may also include a second electrode 210 disposed on a side of the light emitting unit 220 facing the substrate 100, and the second electrode 210 may be located between the light emitting device 200 and the substrate 100.

Optionally, the first electrode 230 and the second electrode 210 may be used as pixel electrodes of the display panel 10, one of the first electrode 230 and the second electrode 210 may be used as an anode, and the other one may be used as a cathode, so as to drive the light emitting unit 220 to emit light. The embodiments of the present application illustrate the first electrode 230 as the cathode of the display panel 10 and the second electrode 210 as the anode of the display panel 10.

In some embodiments of the present application, the substrate 100 may be arranged in various ways. Optionally, the substrate 100 includes a baseplate 110 and a drive circuit 150 disposed on a side of the baseplate 110 facing the isolation structure 310, and the drive circuit 150 may include a transistor 151, a storage capacitor 152, and drive signal lines for connecting various devices. The transistor 151 includes a semiconductor, a gate 151a, and a source and drain 151b. The storage capacitor 152 includes a first electrode plate 152a and a second electrode plate 152b.

As an example, the substrate 100 may also include a first insulating layer 120, a second insulating layer 130 and a third insulating layer 140 arranged on a side of the baseplate 110 facing the drive circuit 150 and stacked on the baseplate 110 in sequence. The gate 151a and the first electrode plate 152a may be disposed in a same layer, for example, the gate 151a and the first electrode plate 152a may be located at a side of the first insulating layer 120 facing the baseplate 110. The second electrode plate 152b may be located between the first insulating layer 120 and the second insulating layer 130, and the source and drain 151b may be located between the second insulating layer 130 and the third insulating layer 140.

In some optional embodiments, the material of the isolation structure 310 may include a conductive material. The first electrode 230 can be connected to the isolation structure 310, so that the first electrodes 230 of the adjacent sub-pixels can be electrically connected by the isolation structure 310. That is, the first electrodes 230 of the adjacent sub-pixels can be electrically connected by the isolation structure 310 to form a surface electrode, thereby facilitating the control of the first electrodes 230 in the display panel 10. Optionally, the material of the first isolation portion 311 may include a conductive material, and the first electrode 230 may be connected to the first isolation portion 311, so that the first electrodes 230 of the adjacent sub-pixels may be electrically connected by the first isolation portion 311.

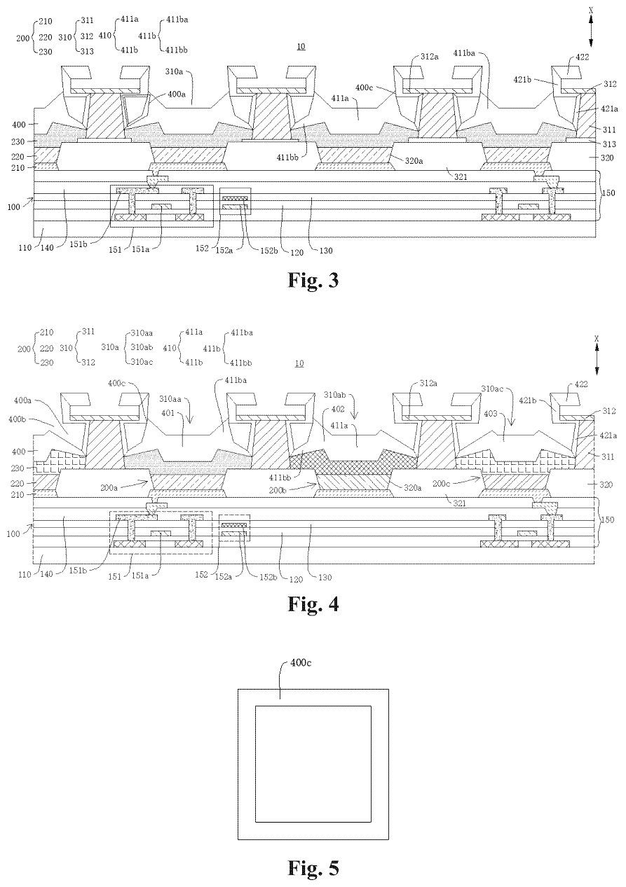

FIG. 3 is a local sectional diagram of a display panel 10 provided by another embodiment of the present application. Optionally, FIG. 3 may be a local sectional diagram of another embodiment at A-A in FIG. 1.

As shown in FIG. 3, in some optional embodiments, the isolation structure 310 also includes a third isolation portion 313 disposed at a side of the first isolation portion 311 facing the substrate 100. The third isolation portion 313 is disposed protruding from the first isolation portion 311 toward the isolation opening 310a, that is, the third isolation portion 313 has a protruding portion protruding from the first isolation portion 311 toward the isolation opening 310a. Here, the material of the third isolation portion 313 may include a conductive material, and the first electrode 230 may be connected to the third isolation portion 313, so that the first electrodes 230 of the adjacent sub-pixels may be electrically connected by the third isolation portion 313. By setting the third isolation portion 313 as protruding from the first isolation portion 311 toward the isolation opening 310a, the third isolation portion 313 may have a large size to facilitate the connection with the first electrode 230.

Optionally, the display panel 10 also includes a pixel definition layer 320 disposed on a side of the substrate 100 facing the light emitting device 200, the pixel definition layer 320 includes a pixel limiting portion 321 and a pixel opening 320a enclosed and formed by the pixel limiting portion 321, the isolation structure 310 is disposed on a side of the pixel limiting portion 321 away from the substrate 100, and the pixel opening 320a may communicate with the isolation opening 310a.

Optionally, an orthographic projection of the pixel opening 320a on the substrate 100 may be located in an orthographic projection of the isolation opening 310a on the substrate 100. The orthographic projection of the pixel opening 320a on the substrate 100 may refer to an orthographic projection region enclosed and formed by an orthographic projection of an inner wall enclosing and forming the pixel opening 320a on the substrate 100. The orthographic projection of the isolation opening 310a on the substrate 100 may refer to an orthographic projection region enclosed and formed by an orthographic projection of an inner wall enclosing and forming the isolation opening 310a on the substrate 100.

Optionally, the pixel limiting portion 321 may be disposed between the adjacent second electrodes 210, the adjacent second electrodes 210 may be insulated by the pixel limiting portion 321, and the setting of the pixel limiting portion 321 may also facilitate the division of the sub-pixels in the display panel 10.

Optionally, the pixel limiting portion 321 may be located between the second electrode 210 and the isolation structure 310, and the isolation structure 310 and the second electrode 210 may be insulated by the pixel limiting portion 321, so that the first electrode 230 and the second electrode 210 do not have short-circuit connection through the isolation structure 310, which is facilitate to improve the operation reliability of the display panel 10.

In these optional embodiments, the relative position between the isolation structure 310 and the pixel limiting portion 321 may be set in a variety of ways. Optionally, as shown in FIG. 2 and FIG. 3, the isolation structure 310 may be disposed at a side of the pixel limiting portion 321 away from the substrate 100, or the pixel limiting portion 321 is provided with an accommodating groove, and at least a part of the isolation structure 310 is located in the accommodating groove, so that the isolation structure 310 does not have a large height compared to the substrate 100, thereby better reducing the thickness of the display panel 10. For ease of description, the latter embodiments illustrate the isolation structure 310 as being disposed on the side of the pixel limiting portion 321 away from the substrate 100.

FIG. 4 is a local sectional diagram of a display panel 10 provided by another embodiment of the present application, and FIG. 4 may be a local sectional diagram of another embodiment at A-A in FIG. 1.

As shown in FIG. 4, in some optional embodiments, the isolation openings 310a may include a first opening 310aa and a third opening 310ac, and the light emitting devices 200 include a first light emitting device 200a disposed corresponding to the first opening 310aa and a third light emitting device 200c disposed corresponding to the third opening 310ac.

Optionally, the light emitting color of the first light emitting device 200a is different from the light emitting color of the third light emitting device 200c, and the display panel 10 may display a variety of colors through the first light emitting device 200a and the third light emitting device 200c having different light emitting colors.

Optionally, the first light emitting device 200a being disposed corresponding to the first opening 310aa may mean that the orthographic projection of the first light emitting device 200a on the substrate 100 may be located within the orthographic projection of the first opening 310aa on the substrate 100. Optionally, the third light emitting device 200c being disposed corresponding to the third opening 310ac may mean that the orthographic projection of the third light emitting device 200c on the substrate 100 may be located within the orthographic projection of the third opening 310ac on the substrate 100.

Optionally, the material of the light emitting unit 220 of the first light emitting device 200a may be at least partially different from the material of the light emitting unit 220 of the third light emitting device 200c, thereby realizing that the light emitting color of the first light emitting device 200a is different from the light emitting color of the third light emitting device 200c.

Optionally, the first encapsulation structure 400 may include a first encapsulation unit 401 that is at least partially located in the first opening 310aa and a third encapsulation unit 403 that is at least partially located in the third opening 310ac. The first encapsulation unit 401 may independently encapsulate the first light emitting device 200a in the first opening 310aa, and the third encapsulation unit 403 may independently encapsulate the third light emitting device 200c in the third opening 310ac, so that the encapsulation of the first encapsulation unit 401 may not affect the encapsulation of the third encapsulation unit 403. That is, when one of the first encapsulation unit 401 and the third encapsulation unit 40 is damaged, the encapsulation effect of the other one is not affected, thereby better improving the encapsulation effect of the display panel 10.

Optionally, the first encapsulation unit 401 and the third encapsulation unit 403 may be spaced apart, so that the encapsulation effect of the first encapsulation unit 401 and the encapsulation effect of the third encapsulation unit 403 are not easily affected with each other.

Optionally, in the preparation process of the display panel 10, the preparation step of the first light emitting device 200a may be located before the preparation step of the third light emitting device 200c. For example, in the preparation process of the display panel 10, the first light emitting device 200a and the first encapsulation unit 401 may be prepared firstly, and then the third light emitting device 200c and the third encapsulation unit 403 may be prepared. Specifically, the preparation of the second electrodes 210 of the first light emitting device 200a and the third light emitting device 200c may be completed simultaneously, then the preparation of the light emitting unit 220 and the first electrode 230 of the first light emitting device 200a may be performed to complete the preparation of the first light emitting device 200a, then the first encapsulation unit 401 is prepared on the first light emitting device 200a, then the preparation of the light emitting unit 220 and the first electrode 230 of the third light emitting device 200c may be performed to complete the preparation of the third light emitting device 200c, then the third encapsulation unit 403 is prepared on the third light emitting device 200c.

In some optional embodiments, the isolation openings 310a also include a second opening 310ab, and the light emitting devices 200 include a second light emitting device 200b disposed corresponding to the second opening 310ab.

Optionally, the first light emitting device 200a, the second light emitting device 200b and the third light emitting device 200c may have different light emitting colors, and the display panel 10 may display a variety of colors through the first light emitting device 200a, the second light emitting device 200b and the third light emitting device 200c having different light emitting colors. For example, the first light emitting device 200a may be used to emit the red light, the second light emitting device 200b may be used to emit the green light, and the third light emitting device 200c may be used to emit the blue light.

Optionally, the second light emitting device 200b being disposed corresponding to the second opening 310ab may mean that the orthographic projection of the second light emitting device 200b on the substrate 100 may be located within the orthographic projection of the second opening 310ab on the substrate 100.

Optionally, the material of the light emitting unit 220 of the first light emitting device 200a, the material of the light emitting unit 220 of the second light emitting device 200b and the material of the light emitting unit 220 of the third light emitting device 200c may be at least partially different, thereby realizing that the light emitting colors of the first light emitting device 200a, the second light emitting device 200b and the third light emitting device 200c are different.

Optionally, the first encapsulation structure 400 includes a second encapsulation unit 402 at least partially located within the second opening 310ab. The second encapsulation unit 402 may independently encapsulate the second light emitting device 200b in the second opening 310ab, so that the encapsulation of the first encapsulation unit 401, the encapsulation of the second encapsulation unit 402, and the encapsulation of the third encapsulation unit 403 may not affect with each other. That is, when one of the first encapsulation unit 401, the second encapsulation unit 402 and the third encapsulation unit 403 is damaged, the encapsulation effect of the other one is not affected, thereby better improving the encapsulation effect of the display panel 10.

Optionally, the first encapsulation unit 401, the second encapsulation unit 402 and the third encapsulation unit 403 may be spaced apart in pairs.

Optionally, in the preparation process of the display panel 10, the preparation step of the second light emitting device 200b is located between the preparation step of the first light emitting device 200a and the preparation step of the third light emitting device 200c. For example, in the preparation process of the display panel 10, the first light emitting device 200a and the first encapsulation unit 401 may be prepared firstly, then the second light emitting device 200b and the second encapsulation unit 402 may be prepared, and then the third light emitting device 200c and the third encapsulation unit 403 may be prepared. Specifically, the preparation of the second electrodes 210 of the first light emitting device 200a, the second light emitting device 200b and the third light emitting device 200c may be completed simultaneously, then the preparation of the light emitting unit 220 and the first electrode 230 of the first light emitting device 200a may be performed to complete the preparation of the first light emitting device 200a, then the first encapsulation unit 401 is prepared on the first light emitting device 200a, then the preparation of the light emitting unit 220 and the first electrode 230 of the second light emitting device 200b may be performed to complete the preparation of the second light emitting device 200b, then the second encapsulation unit 402 is prepared on the second light emitting device 200b, then the preparation of the light emitting unit 220 and the first electrode 230 of the third light emitting device 200c may be performed to complete the preparation of the third light emitting device 200c, finally, the third encapsulation unit 403 is prepared on the third light emitting device 200c.

In some embodiments of the present application, the material of the first encapsulation structure 400 may include an inorganic material, such that the first encapsulation structure 400 has a better encapsulation capability to reduce the influence of water vapor on the light emitting device 200. Optionally, the first encapsulation structure 400 may be prepared by a chemical vapor deposition (CVD) process.

In some optional embodiments, the third sub-portion 421b being at least partially connected with the first sub-portion 410 to form the connection portion 400c may mean that a side of the third sub-portion 421b close to the isolation opening 310a may be at least partially connected with a surface of the first sub-portion 410 away from the substrate 100 to form the connection portion 400c.

It should be understood that, the surface of the first sub-portion 410 away from the substrate 100 is not connected in its entirety to the side of the third sub-portion 421b close to the isolation opening 310a. That is, the side of the third sub-portion 421b close to the isolation opening 310a being at least partially connected with the surface of the first sub-portion 410 away from the substrate 100 to form the connection portion 400c may mean that, the surface of the first sub-portion 410 away from the substrate 100 is everywhere connected to the surface of the third sub-portion 421b close to the isolation opening 310a, or the surface of the first sub-portion 410 away from the substrate 100 is partially connected to the surface of the third sub-portion 421b close to the isolation opening 310a.

Optionally, the third sub-portion 421b and the first sub-portion 410 may not have a distinct interface at the connection portion 400c, for example, the third sub-portion 421b and the first sub-portion 410 may be integrated into one formed structure at the connection portion 400c, that is, the material of the third sub-portion 421b may be integrated with the material of the first sub-portion 410 at the connection portion 400c. Optionally, the third sub-portion 421b and the first sub-portion 410 may have a distinct interface at the connection portion 400c, that is, the surface of the third sub-portion 421b close to the isolation opening 310a is bonded but not fused with the surface of the first sub-portion 410 away from the substrate 100.

In some optional embodiments, the third sub-portion 421b may also partially cover the end portion of the second isolation portion 312 facing the isolation opening 310a.

Optionally, the side of the third sub-portion 421b away from the first isolation portion 311 may protrude from the second isolation portion 312, so that the side of the third sub-portion 421b close to the isolation opening 310a is at least partially connected with the surface of the first sub-portion 410 away from the substrate 100 to form the connection portion 400c. That is, the first sub-portion 410 can play a better supporting role for the third sub-portion 421b.

In some optional embodiments, the first sub-portion 410 may include a first body sub-portion 411a and a second body sub-portion 411b that are interconnected, the first body sub-portion 411a is located in the pixel opening 320a, and the second body sub-portion 411b is located on the side of the pixel limiting portion 321 away from the substrate 100.

Optionally, the orthographic projection of the first body sub-portion 411a on the substrate 100 may be located within the orthographic projection of the pixel opening 320a on the substrate 100, and the orthographic projection of the second body sub-portion 411b on the substrate 100 may be located within the orthographic projection of the pixel limiting portion 321 on the substrate 100.

Optionally, the connection portion 400c may be formed by at least partially connecting the side of the third sub-portion 421b close to the isolation opening 310a and the surface of the second body sub-portion 411b away from the substrate 100.

Optionally, the side of the second body sub-portion 411b facing the isolation structure 310 may be connected to the side of the second sub-portion 421a facing the substrate 100. Here, the gap space 400a may be enclosed and formed by the second body sub-portion 411b, the second sub-portion 421a, and the third sub-portion 421b.

Optionally, the orthographic projection of the connection portion 400c on the substrate 100 may at least partially overlap with the orthographic projection of the pixel limiting portion 321 on the substrate 100, that is, at least a part of the connection portion 400c may be located at the side of the pixel limiting portion 321 away from the substrate 100. Here, the pixel limiting portion 321 may raise the position of the second body sub-portion 411b, so as to facilitate the connection of the side of the third sub-portion 421b close to the isolation opening 310a and the surface of the second body sub-portion 411b away from the substrate 100.

FIG. 5 is a structure schematic diagram of a connection portion 400c provided by an embodiment of the present application.

As shown in FIG. 4 and FIG. 5, in some optional embodiments, an orthographic projection of the connection portion 400c in at least a part of the isolation openings 310a on the substrate 100 is in a ring shape, so that the gap space 400a is an enclosed space.

Optionally, the gap space 400a in at least a part of the isolation openings 310a being the enclosed space may specifically mean that the first sub-portion 410, the second sub-portion 421a and the third sub-portion 421b in at least a part of the isolation openings 310a may enclose and form an enclosed gap space 400a.

Optionally, the orthographic projection of the connection portion 400c on the substrate 100 being in the ring shape may mean that the orthographic projection of the connection portion 400c on the substrate 100 is in a closed ring shape, so as to facilitate the formation of the enclosed gap space 400a. Here, the enclosed gap space 400a enclosed and formed by the first sub-portion 410, the second sub-portion 421a and the third sub-portion 421b may not be communicated with other external spaces, thereby further enhancing the structural stability of the first sub-portion 410, the second sub-portion 421a and the third sub-portion 421b.

Optionally, the orthographic projection of the connection portion 400c on the substrate 100 may surround the orthographic projection of the pixel opening 320a on the substrate 100.

In these optional embodiments, by setting that the orthographic projection of the connection portion 400c in at least a part of the isolation openings 310a on the substrate 100 is in the ring shape, the first sub-portion 410 in the isolation opening 310a and the third sub-portion 421b on the peripheral side of the isolation structure 310 may have a large connection area, that is, the first sub-portion 410 in the isolation opening 310a can better support the second sub-portion 421a and the third sub-portion 421b on the peripheral side of the isolation structure 310. Therefore, the supporting effect of the first sub-portion 410 for the second sub-portion 421a and the third sub-portion 421b can be better improved, and the second sub-portion 421a and the third sub-portion 421b are not easily detached from the isolation structure 310, which can better improve the encapsulation effect of the first encapsulation structure 400 on the display panel 10. Further, when the subsequent film layer is prepared on the first encapsulation structure 400, the material of the subsequent film layer can be better continuous at the connection portion 400c in the ring shape, which can facilitate the formation of the subsequent film layer or facilitate the patterning of the subsequent film layer. Therefore, the subsequent film layer can better cover the first encapsulation structure 400 in at least a part of the isolation openings 310a, and the subsequent film layer can provide certain protection to the first encapsulation structure 400.

In some optional embodiments, the gap space 400a in the first opening 310aa is an enclosed space. For example, the first sub-portion 410 of the first encapsulation unit 401, the second sub-portion 421a of the first encapsulation unit 401, and the third sub-portion 421b of the first encapsulation unit 401 may enclose and form an enclosed gap space 400a.

Optionally, the third sub-portion 421b in the first opening 310aa is connected with the first sub-portion 410 to form the connection portion 400c, and the orthographic projection of the connection portion 400c in the first opening 310aa on the substrate 100 is in a ring shape. For example, the surface of the first sub-portion 410 of the first encapsulation unit 401 away from the substrate 100 and the surface of the third sub-portion 421b away from the first isolation portion 311 and covering the second isolation portion 312 may connect with each other, and form a ring shaped connection portion 400c.

In these optional embodiments, by setting the gap space 400a in the first opening 310aa as an enclosed space, the first sub-portion 410 in the first encapsulation unit 401 may play a better supporting role for the third sub-portion 421b, so that the first encapsulation unit 401 may have better structural stability. Thus, the first encapsulation unit 401 is not easily damaged by subsequent processes. For example, the first encapsulation unit 401 is not easily damaged when preparing the second light emitting device 200b, the second encapsulation unit 402, the third light emitting device 200c and the third encapsulation unit 403, thereby better improving the encapsulation stability of the first encapsulation unit 401.

Further, when the subsequent film layer is prepared on the first encapsulation unit 401, the material of the subsequent film layer can be better continuous at the connection portion 400c, which can facilitate the formation of the subsequent film layer or facilitate the patterning of the subsequent film layer. Therefore, the subsequent film layer can better cover the first encapsulation unit 401, and the subsequent film layer can provide certain protection to the first encapsulation unit 401.

For example, in the subsequent preparation process of the light emitting unit 220 and the second electrode 210 of the second light emitting device 200b as well as the second encapsulation unit 402, after preparing the material of the light emitting unit 220 and the second electrode 210 of the second light emitting device 200b on the whole surface, the material of the light emitting unit 220 and the second electrode 210 of the second light emitting device 200b may be relatively continuous on the first encapsulation unit 401. Therefore, when patterning the second encapsulation unit 402 on the light emitting unit 220 and the second electrode 210 of the second light emitting device 200b, that is, when removing the material of the second encapsulation unit 402 outside of the second opening 310ab, the material of the light emitting unit 220 and the second electrode 210 of the second light emitting device 200b may be used to protect the first encapsulation unit 401 in the first opening 310aa, so that the etching material is not easy to damage the first encapsulation unit 401, thereby better improving the structural stability of the first encapsulation unit 401. Moreover, when preparing the second light emitting device 200b or the second encapsulation unit 402, the etching material is not easily accessible into the gap space 400a of the first encapsulation unit 401, thereby better reducing the etching damage of the inner wall of the gap space 400a in the first encapsulation unit 401 by the etching material, and better improving the structural stability of the first encapsulation structure 400.

For example, in the subsequent preparation process of the light emitting unit 220 and the second electrode 210 of the third light emitting device 200c as well as the third encapsulation unit 403, after preparing the material of the light emitting unit 220 and the second electrode 210 of the third light emitting device 200c on the whole surface, the material of the light emitting unit 220 and the second electrode 210 of the third light emitting device 200c may be relatively continuous on the first encapsulation unit 401. Therefore, when patterning the third encapsulation unit 403 on the light emitting unit 220 and the second electrode 210 of the third light emitting device 200c, that is, when removing the material of the third encapsulation unit 403 outside of the third opening 310ac, the material of the light emitting unit 220 and the second electrode 210 of the third light emitting device 200c may be used to protect the first encapsulation unit 401 in the first opening 310aa, so that the etching material is not easy to damage the first encapsulation unit 401, thereby better improving the structural stability of the first encapsulation unit 401. Moreover, when preparing the third light emitting device 200c or the third encapsulation unit 403, the etching material is not easily accessible into the gap space 400a of the first encapsulation unit 401, thereby better reducing the etching damage of the inner wall of the gap space 400a in the first encapsulation unit 401 by the etching material, and better improving the structural stability of the first encapsulation structure 400.

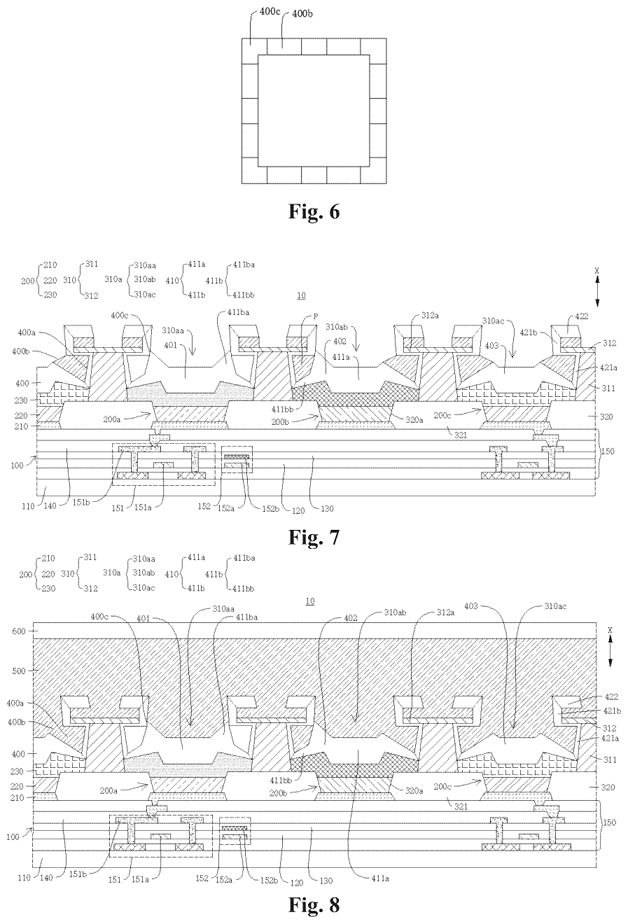

FIG. 6 is a structure schematic diagram of a connection portion 400c provided by another embodiment of the present application. FIG. 7 is a local sectional diagram of a display panel 10 provided by another embodiment of the present application, and FIG. 7 may be a local sectional diagram of another embodiment at A-A in FIG. 1.

As shown in FIG. 6 and FIG. 7, in some optional embodiments, the first sub-portion 410 and the third sub-portion 421b in at least a part of the isolation openings 310a may be at least partially spaced apart and form a communication opening 400b. For example, the first sub-portion 410 and the third sub-portion 421b in the second opening 310ab may be at least partially spaced apart and form the communication opening 400b, or the first sub-portion 410 and the third sub-portion 421b in the third opening 310ac may be at least partially spaced apart and form the communication opening 400b.

Optionally, a surface of the first sub-portion 410 away from the substrate 100 and a surface of the third sub-portion 421b close to the isolation opening 310a in at least a part of the isolation openings 310a are at least partially spaced apart and form at least one communication opening 400b.

In these optional embodiments, by setting the communication opening 400b, materials can then be filled into the gap space 400a through the communication opening 400b, so as to better support the second sub-portion 421a and the third sub-portion 421b. Therefore, the second sub-portion 421a and the third sub-portion 421b are not easy to be separated from the isolation structure 310, thereby better improving the encapsulation effect of the first encapsulation structure 400 on the display panel 10.

In some optional embodiments, at least a part of the gap space 400a is filled with a support structure P. The support structure P may play a better supporting role for the second sub-portion 421a and the third sub-portion 421b. Specifically, the support structure P may play a better supporting role for the second sub-portion 421a and the third sub-portion 421b, so that the second sub-portion 421a and the third sub-portion 421b are not easy to be separated from the isolation structure 310, thereby better improving the encapsulation effect of the first encapsulation structure 400 on the display panel 10.

Optionally, when preparing the display panel 10, the material of the support structure P may be filled to the gap space 400a through the communication opening 400b.

Optionally, the material of the support structure P may include an organic material, such that the material of the support structure P may have good fluidity to allow the support structure P to fill into the gap space 400a through the communication opening 400b.

In some optional embodiments of the present application, there are various preparation methods for the support structure P.

In some optional embodiments, the support structure P may be prepared independently. Specifically, the support structure P may be prepared after completing the preparation of the first encapsulation structure 400 in the partially isolation opening 310a.

For example, the gap space 400a in the second opening 310ab may form at least one communication opening 400b, that is, the second encapsulation unit 402 may have at least one communication opening 400b. After completing the preparation of the second encapsulation unit 402, and before starting the preparation of the third light emitting device 200c, the material of the support structure P may be filled into the gap space 400a of the second encapsulation unit 402 through the communication opening 400b, so as to complete the preparation of at least a part of the support structure P. The support structure P filled in the gap space 400a of the second encapsulation unit 402 may be used to support the second sub-portion 421a and the third sub-portion 421b of the second encapsulation unit 402, and the support structure P filled in the gap space 400a of the second encapsulation unit 402 may also be used to protect the second encapsulation unit 402 at the gap space 400a. Therefore, when preparing the third light emitting device 200c or the third encapsulation unit 403, the etching material is not easily accessible into the gap space 400a of the second encapsulation unit 402, thereby better reducing the etching damage of the inner wall of the gap space 400a in the second encapsulation unit 402 by the etching material, and better improving the structural stability of the first encapsulation structure 400.

For example, the gap space 400a in the third opening 310ac may form at least one communication opening 400b, that is, the third encapsulation unit 403 may have at least one communication opening 400b. After completing the preparation of the third encapsulation unit 403, the material of the support structure P may be filled into the gap space 400a of the third encapsulation unit 403 through the communication opening 400b, so as to complete the preparation of at least a part of the support structure P.

FIG. 8 is a local sectional diagram of a display panel 10 provided by another embodiment of the present application, and FIG. 8 may be a local sectional diagram of another embodiment at A-A in FIG. 1.

As shown in FIG. 8, in other optional embodiments, when preparing other film layer structures in the display panel 10, the materials of the other film layer structures can be filled into the gap space 400a through the communication opening 400b to form the support structure P.

Optionally, the display panel 10 also includes a second encapsulation layer 500 disposed on a side of the first encapsulation structure 400 away from the substrate 100, the surface of the first sub-portion 410 away from the substrate 100 and the surface of the third sub-portion 421b close to the isolation opening 310a in at least a part of the isolation openings 310a are at least partially spaced apart and form the communication opening 400b, and at least a part of the second encapsulation layer 500 is located within the gap space 400a to form the support structure P. Here, the material of the second encapsulation layer 500 is the same as the material of the support structure P.

For example, when preparing the second encapsulation layer 500 after completing the preparation of the first encapsulation structure 400, at least a part of the material of the second encapsulation layer 500 may be extended into the gap space 400a through the communication opening 400b to form the support structure P.

In these optional embodiments, the second encapsulation layer 500 may also be used to encapsulate the light emitting device 200 of the display panel 10. When preparing the second encapsulation layer 500, the material of the second encapsulation layer 500 may enter into the gap space 400a through the communication opening 400b to form the support structure P, so that a part of the material of the second encapsulation layer 500 can also be used to support the second sub-portion 421a and the third sub-portion 421b, thereby further enhancing the structural stability of the first encapsulation structure 400 at the gap space 400a. Moreover, the setting of the second encapsulation layer 500 can further enhance the encapsulation effect of the display panel 10.

Optionally, the material of the second encapsulation layer 500 includes an organic material, such that the second encapsulation layer 500 may have good fluidity to facilitate the extension of the material of the second encapsulation layer 500 into the gap space 400a through the communication opening 400b when the second encapsulation layer 500 is prepared. Optionally, the second encapsulation layer 500 may be prepared by the ink jet printing (IJP) technology.

Optionally, the display panel 10 may also include a third encapsulation layer 600 disposed on a side of the second encapsulation layer 500 away from the substrate 100, so as to further enhance the encapsulation effect of the light emitting device 200.

Optionally, the material of the third encapsulation layer 600 may include an inorganic material, such that the third encapsulation layer 600 has a better encapsulation capability to reduce the influence of water vapor on the light emitting device 200. Optionally, the third encapsulation layer 600 may be prepared by a chemical vapor deposition process.

It is understood that the display panel 10 may also include a light filter layer, an optical adhesive or a cover plate structure located at a side of the third encapsulation layer 600 away from the second encapsulation layer 500.

In some optional embodiments, the first encapsulation structure 400 may also include a fourth sub-portion 422 located on the side of the second isolation portion 312 away from the substrate 100 and spaced apart from the isolation structure 310. The fourth sub-portion 422 located on the side of the isolation structure 310 away from the substrate 100 may better improve the path of water vapor (including the etching material) to the light emitting device 200, thereby better improving the encapsulation effect of the first encapsulation structure 400 on the light emitting device 200.

Optionally, the first sub-portion 410, the second sub-portion 421a, the third sub-portion 421b, and the fourth sub-portion 422 may be connected sequentially.

Specifically, the side of the second sub-portion 421a away from the substrate 100 may be connected to the side of the fourth sub-portion 422 facing the isolation opening 310a.

Optionally, the support structure P may also be filled between the fourth sub-portion 422 and the isolation structure 310, and the support structure P filled between the fourth sub-portion 422 and the isolation structure 310 may play a better limiting effect on the fourth sub-portion 422. For example, the support structure P filled between the fourth sub-portion 422 and the isolation structure 310 can be used to support the fourth sub-portion 422, so that the fourth sub-portion 422 does not easily break off toward the isolation structure 310, thereby better improving the structural stability of the first encapsulation structure 400.

Optionally, when at least a part of the second encapsulation layer 500 is reused as the support structure P, the material of the at least a part of the second encapsulation layer 500 may also extend between the fourth sub-portion 422 and the isolation structure 310 to form the support structure P, so that a part of the material of the second encapsulation layer 500 can also be used to support the fourth sub-portion 422.

In some optional embodiments, at least a part of the support structure P may also be located on the side of the fourth sub-portion 422 away from the isolation structure 310, so that the fourth sub-portion 422 may be better wrapped by the support structure P to further enhance the limiting effect of the support structure P on the fourth sub-portion 422. Therefore, the support structure P may limit the breaking of the fourth sub-portion 422 toward the pixel opening 320a, thereby better improving the structural stability of the first encapsulation structure 400.

Optionally, the adjacent fourth sub-portions 422 are spaced apart, for example, the side of the isolation structure 310 away from the substrate 100 may have at least two fourth sub-portions 422, and the fourth sub-portions 422 may be respectively connected to the second sub-portion 421a within different isolation openings 310a. By setting that the adjacent fourth sub-portions 422 are spaced apart, when preparing the support structure P, the material of the support structure P can extend between the fourth sub-portion 422 and the isolation structure 310 through the interval between the adjacent fourth sub-portions 422, thereby facilitating the formation of the support structure P better wrapping the peripheral side of the fourth sub-portion 422.

In some embodiments of the present application, the communication opening 400b can be arranged in a variety of ways.

As shown in FIG. 6, in some optional embodiments, there are a plurality of communication openings 400b in at least a part of the isolation openings 310a, and the plurality of communication openings 400b are spaced apart. For example, there are a plurality of communication openings 400b in the second opening 310ab.

Optionally, the plurality of communication openings 400b may be spaced apart at the peripheral side of the pixel opening 320a.

In these optional embodiments, by reasonably setting the number of the communication openings 400b, the connection area of the first sub-portion 410 and the third sub-portion 421b can be better regulated. Therefore, the first sub-portion 410 can provide better support for the third sub-portion 421b to enhance the structural stability of the first encapsulation structure 400, and at the same time, it can reduce the blocking influence of the connection portion 400c on the material of the support structure P, so that the material of the support structure P can be sufficiently filled into the gap space 400a, thereby improving the encapsulation effect of the first encapsulation structure 400 for the light emitting device 200.

Optionally, the orthographic projection of the connection portion 400c in at least a part of the isolating openings 310a on the substrate 100 may not be a closed ring shape, for example, there may be a plurality of connection portions 400c, the plurality of connection portions 400c may be spaced apart at the peripheral side of the pixel opening 320a, and the communication opening 400b may be located between the adjacent connection portions 400c.

Optionally, the plurality of communication openings 400b may be equally spaced apart.

Here, the size of the communication opening 400b can be set in various ways. Optionally, as shown in FIG. 6, the areas of the orthographic projections of the communication openings 400b on the substrate 100 may be equal, or the shapes of the orthographic projections of the communication openings 400b on the substrate 100 may be the same. So that, the connection portion 400c can be used to uniformly support the third sub-portion 421b located at the side of the isolation structure 310 facing the isolation opening 310a, so as to enhance the structural stability of the first encapsulation structure 400. Further, the material of the support structure P can be uniformly filled through the communication opening 400b into the gap space 400a located at the side of the isolation structure 310 facing the isolation opening 310a.

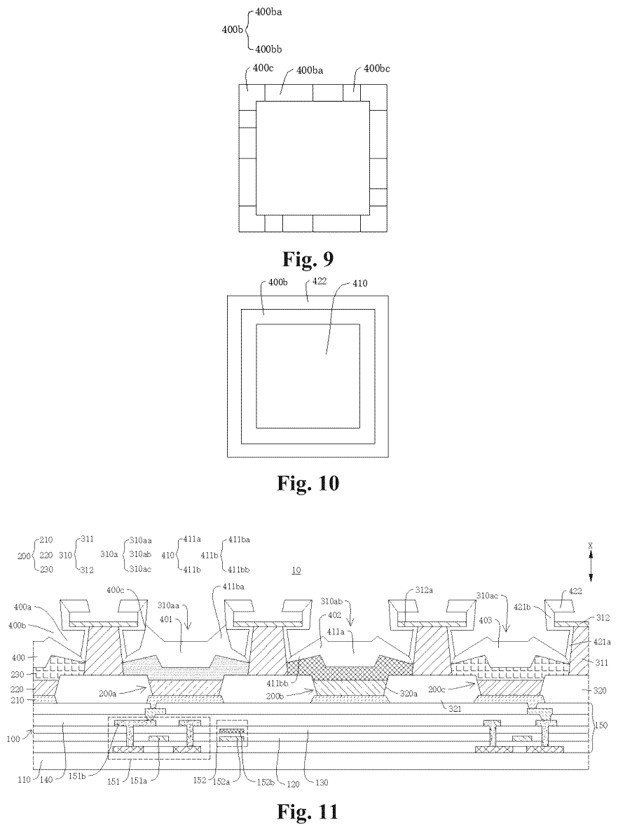

FIG. 9 is a structure schematic diagram of a connection portion 400c provided by another embodiment of the present application.

Optionally, as shown in FIG. 9, the communication openings 400b include a first type communication opening 400ba and a second type communication opening 400bb, and the area of the orthographic projection of the first type communication opening 400ba on the substrate 100 is greater than the area of the orthographic projection of the second type communication opening 400bb on the substrate 100. By providing the first type communication opening 400ba and the second type communication opening 400bb having different areas, the first type communication opening 400ba having a larger area can facilitate the subsequent filling of the material into the gap space 400a, and the first sub-portion 410 on two sides of the second type communication opening 400bb having a smaller area may better support the third sub-portion 421b. Therefore, the first sub-portion 410 can provide better support for the third sub-portion 421b to enhance the structural stability of the first encapsulation structure 400, and at the same time, it can reduce the blocking influence of the connection portion 400c on the material of the support structure P, so that the material of the support structure P can be sufficiently filled into the gap space 400a.

Optionally, the first type communication openings 400ba and the second type communication openings 400bb may be arranged alternately, that is, the first type communication opening 400ba may be located between adjacent second type communication openings 400bb, and/or, the second type communication opening 400bb may be located between adjacent first type communication openings 400ba. For example, in the side of the isolation structure 310 facing the isolation opening 310a, the first type communication openings 400ba and the second type communication openings 400bb may be arranged alternately, so as to better balance the structural strength of the first encapsulation structure 400 and the ability of the first encapsulation structure 400 facilitating the filling of the material of the support structure P.

FIG. 10 is a local structure schematic diagram of a first encapsulation structure 400 provided by an embodiment of the present application.

In some optional embodiments, the orthographic projection of the communication opening 400b in at least a part of the isolation openings 310a on the substrate 100 is in a ring shape, thereby better reducing the interference influence of the first sub-portion 410, the second sub-portion 421a and the third sub-portion 421b when forming the first encapsulation structure 400, and enabling the material of the support structure P to better enter the gap space 400a through the communication opening 400b.

In some optional embodiments, the communication opening 400b in the third opening 310ac may be in a ring shape, that is, the third encapsulation unit 403 may have the communication opening 400b in the ring shape, and the surface of the first sub-portion 410 in the third encapsulation unit 403 away from the substrate 100 may be spaced apart from the third sub-portions 421b in the third encapsulation unit 403.

In this optional embodiment, since the preparation step of the third encapsulation unit 403 is located after the preparation steps of the first light emitting device 200a, the first encapsulation unit 401, the second light emitting device 200b and the second encapsulation unit 402, the preparation process of the first light emitting device 200a, the first encapsulation unit 401, the second light emitting device 200b and the second encapsulation unit 402 does not easily affect the subsequent formation of the third encapsulation unit 403. Therefore, the surface of the first sub-portion 410 in the third encapsulation unit 403 away from the substrate 100 may be spaced apart from the surface of the third sub-portion 421b away from the first isolation portion 311 and covering the second isolation portion 312. That is, the first sub-portion 410 in the third encapsulation unit 403 may not provide excessive support to the third sub-portion 421b in the third encapsulation unit 403. Therefore, by setting that the communication opening 400b in the third opening 310ac is in the ring shape, it can better reduce the interference influence of the first sub-portion 410, the second sub-portion 421a and the third sub-portion 421b in the third encapsulation unit 403 when forming the third encapsulation unit 403.

In some embodiments of the present application, the gap space 400a of the first encapsulation unit 401 corresponding to the first opening 310aa may be an enclosed space, and the communication opening 400b of the third encapsulation unit 403 corresponding to the third opening 310ac may be in a ring shape, so that the first encapsulation unit 401 and the third encapsulation unit 403 may have the beneficial effect in the aforementioned embodiments. Further, the second encapsulation unit 402 corresponding to the second opening 310ab has a variety of morphology settings.

In some optional embodiments, as described in the aforementioned embodiments, the first sub-portion 410 and the third sub-portion 421b in the second opening 310ab may be at least partially spaced apart and form the communication opening 400b. That is, the second encapsulation unit 402 corresponding to the second opening 310ab may have the communication opening 400b.

For example, as shown in FIG. 4, FIG. 7 and FIG. 8, the first sub-portion 410 and the third sub-portion 421b in the second opening 310ab may be partially spaced apart and form the communication opening 400b, and the first sub-portion 410 and the third sub-portion 421b in the second opening 310ab may be partially connected and form the connection portion 400c. That is, the second encapsulation unit 402 corresponding to the second opening 310ab may have the connection portion 400c and the communication opening 400b at the same time.

FIG. 11 is a local sectional diagram of a display panel 10 provided by another embodiment of the present application, and FIG. 11 may be a local sectional diagram of another embodiment at A-A in FIG. 1.

For example, the first sub-portion 410 and the third sub-portion 421b in the second opening 310ab may be spaced apart and form the communication opening 400b in the ring shape. That is, the second encapsulation unit 402 corresponding to the second opening 310ab may have the communication opening 400b in the ring shape.

In these optional embodiments, since the preparation step of the second encapsulation unit 402 is located after the preparation steps of the first light emitting device 200a and the first encapsulation unit 401, the preparation process of the first light emitting device 200a and the first encapsulation unit 401 does not easily affect the subsequent formation of the second encapsulation unit 402. Therefore, the surface of the first sub-portion 410 in the second encapsulation unit 402 away from the substrate 100 may be spaced apart from the surface of the third sub-portion 321b away from the first isolation portion 311 and at least partially covering the second isolation portion 312. That is, the first sub-portion 410 in the second encapsulation unit 402 may not provide excessive support to the third sub-portion 421b in the second encapsulation unit 402.

Further, the preparation step of the second encapsulation unit 402 is located before the preparation steps of the third light emitting device 200c and the third encapsulation unit 403. Therefore, as shown in FIG. 4, FIG. 7 and FIG. 8, by setting that the surface of the first sub-portion 410 in the second encapsulation unit 402 away from the substrate 100 is partially connected to the third sub-portion 421b in the second encapsulation unit 402, a part of the first sub-portion 410 may provide a certain support effect to the third sub-portion 421b, so that the second encapsulation unit 402 is not easily damaged when preparing the third light emitting device 200c and the third encapsulation unit 403, thereby better improving the encapsulation stability of the second encapsulation unit 402.

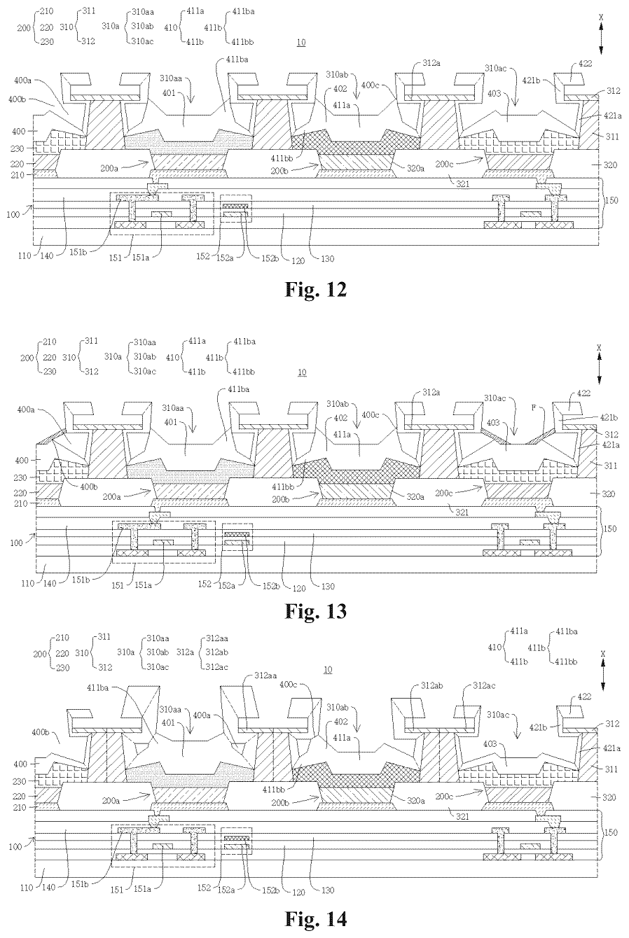

FIG. 12 is a local sectional diagram of a display panel 10 provided by another embodiment of the present application, and FIG. 12 may be a local sectional diagram of another embodiment at A-A in FIG. 1.

In other optional embodiments, as shown in FIG. 12, the gap space 400a in the second opening 310ab is an enclosed space, that is. the gap space 400a of the second encapsulation unit 402 corresponding to the second opening 310ab may be an enclosed space. For example, the first sub-portion 410 of the second encapsulation unit 402, the second sub-portion 421a of the second encapsulation unit 402 and the third sub-portion 421b of the second encapsulation unit 402 may enclose and form an enclosed gap space 400a.

Optionally, the third sub-portion 421b in the second opening 310ab is connected with the first sub-portion 410 to form the connection portion 400c, and the orthographic projection of the connection portion 400c in the second opening 310ab on the substrate 100 is in a ring shape. For example, the surface of the first sub-portion 410 of the second encapsulation unit 402 away from the substrate 100 and the surface of the third sub-portion 421b away from the first isolation portion 311 and covering the second isolation portion 312 may connect with each other, and form a ring shaped connection portion 400c.

In these optional embodiments, by setting that the first sub-portion 410 of the second encapsulation unit 402, the second sub-portion 421a of the second encapsulation unit 402 and the third sub-portion 421b of the second encapsulation unit 402 enclose and form an enclosed gap space 400a, the first sub-portion 410 in the second encapsulation unit 402 may play a better supporting role for the third sub-portion 421b, so that the second encapsulation unit 402 may have better structural stability. Thus, the second encapsulation unit 402 is not easily damaged by subsequent processes. For example, the second encapsulation unit 402 is not easily damaged when preparing the third light emitting device 200c and the third encapsulation unit 403, thereby better improving the encapsulation stability of the second encapsulation unit 402.

Further, when the subsequent film layer is prepared on the second encapsulation unit 402, the material of the subsequent film layer can be better continuous at the connection portion 400c, which can facilitate the formation of the subsequent film layer or facilitate the patterning of the subsequent film layer. Therefore, the subsequent film layer can better cover the second encapsulation unit 402, and the subsequent film layer can provide certain protection to the second encapsulation unit 402.

For example, in the subsequent preparation process of the light emitting unit 220 and the second electrode 210 of the third light emitting device 200c as well as the third encapsulation unit 403, after preparing the material of the light emitting unit 220 and the second electrode 210 of the third light emitting device 200c on the whole surface, the material of the light emitting unit 220 and the second electrode 210 of the third light emitting device 200c may be relatively continuous on the second encapsulation unit 402. Therefore, when patterning the third encapsulation unit 403 on the light emitting unit 220 and the second electrode 210 of the third light emitting device 200c, that is, when removing the material of the third encapsulation unit 403 outside of the third opening 310ac, the material of the light emitting unit 220 and the second electrode 210 of the third light emitting device 200c may be used to protect the second encapsulation unit 402 in the second opening 310ab, so that the etching material is not easy to damage the second encapsulation unit 402, thereby better improving the structural stability of the second encapsulation unit 402. Moreover, when preparing the third light emitting device 200c or the third encapsulation unit 403, the etching material is not easily accessible into the gap space 400a of the second encapsulation unit 402, thereby better reducing the etching damage of the inner wall of the gap space 400a in the second encapsulation unit 402 by the etching material, and better improving the structural stability of the second encapsulation unit.

FIG. 13 is a local sectional diagram of a display panel 10 provided by another embodiment of the present application, and FIG. 13 may be a local sectional diagram of another embodiment at A-A in FIG. 1.

As shown in FIG. 13, in some optional embodiments, when the communication opening 400b is provided on the first encapsulation structure 400, at least a part of the communication openings 400b may be provided with a sealing structure F, one side of the sealing structure F is connected to the surface of the first sub-portion 410, and the other side of the sealing structure F is connected to the surface of the third sub-portion 421b.

Optionally, the sealing structure F may fully cover the communication opening 400b, so that the communication opening 400b may be blocked by the sealing structure F. Therefore, the sealing structure F as well as the first sub-portion 410, second sub-portion 421a and third sub-portion 421b may together enclose and form an enclosed gap space 400a. Alternatively, the sealing structure F may not fully cover the communication opening 400b.

Optionally, as shown in FIG. 13, the display panel 10 may include only the sealing structure F but not the support structure P.

Optionally, the display panel 10 may simultaneously include the sealing structure F and the support structure P. For example, the support structure P may be prepared firstly, so that the material of the support structure P may enter the gap space 400a through the communication opening 400b, and then the sealing structure F may be prepared. Further, for example, under a condition that the sealing structure F is not provided to fully cover the communication opening 400b, the material of the support structure P may enter the gap space 400a through the communication opening 400b which is not covered by the sealing structure.

Optionally, the sealing structure F has a variety of material settings. For example, the material of the sealing structure F may include either an organic material or an inorganic material.

Optionally, the material of the sealing structure F may have a large viscosity, so that under a condition that the display panel 10 includes only the sealing structure F but not the support structure P, the sealing structure F may better cover the communication opening 400b, and the sealing structure F does not easily flow into the gap space 400a through the communication opening 400b.

In these optional embodiments, the sealing structure F connected between the surface of the first sub-portion 410 away from the substrate 100 and the surface of the third sub-portion 421b close to the isolation opening 310a may also be used to support the third sub-portion 421b, thereby better improving the structural stability of the first encapsulation structure 400. Further, when the subsequent film layer is prepared on the first encapsulation structure 400, the material of the subsequent film layer can be better continuous at the sealing structure F, which can facilitate the formation of the subsequent film layer or facilitate the patterning of the subsequent film layer. Therefore, the subsequent film layer can better cover the first encapsulation structure 400, and the subsequent film layer can provide certain protection to the first encapsulation structure 400.

In some embodiments of the present application, there are various ways of adjusting the relative position between the surface of the first sub-portion 410 away from the substrate 100 and the surface of the third sub-portion 421b away from the isolation structure 310. That is, there are various ways of at least partially connecting the first sub-portion 410 and the third sub-portion 421b, and there are various ways of at least partially spacing apart the first sub-portion 410 from the third sub-portion 421b and forming the communication opening 400b.

FIG. 14 is a local sectional diagram of a display panel 10 provided by another embodiment of the present application, and FIG. 14 may be a local sectional diagram of another embodiment at A-A in FIG. 1.

As shown in FIG. 14, in some optional embodiments of the present application, the relative position between the surface of the first sub-portion 410 away from the substrate 100 and the surface of the third sub-portion 421b away from the isolation structure 310 may be adjusted by changing the thickness of the first encapsulation structure 400.

In some optional embodiments, the maximum thickness of the first encapsulation structure 400 in at least one part of the isolation openings 310a is greater than the maximum thickness of the first encapsulation structure 400 in at least another part of the isolation openings 310a.

Optionally, the maximum thickness of the first encapsulation structure 400 in the isolation opening 310a may refer to the thickness of the first encapsulation structure 400 at the middle of the sub-pixel corresponding to the isolation opening 310a. For example, the maximum thickness of the first encapsulation structure 400 in the isolation opening 310a may be the thickness of the first body sub-portion 411a of the first encapsulation structure 400 in the isolation opening 310a.

Optionally, the maximum thickness of the first sub-portion 410 of the first encapsulation structure 400 in at least one part of the isolation openings 310a is greater than the maximum thickness of the first sub-portion 410 of the first encapsulation structure 400 in at least another part of the isolation openings 310a.

Optionally, the maximum thickness of the second sub-portion 421a of the first encapsulation structure 400 in at least one part of the isolation openings 310a is greater than the maximum thickness of the second sub-portion 421a of the first encapsulation structure 400 in at least another part of the isolation openings 310a.

Optionally, the maximum thickness of the third sub-portion 421b of the first encapsulation structure 400 in at least one part of the isolation openings 310a is greater than the maximum thickness of the third sub-portion 421b of the first encapsulation structure 400 in at least another part of the isolation openings 310a.

In these optional embodiments, under a condition that the thickness of the first encapsulation structure 400 at a part of the isolation openings 310a is relatively thick, the surface of the first sub-portion 410 of the part of the isolation opening 310a away from the substrate 100 may be connected with the surface of the third sub-portion 421b away from the first isolation portion 311 and covering the second isolation portion 312, so that the first sub-portion 410 at the part of the isolation openings 310a may provide a better support to the third sub-portion 421b, and the relatively thick first encapsulation structure 400 at the part of the isolation openings 310a is not easy to be damaged by etching.

Under a condition that the thickness of the first encapsulation structure 400 at a part of the isolation openings 310a is relatively thin, the surface of the first sub-portion 410 of the part of the isolation openings 310a away from the substrate 100 may be spaced apart from the surface of the third sub-portion 421b away from the first isolation portion 311 and covering the second isolation portion 312, so as to form the communication opening 400b located at a side of the gap space 400a away from the substrate 100, so that the material of the support structure P can be filled in the gap space 400a through the communication opening 400b, thereby better supporting the structure of the first encapsulation structure 400 at the part of the isolation openings 310a.

Under a condition that the thickness of the first encapsulation structure 400 at a part of the isolation opening 310a is relatively moderate, the surface of the first sub-portion 410 of the part of the isolation openings 310a away from the substrate 100 may be spaced apart from a part of the third sub-portions 421b, and the surface of the first sub-portion 410 of the part of the isolation opening 310a away from the substrate 100 may be connected with another part of the third sub-portions 421b, so that a part of the first sub-portions 410 at the part of the isolation openings 310a may provide a better support to the third sub-portion 421b, and the material of the support structure P may be filled in the gap space 400a through the communication opening 400b formed between the first sub-portion 410 and the second sub-portion 421a.

In some optional embodiments, the maximum thickness of the first encapsulation unit 401 is greater than the maximum thickness of the third encapsulation unit 403.

Optionally, the thickness of the first sub-portion 410 in the first encapsulation unit 401 may represent the maximum thickness of the first encapsulation unit 401, specifically, the thickness of the first body sub-portion 411a in the first encapsulation unit 401 may represent the maximum thickness of the first encapsulation unit 401.

Optionally, the thickness of the first sub-portion 410 in the third encapsulation unit 403 may represent the maximum thickness of the third encapsulation unit 403, specifically, the thickness of the first body sub-portion 411a in the third encapsulation unit 403 may represent the maximum thickness of the third encapsulation unit 403.

Optionally, the maximum thickness of the first sub-portion 410 of the first encapsulation unit 401 is greater than the maximum thickness of the first sub-portion 410 of the third encapsulation unit 403; and/or the maximum thickness of the second sub-portion 421a of the first encapsulation unit 401 is greater than the maximum thickness of the second sub-portion 421a of the third encapsulation unit 403; and/or the maximum thickness of the third sub-portion 421b of the first encapsulation unit 401 is greater than the maximum thickness of the third sub-portion 421b of the third encapsulation unit 403.

In these optional embodiments, by setting that the maximum thickness of the first encapsulation unit 401 is greater than the maximum thickness of the third encapsulation unit 403, in the preparation process of the display panel 10, the first encapsulation unit 401 is not easily damaged by the subsequent etching process. For example, the first encapsulation unit 401 is not easily damaged by the etching material during the etching process of the second light emitting device 200b, the second encapsulation unit 402, the third light emitting device 200c, and the third encapsulation unit 403, so that the encapsulation stability of the first encapsulation unit 401 can be better improved. At the same time, it is also possible to realize that the first sub-portion 410 of the first encapsulation unit 401, the second sub-portion 421a of the first encapsulation unit 401 and the third sub-portion 421b of the first encapsulation unit 401 enclose and form an enclosed gap space 400a, so that the first sub-portion 410 of the first encapsulation unit 401 may play a better supporting role on the third sub-portion 421b, and the first encapsulation unit 401 may have a better structural stability. Moreover, it is also possible to realize that the surface of the first sub-portion 410 of the third encapsulation unit 403 away from the substrate 100 and the surface of a part of the third sub-portions of the third encapsulation unit 403 away from the isolation structure 310 are spaced apart, so as to form the communication opening 400b located at a side of the gap space 400a away from the substrate 100, so that the material of the support structure P can be filled into the gap space 400a of the third encapsulation unit 403 through the communication opening 400b.

In some optional embodiments, the maximum thickness of the second encapsulation unit 402 is greater than or equal to the maximum thickness of the third encapsulation unit 403; and/or, the maximum thickness of the second encapsulation unit 402 is less than or equal to the maximum thickness of the first encapsulation unit 401.

Optionally, the thickness of the first sub-portion 410 in the second encapsulation unit 402 may represent the maximum thickness of the second encapsulation unit 402, specifically, the thickness of the first body sub-portion 411a in the second encapsulation unit 402 may represent the maximum thickness of the second encapsulation unit 402.

For example, as shown in FIG. 14, the maximum thickness of the second encapsulation unit 402 may be greater than the maximum thickness of the third encapsulation unit 403, and the maximum thickness of the second encapsulation unit 402 may be less than the maximum thickness of the first encapsulation unit 401. Here, by setting that the maximum thickness of the second encapsulation unit 402 is greater than the maximum thickness of the third encapsulation unit 403, in the preparation process of the display panel 10, the second encapsulation unit 402 is not easily damaged by the etching material during the etching process of the third light emitting device 200c and the third encapsulation unit 403, thereby better improving the encapsulation stability of the second encapsulation unit 402. By setting that the maximum thickness of the second encapsulation unit 402 is less than the maximum thickness of the first encapsulation unit 401, it is possible to realize that the surface of the first sub-portion 410 of the second encapsulation unit 402 away from the substrate 100 may be spaced apart from one part of the third sub-portions 421b of the second encapsulation unit 402, and the surface of the first sub-portion 410 of the second encapsulation unit 402 away from the substrate 100 may be connected with another part of the third sub-portions 421b of the second encapsulation unit 402, so as to achieve the beneficial effect similar to the second encapsulation unit 402 having a similar structure in the aforementioned embodiments, which will not be repeated in the present application.

Alternatively, for example, the maximum thickness of the second encapsulation unit 402 may be equal to the maximum thickness of the first encapsulation unit 401 (not shown), so that the structure of the second encapsulation unit 402 may be similar as the structure of the first encapsulation unit 401. Therefore, the second encapsulation unit 402 is not easily damaged by the etching material during the etching process of the third light emitting device 200c and the third encapsulation unit 403, and it is also possible to realize that the first sub-portion 410 of the second encapsulation unit 402, the second sub-portion 421a of the second encapsulation unit 402 and a third sub-portion 421b of the second encapsulation unit 402 enclose and form an enclosed gap space 400a, so as to achieve the beneficial effect similar to the first encapsulation unit 401 having a similar structure in the aforementioned embodiments, which will not be repeated in the present application.

Alternatively, for example, the maximum thickness of the second encapsulation unit 402 may be equal to the maximum thickness of the third encapsulation unit 403 (not shown), so that the structure of the second encapsulation unit 402 may be similar as the structure of the third encapsulation unit 403. Therefore, the surface of the first sub-portion 410 in the second encapsulation unit 402 away from the substrate 100 may be spaced apart from the third sub-portion 421b in the second encapsulation unit 402, so as to form the ring shaped communication opening 400b located at the side of the gap space 400a away from the substrate 100, thereby achieving the beneficial effect similar to the third encapsulation unit 403 having a similar structure in the aforementioned embodiments, which will not be repeated in the present application.

In some optional embodiments, a first spacing is provided between a surface of the protruding portion 312a facing the substrate 100 and a surface of the pixel limiting portion 321 away from the substrate 100, and a ratio of a maximum thickness of at least a part of the first body sub-portion 411a to the first spacing is not less than 1.25; and/or, a ratio of a maximum thickness of at least a part of the second body sub-portion 411b to the first spacing is not less than 1.25.

Optionally, the maximum thickness of the first body sub-portion 411a may be slightly greater than the maximum thickness of the second body sub-portion 411b.

Optionally, the ratio of the maximum thickness of the first body sub-portion 411a to the first spacing is 1.5-2.5. Further optionally, the ratio of the maximum thickness of the first body sub-portion 411a to the first spacing may be 1.6-2.

Optionally, the second body sub-portion 411b includes a first body subpart 411ba and a second body subpart 411bb that are interconnected, the orthographic projection of the first body subpart 411ba on the substrate 100 is located outside the orthographic projection of the second isolation portion 312 on the substrate 100, and the orthographic projection of the second body subpart 411bb on the substrate 100 is located within the orthographic projection of the second isolation portion 312 on the substrate 100.

Optionally, the first sub-portion 410 being connected to the third sub-portion 421b may mean that the first body subpart 411ba is connected to the third sub-portion 421b.

Optionally, the maximum thickness of the second body sub-portion 411b may be the maximum thickness of the first body subpart 411ba, and the ratio of the maximum thickness of the first body subpart 411ba to the first spacing is not less than 1.25.

Optionally, the ratio of the maximum thickness of at least a part of the first body sub-portion 411a of the first encapsulation unit 401 to the first spacing is not less than 1.25; and/or the ratio of the maximum thickness of at least a part of the second body sub-portion 411b of the first encapsulation unit 401 to the first spacing is not less than 1.25.

Optionally, the protruding portion 312a includes a first protruding portion 312aa corresponding to the first opening 310aa and a third protruding portion 312ac corresponding to the third opening 310ac. Optionally, the first protruding portion 312aa may participate in the enclosure and formation of the first opening 310aa. Optionally, the third protruding portion 312ac may participate in the enclosure and formation of the third opening 310ac.

Specifically, the first spacing may refer to a spacing between the surface of the first protruding portion 312aa facing the substrate 100 and the surface of the pixel limiting portion 321 away from the substrate 100. The ratio of the maximum thickness of the first body sub-portion 411a of the first encapsulation unit 401 to the first spacing corresponding to the first protruding portion 312aa is not less than 1.25, and/or the ratio of the maximum thickness of the second body sub-portion 411b of the first encapsulation unit 401 to the first spacing corresponding to the first protruding portion 312aa is not less than 1.25.

Optionally, the ratio of the maximum thickness of at least a part of the first body sub-portion 411a of the second encapsulation unit 402 to the first spacing is not less than 1.25; and/or the ratio of the maximum thickness of at least a part of the second body sub-portion 411b of the second encapsulation unit 402 to the first spacing is not less than 1.25.

Optionally, the protruding portion 312a further includes a second protruding portion 312ab corresponding to the second opening 310ab. Optionally, the second protruding portion 312ab may participate in the enclosure and formation of the second opening 310ab.

Specifically, the first spacing may also refer to a spacing between the surface of the second protruding portion 312ab facing the substrate 100 and the surface of the pixel limiting portion 321 away from the substrate 100. The ratio of the maximum thickness of the first body sub-portion 411a of the second encapsulation unit 402 to the first spacing corresponding to the second protruding portion 312ab is not less than 1.25, and/or the ratio of the maximum thickness of the second body sub-portion 411b of the second encapsulation unit 402 to the first spacing corresponding to the second protruding portion 312ab is not less than 1.25.

Here, the spacing between the surface of the first protruding portion 312aa facing the substrate 100 and the surface of the pixel limiting portion 321 away from the substrate 100 may be equal to the spacing between the surface of the second protruding portion 312ab facing the substrate 100 and the surface of the pixel limiting portion 321 away from the substrate 100, or the spacing between the surface of the first protruding portion 312aa facing the substrate 100 and the surface of the pixel limiting portion 321 away from the substrate 100 may not be equal to the spacing between the surface of the second protruding portion 312ab facing the substrate 100 and the surface of the pixel limiting portion 321 away from the substrate 100, which is no specifically limited in the present application.

In these optional embodiments, by reasonably setting the ratio of the maximum thickness of the first body sub-portion 411a to the first spacing, and reasonably setting the ratio of the maximum thickness of the second body sub-portion 411b to the first spacing, the thicknesses of at least a part of the first body sub-portion 411a and at least a part of the second body sub-portion 411b in the first encapsulation structure 400 may be better adjusted in accordance with the blocking capability of the protruding portion 312a to the first encapsulation structure 400, thereby achieving that the first sub-portion of 410 of at least a part of the first encapsulation structure 400 may be connected to the third sub-portion 421b, and achieving the support of the first sub-portion 410 for the third sub-portion 421b.

Specifically, under a condition that the first spacing is relatively large, in the process of preparing the first encapsulation structure 400, the protruding portion 312a will be relatively close to the preparation apparatus of the first encapsulation structure 400, so that the protruding portion 312a has a great blocking influence on the material of the first encapsulation structure 400, that is, the protruding portion 312a can have a better blocking capability. Therefore, according to the relatively large first spacing, at least a part of the first body sub-portion 411a and at least a part of the second body sub-portion 411b may be set to have a relatively large thickness, thereby facilitating the connection of at least a part of the first sub-portion 410 with the third sub-portion 421b, and achieving the support of the first sub-portion 410 for the third sub-portion 421b.

Under a condition that the first spacing is relatively small, in the process of preparing the first encapsulation structure 400, the protruding portion 312a will be relatively away from the preparation apparatus of the first encapsulation structure 400, so that the protruding portion 312a has a little blocking influence on the material of the first encapsulation structure 400, that is, the protruding portion 312a has a poor blocking capability for the first encapsulation structure 400. Therefore, according to the relatively small first spacing, at least a part of the first body sub-portion 411a and at least a part of the second body sub-portion 411b may be set to have a reasonable thickness, thereby facilitating the connection of at least a part of the first sub-portion 410 with the third sub-portion 421b, and at the same time, it is not easy to increase the thickness of the display panel 10.

Here, there are various ways of regulating the first spacing, for example, the first spacing can be adjusted by adjusting the size of the first isolation portion 311 in the thickness direction.

In some optional embodiments, the size of the first isolation portion 311 in the thickness direction of the display panel 10 is a first height, the ratio of the maximum thickness of at least a part of the first body sub-portion 411a to the first height is not less than 1, so as to achieve that the ratio of the maximum thickness of at least a part of the first body sub-portion 411a to the first spacing is not less than 1.25, or, the ratio of the maximum thickness of at least a part of the second body sub-portion 411b to the first height is not less than 1, so as to achieve that the ratio of the maximum thickness of at least a part of the second body sub-portion 411b to the first spacing is not less than 1.25.

Optionally, the first height may also refer to the maximum spacing between the surface of the first isolation portion 311 facing the substrate 100 and the surface of the first isolation portion 311 away from the substrate 100. Optionally, the first height may be equal to the first spacing.

Optionally, the maximum thickness of the first body sub-portion 411a may be slightly greater than the maximum thickness of the second body sub-portion 411b.

Optionally, the ratio of the maximum thickness of at least a part of the first body sub-portion 411a to the first height is not less than 1.4. Further optionally, the ratio of the maximum thickness of at least a part of the first body sub-portion 411a to the first height is not less than 1.617, and/or the ratio of the maximum thickness of at least a part of the second body sub-portion 411b to the first height is not less than 1.389.

In some optional embodiments, a second spacing is provided between the surface of the protruding portion 312a facing the substrate 100 and the surface of the light emitting device 200 away from the substrate 100, the ratio of the maximum thickness of at least a part of the first body sub-portion 411a to the second spacing is not less than 1, and/or the ratio of the maximum thickness of at least a part of the second body sub-portion 411b to the second spacing is not less than 1.

Optionally, at least a part of the light emitting devices 200 may be located at the side of the pixel limiting portion 321 away from the substrate 100, and a second spacing is provided between the surface of the protruding portion 312a facing the substrate 100 and the surface of the light emitting device 200 located on the pixel limiting portion 321 away from the substrate 100.

Optionally, the ratio of the maximum thickness of at least a part of the first body sub-portion 411a of the first encapsulation unit 401 to the second spacing is not less than 1; and/or the ratio of the maximum thickness of at least a part of the second body sub-portion 411b of the first encapsulation unit 401 to the second spacing is not less than 1.

Specifically, the second spacing may refer to a spacing between the surface of the first protruding portion 312aa facing the substrate 100 and the surface of the light emitting device 200 away from the substrate 100. The ratio of the maximum thickness of the first body sub-portion 411a of the first encapsulation unit 401 to the second spacing corresponding to the first protruding portion 312aa is not less than 1, and/or the ratio of the maximum thickness of the second body sub-portion 411b of the first encapsulation unit 401 to the second spacing corresponding to the first protruding portion 312aa is not less than 1.

Optionally, the ratio of the maximum thickness of at least a part of the first body sub-portion 411a of the second encapsulation unit 402 to the second spacing is not less than 1; or the ratio of the maximum thickness of at least a part of the second body sub-portion 411b of the second encapsulation unit 402 to the second spacing is not less than 1.

Specifically, the second spacing may also refer to a spacing between the surface of the second protruding portion 312ab facing the substrate 100 and the surface of the pixel limiting portion 321 away from the substrate 100. The ratio of the maximum thickness of the first body sub-portion 411a of the second encapsulation unit 402 to the second spacing corresponding to the second protruding portion 312ab is not less than 1, and/or the ratio of the maximum thickness of the second body sub-portion 411b of the second encapsulation unit 402 to the second spacing corresponding to the second protruding portion 312ab is not less than 1.

Here, the spacing between the surface of the first protruding portion 312aa facing the substrate 100 and the surface of the light emitting device 200 away from the substrate 100 may be equal to the spacing between the surface of the second protruding portion 312ab facing the substrate 100 and the surface of the light emitting device 200 away from the substrate 100, or the spacing between the surface of the first protruding portion 312aa facing the substrate 100 and the surface of the light emitting device 200 away from the substrate 100 may not be equal to the spacing between the surface of the second protruding portion 312ab facing the substrate 100 and the surface of the light emitting device 200 away from the substrate 100, which is no specifically limited in the present application.

In these optional embodiments, the thickness of the light emitting device 200 located on the pixel limiting portion 321 can affect the spacing between the first sub-portion 410 and the protruding portion 312a. That is, the thickness of the light emitting device 200 located on the pixel limiting portion 321 can affect the spacing between the first sub-portion 410 and the third sub-portion 421b covering the protruding portion 312a. Therefore, by further defining the ratio of the maximum thickness of the first body sub-portion 411a to the second spacing, and reasonably setting the ratio of the maximum thickness of the second body sub-portion 411b to the second spacing, the thickness of at least a part of the first body sub-portion 411a and at least a part of the second body sub-portion 411b in the first encapsulation structure 400 may be adjusted more accurately according to the spacing between the protruding portion 312a and the light emitting device 200, thereby achieving that the first sub-portion of 410 of at least a part of the first encapsulation structure 400 may be connected to the third sub-portion 421b, and achieving the support of the first sub-portion 410 for the third sub-portion 421b.

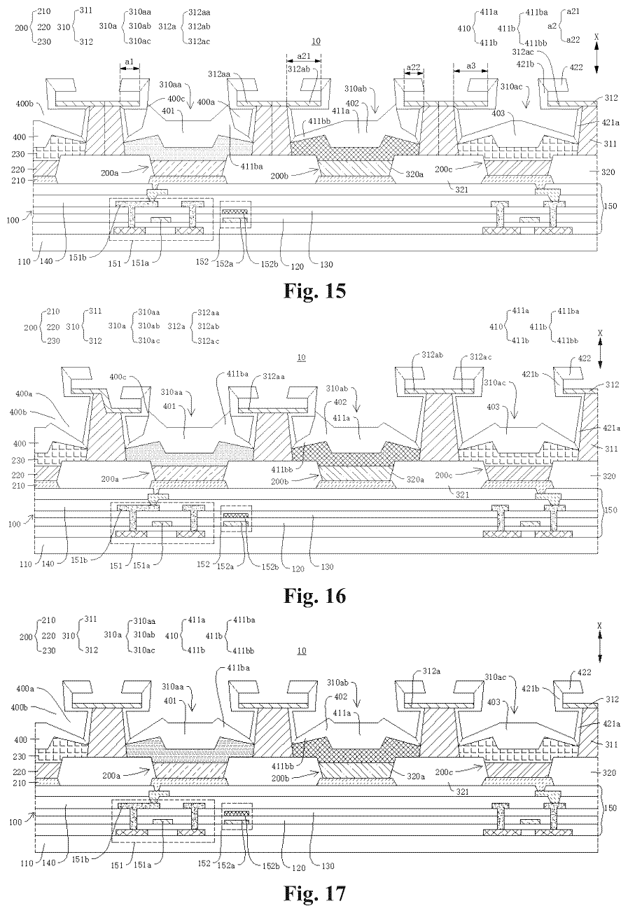

FIG. 15 is a local sectional diagram of a display panel 10 provided by another embodiment of the present application, and FIG. 15 may be a local sectional diagram of another embodiment at A-A in FIG. 1.

As shown in FIG. 15, in some optional embodiments of the present application, the relative position between the surface of the first sub-portion 410 away from the substrate 100 and the surface of the third sub-portion 421b away from the isolation structure 310 may be adjusted by changing the morphology of the isolation structure 310.

In some optional embodiments, a protruding length of the protruding portion 312a disposed corresponding to one part of the isolation openings 310a is greater than a protruding length of the protruding portion 312a disposed corresponding to the other part of the isolation openings 310a.

Optionally, the protruding length of the projection portion 312a may refer to a spacing between the orthographic projection of the edge of the projection portion 312a facing the isolation opening 310a on the substrate 100 and the orthographic projection of the surface of the first isolation portion 311 away from the substrate 100 on the substrate 100.

Optionally, the protruding portion 312a provided corresponding to the isolation opening 310a may refer to a protruding portion 312a which participates in the enclosure and formation of the isolation opening 310a.

In these optional embodiments, by reasonable setting that the protruding lengths of the protruding portions 312a disposed corresponding to different isolation openings 310a are different, in the preparation process of the display panel 10, the protruding portion 312a having a relatively long protruding length in a part of the isolation openings 312a has a better blocking capacity, and the protruding portion 312a having a relatively short protruding length in the other part of the isolation openings 312a has a small blocking capacity.

Therefore, when preparing the first encapsulation structure 400, the protruding portion 312a having a relatively long protruding length in a part of the isolation openings 312a may better block the material of the first encapsulation structure 400, so that the surface of the first sub-portion 410 in the part of the isolation opening 310a away from the substrate 100 is not easily to be connected with the surface of the third sub-portion 421b away from the first isolation portion 311, and the third sub-portion 421b may be spaced apart from the first sub-portion 410, which is facilitate to form the communication opening 400b located at a side of the gap space 400a away from the substrate opening 100 in the part of the isolation opening 310a.

The protruding portion 312a having a relatively short protruding length in the other part of the isolation openings 312a is not easily to cause a large blocking effect on the material of the first encapsulation structure 400, so that the surface of the first sub-portion 410 in the other part of the isolation opening 310a away from the substrate 100 is easily to be connected with the surface of the third sub-portion 421b away from the first isolation portion 311, and the first sub-portion 410 may play a better supporting role for the third sub-portion 421b, thereby improving the encapsulation effect of the first encapsulation structure 400 on the display panel 10.

In some optional embodiments, the protruding length of the first protruding portion 312aa is less than the protruding length of the third protruding portion 312ac, that is, the protruding length of the side of the second isolation portion 312 facing the first opening 310aa relative to the first isolation portion 311 is less than the protruding length of the side of the second isolation portion 312 facing the third opening 310ac relative to the first isolation portion 311.

Optionally, the protruding length of the first protruding portion 312aa may refer to a minimum spacing between the orthographic projection of the edge of the first protruding portion 312aa facing the first opening 310aa on the substrate 100 and the orthographic projection of the surface of the first isolation portion 311 facing the first protruding portion 312aa on the substrate 100. Optionally, the length of a1 in FIG. 15 may represent the protruding length of the first protruding portion 312aa.

Optionally, the protruding length of the third protruding portion 312ac may refer to a minimum spacing between the orthographic projection of the edge of the third protruding portion 312ac facing the third opening 310ac on the substrate 100 and the orthographic projection of the surface of the first isolation portion 311 facing the third protruding portion 312ac on the substrate 100. Optionally, the length of a3 in FIG. 15 may represent the protruding length of the third protruding portion 312ac.)

In these optional embodiments, under the small blocking influence provided by the first protruding portion 312aa having a relatively short protruding length, the first sub-portion 410 of the first encapsulation unit 401, the second sub-portion 421a of the first encapsulation unit 401 and the third sub-portion 421b of the first encapsulation unit 401 at the first opening 310aa may enclose and form an enclosed gap space 400a, so that the first sub-portion 410 in the first encapsulation unit 401 may play a better supporting role for the third sub-portion 421b, and the first encapsulation unit 401 may have better structural stability. Thus, the first encapsulation unit 401 is not easily damaged by the subsequent process.

Under the large blocking influence provided by the third protruding portion 312ac having a relatively long protruding length, the surface of the first sub-portion 410 in the third encapsulation unit 403 at the third opening 310ac away from the substrate 100 may be spaced apart from the third sub-portions 421b in the third encapsulation unit 403, so as to form a ring shaped communication opening 400a located at the side of the gap space 400a away from the substrate 100, so that the material of the support structure P can be filled into the gap space 400a of the third encapsulation unit 403 through the communication opening 400b, thereby better supporting the third encapsulation unit 403.

In some optional embodiments, the protruding length of the second protruding portion 312ab is less than or equal to the protruding length of the third protruding portion 312ac; and/or the protruding length of the second protruding portion 312ab is greater than or equal to the protruding length of the first protruding portion 312aa.

That is, the protruding length of the second isolation portion 312 facing the second opening 310ab relative to the first isolation portion 311 is less than or equal to the protruding length of the second isolation portion 312 facing the third opening 310ac relative to the first isolation portion 311, and/or the protruding length of the second isolation portion 312 facing the second opening 310ab relative to the first isolation portion 311 is greater than or equal to the protruding length of the second isolation portion 312 facing the first opening 310aa relative to the first isolation portion 311.

Optionally, the protruding length of the second protruding portion 312ab may refer to a minimum spacing between the orthographic projection of the edge of the second protruding portion 312ab facing the second opening 310ab on the substrate 100 and the orthographic projection of the surface of the first isolation portion 311 facing the second protruding portion 312ab on the substrate 100.

Optionally, the length of a2 in FIG. 15 may represent the protruding length of the second protruding portion 312ab. Here, a2 may include a21 and a22. Specifically, when the protruding length of the second protruding portion 312ab is greater than or equal to the protruding length of the first protruding portion 312aa, the length of a21 may represent the protruding length of the second protruding portion 312ab; when the protruding length of the second protruding portion 312ab is less than or equal to the protruding length of the third protruding portion 312ac, the length of a22 may represent the protruding length of the second protruding portion 312ab.

In some embodiments, as shown in FIG. 15, the protruding length of one part of the second protruding portions 312ab may be equal to the protruding length of the third protruding portion 312ac, and the protruding length of the other part of the second protruding portions 312ab may be equal to the protruding length of the first protruding portion 312aa. Therefore, under the large blocking influence provided by one part of the second protruding portions 312ab having a relatively long protruding length, the third sub-portion 421b in the second encapsulation unit 402 may be spaced apart from a part of the first sub-portion 410, so as to form the communication opening 400b located at a side of the gap space 400a away from the substrate 100 on the second encapsulation unit 402, so that the material of the support structure P can be filled into the gap space 400a of the second encapsulation unit 402 through the communication opening 400b, thereby better supporting the structure of the second encapsulation unit 402. Further, under the small blocking influence provided by the other part of the second protruding portion 312ab having a relatively short protruding length, the third sub-portion 421b in the second encapsulation unit 402 may be interconnected with a part of the first sub-portion 410, so that the part of the first sub-portion 410 in the second encapsulation unit 402 may provide certain support to the third sub-portion 421b. Therefore, the second encapsulation unit 402 is not easily damaged during the preparation of the third light emitting device 200c and the third encapsulation unit 403, and thus the encapsulation stability of the second encapsulation unit 402 can be better improved.

In other embodiments, the protruding length of the second protruding portion 312ab may be less than the protruding length of the third protruding portion 312ac, and the protruding length of the second protruding portion 312ab may be equal to the protruding length of the first protruding portion 312aa. Therefore, under the large blocking influence provided by the second protruding portions 312ab having a relatively long protruding length, the structure of the second encapsulation unit 402 at the second opening 310ab may be similar as the structure of the first encapsulation unit 401 in the first opening 310aa, so that the first sub-portion 410 of the second encapsulation unit 402, the second sub-portion 421a of the second encapsulation unit 402 and the third sub-portion 421b of the second encapsulation unit 402 can enclose and form an enclosed gap space 400a, thereby achieving the beneficial effect similar to the first encapsulation unit 401 having a similar structure in the aforementioned embodiments, which will not be repeated in the present application.

In other embodiments, the protruding length of the second protruding portion 312ab may be equal to the protruding length of the third protruding portion 312ac, and the protruding length of the second protruding portion 312ab may be greater than the protruding length of the first protruding portion 312aa. Therefore, under the small blocking influence provided by the second protruding portion 312ab having a relatively short protruding length, the structure of the second encapsulation unit 402 at the second opening 310ab may be similar as the structure of the third encapsulation unit 403 in the third opening 310ac, so that the surface of the first sub-portion 410 in the second encapsulation unit 402 at the second opening 310ab away from the substrate 100 may be spaced apart from the third sub-portions 421b in the second encapsulation unit 402, so as to form a ring shaped communication opening 400b located at a side of the gap space 400a away from the substrate 100, thereby achieving the beneficial effect similar to the third encapsulation unit 403 having a similar structure in the aforementioned embodiments, which will not be repeated in the present application.

In some optional embodiments, the ratio of the protruding length of at least a part of the protruding portion 312a to the first height is not greater than 1.25.

Optionally, the ratio of the protruding length of the first protruding portion 312aa to the first height is not greater than 1.25, or the ratio of the protruding length of at least a part of the second protruding portion 312ab to the first height is not greater than 1.25.

In these optional embodiments, by setting that the ratio of the protruding length of at least a part of the protruding portion 312a to the first height is not greater than 1.25, that is, by reasonably limiting the protruding length of a part of the protruding portion 312a according to the size of the first isolation portion 311, the protruding length of at least a part of the protruding portion 312a is not too large relative to the height of the first isolation portion 311. Therefore, the part of the protruding portion 312a has a small blocking effect on the material of the first encapsulation structure 400, which can facilitate the connection of the first sub-portion 410 and the third sub-portion 421b in the isolation opening 310a corresponding to the part of the protruding portion 312a, that is, it can facilitate that the first sub-portion 410 in the isolation opening 310a corresponding to the part of the protruding portion 312a provides a better support effect to the third sub-portion 421b, thereby enhancing the structural stability of the first encapsulation structure 400 in the isolation opening 310a.

For example, under a condition that the ratio of the protruding length of the first protruding portion 312aa to the first height is not greater than 1.25, under the small blocking influence provided by the first protruding portion 312aa having a short protruding length relative to the height of the first isolation portion 311, it can facilitate the connection of the first sub-portion 410 in the first opening 310aa to the third sub-portion 421b, that is, it can facilitate that the first sub-portion 410 in the first opening 310aa provides a better support effect to the third sub-portion 421b, thereby enhancing the structural stability of the first encapsulation structure 400 in the first opening 310a.

For example, under a condition that the ratio of the protruding length of at least a part of the second protruding portion 312ab to the first height is not greater than 1.25, under the small blocking influence provided by the second protruding portion 312ab having a short protruding length relative to the height of the first isolation portion 311, it can facilitate the connection of at least a part of the first sub-portion 410 in the second opening 310ab to the third sub-portion 421b, that is, it can facilitate that the first sub-portion 410 in the second opening 310ab provides a better support effect to the third sub-portion 421b, thereby enhancing the structural stability of the first encapsulation structure 400 in the second opening 310ab.

FIG. 16 is a local sectional diagram of a display panel 10 provided by another embodiment of the present application, and FIG. 16 may be a local sectional diagram of another embodiment at A-A in FIG. 1.

As shown in FIG. 16, in some optional embodiments, a spacing between the substrate 100 and at least a part of the second isolation portion 312 involved in enclosing and forming the first opening 310aa is less than a spacing between the substrate 100 and the second isolation portion 312 involved in enclosing and forming the third opening 310ac.

Optionally, the spacing between the second isolation portion 312 and the substrate 100 may refer to a spacing between a surface of the second isolation portion 312 facing the substrate 100 and the substrate 100.

Optionally, the spacing between the first protruding portion 312aa and the substrate 100 may be less than the spacing between the third protruding portion 312ac and the substrate 100.

In these optional embodiments, by setting that the spacing between the substrate 100 and at least a part of the second isolation portion 312 involved in enclosing and forming the first opening 310aa is less than the spacing between the substrate 100 and the second isolation portion 312 involved in enclosing and forming the third opening 310ac, in the preparation process of the first encapsulation structure 400, compared to the first protruding portion 312aa, the third protruding portion 312ac can be closer to the preparation apparatus of the first encapsulation structure 400, so that the first protruding portion 312aa has a small blocking effect on the material of the first encapsulation structure 400, which can facilitate the connection of the first sub-portion 410 in the first opening 310aa to the third sub-portion 421b, that is, it can facilitate that the first sub-portion 410 in the first opening 310aa provides a better support effect to the third sub-portion 421b, thereby enhancing the structural stability of the first encapsulation structure 400 in the first opening 310a. Moreover, the third protruding portion 312ac has a large blocking effect on the material of the first encapsulation structure 400, which can facilitate that the first sub-portion 410 in the third opening 310ac is at least partially spaced apart from the third sub-portion 421b to form the communication opening 400b, so that the material of the support structure P can be subsequently filled into the gap space 400a of the third encapsulation unit 403 through the communication opening 400b, thereby better supporting the third encapsulation unit 403.

Here, there are various ways of regulating the spacing between the second isolation portion 312 and the substrate 100. For example, the spacing between the second isolation portion 312 and the substrate 100 may be adjusted by adjusting the size of the first isolation portion 311 in the thickness direction.

Optionally, the size of at least a part of the first isolation portion 311 involved in enclosing and forming the first opening 310aa in the thickness direction of the display panel 10 may be smaller than the size of the first isolation portion 311 involved in enclosing and forming the third opening 310ac in the thickness direction of the display panel 10, which can facilitate to realize that the spacing between the substrate 100 and at least a part of the second isolation portion 312 involved in enclosing and forming the first opening 310aa is less than the spacing between the substrate 100 and the second isolation portion 312 involved in enclosing and forming the third opening 310ac.

In some optional embodiments, the spacing between the substrate 100 and at least a part of the second isolation portion 312 involved in enclosing and forming the second opening 310ab is greater than or equal to the spacing between the substrate 100 and the second isolation portion 312 involved in enclosing and forming the first opening 310aa; and/or, the spacing between the substrate 100 and at least a part of the second isolation portion 312 involved in enclosing and forming the second opening 310ab is less than or equal to the spacing between the substrate 100 and the second isolation portion 312 involved in enclosing and forming the third opening 310ac.

Optionally, the spacing between at least a part of the second protruding portion 312ab and substrate 100 is greater than or equal to the spacing between the first protruding portion 312aa and substrate 100; and/or the spacing between at least a part of the second protruding portion 312ab and substrate 100 is less than or equal to the spacing between the third protruding portion 312ac and substrate 100.

Optionally, the size of at least a part of the first isolation portion 311 involved in enclosing and forming the second opening 310ab in the thickness direction of the display panel 10 is greater than or equal to the size of the first isolation portion 311 involved in enclosing and forming the first opening 310aa in the thickness direction of the display panel 10, so as to facilitate to realize that the spacing between the substrate 100 and at least a part of the second isolation portion 312 involved in enclosing and forming the second opening 310ab is greater than or equal to the spacing between the substrate 100 and the second isolation portion 312 involved in enclosing and forming the first opening 310aa; and/or, the size of at least a part of the first isolation portion 311 involved in enclosing and forming the second opening 310ab in the thickness direction of the display panel 10 is less than or equal to the size of the first isolation portion 311 involved in enclosing and forming the third opening 310ac in the thickness direction of the display panel 10, so as to facilitate to realize that the spacing between the substrate 100 and at least a part of the second isolation portion 312 involved in enclosing and forming the second opening 310ab is less than or equal to the spacing between the substrate 100 and the second isolation portion 312 involved in enclosing and forming the third opening 310ac.

In these optional embodiments, the spacing between at least a part of the second protruding portion 312ab and the substrate 100 may be between the spacing between the first protruding portion 312aa and the substrate 100 and the spacing between the third protruding portion 312ac and the substrate 100, or, the spacing between at least a part of the second protruding portion 312ab and the substrate 100 may be equal to the spacing between the first protruding portion 312aa and the substrate 100, or, the spacing between at least a part of the second protruding portion 312ab and the substrate 100 may be equal to the spacing between the third protruding portion 312ac and the substrate 100. For easy of description, it is illustrated that the spacing between one part of the second protruding portion 312ab and the substrate 100 may be equal to the spacing between the first protruding portion 312aa and the substrate 100, and the spacing between another part of the second protruding portion 312ab and the substrate 100 may be equal to the spacing between the third protruding portion 312ac and the substrate 100.

In the preparation process of the first encapsulation structure 400, a part of the second protruding portion 312ab having a large spacing from the substrate 100 may be closer to the preparation apparatus of the first encapsulation structure 400, so that the part of the second protruding portion 312ab has a large blocking influence on the material of the first encapsulation structure 400, which can facilitate that the first sub-portion 410 in the third opening 310ac is at least partially spaced apart from the third sub-portion 421b to form the communication opening 400b. Therefore, the material of the support structure P can be subsequently filled into the gap space 400a of the third encapsulation unit 403 through the communication opening 400b, thus better supporting the third encapsulation unit 403. Further, another part of the second protruding portion 312ab having a small spacing from the substrate 100 may be further away from the preparation apparatus of the first encapsulation structure 400, so that the another part of the second protruding portion 312ab has a small blocking influence on the material of the first encapsulation structure 400, which can facilitate the connection of a part of the first sub-portion 410 in the second opening 310ab to the third sub-portion 421b, that is, it can facilitate that the part of the first sub-portion 410 in the second opening 310ab provides a better support effect to the third sub-portion 421b, thereby enhancing the structural stability of the first encapsulation structure 400 in the second opening 310ab.

FIG. 17 is a local sectional diagram of a display panel 10 provided by another embodiment of the present application.

Referring to FIG. 1 to FIG. 17, the embodiments of the first aspect of the present application also provide a display panel 10, including: a substrate 100; an isolation structure 310 disposed on a side of the substrate 100 and enclosing and forming a plurality of isolation openings 310a, the isolation structure 310 including a first isolation portion 311 and a second isolation portion 312 located on a side of the first isolation portion 311 away from the substrate 100, the second isolation portion 312 having a protruding portion 312a protruding from the first isolation portion 311 towards the isolation opening 310a; a plurality of light emitting devices 200, at least a part of a structure of the light emitting device 200 is located within the isolation opening 310a, the light emitting device 200 including a light emitting unit 220 and a first electrode 230 located on a side of the light emitting unit 200 away from the substrate 100; a first encapsulation structure 400 disposed on a side of the light emitting device 200 away from the substrate 100, the first encapsulation structure 400 including a first sub-portion 410, a second sub-portion 412a and a third sub-portion 412b, the first sub-portion 410 covering on the side of the light emitting device 200 away from the substrate 100, the second sub-portion 412a covering on a side of the first isolation portion 311 facing the isolation opening 310a, the third sub-portion 412b being at least partially located on a side of the second isolation portion 312 facing the substrate 100 and being at least partially attached on the protruding portion 312a, the first sub-portion 410, the second sub-portion 412a and the third sub-portion 412b enclosing and forming a gap space 400a, and the first sub-portion 410 and the third sub-portion 412b in at least a part of the isolation openings 310a being at least partially spaced apart and forming a communication opening 400b, wherein a minimum size of the communication opening 400b in a thickness direction of the display panel 10 is less than or equal to a product of a sum of thicknesses of the light emitting unit 220 and the first electrode 230 of at least a part of the light emitting devices 200 and a sealing coefficient.

In the display panel 10 provided by the embodiments of the present application, the display panel 10 includes the substrate 100, the isolation structure 310, the light emitting devices 200, and the first encapsulation structure 400. The isolation structure 310 is disposed on a side of the substrate 100 and encloses and forms a plurality of isolation openings 310a, at least a part of the light emitting device 200 is located within the isolation opening 310a, and the isolation structure 310 can be used to divide the sub-pixels of the display panel 10. The isolation structure 310 includes the first isolation portion 311 and the second isolation portion 312 located on the side of the first isolation portion 311 away from the substrate 100, the second isolation portion 312 has the protruding portion 312a protruding from the first isolation portion 311 towards the isolation opening 310a. Therefore, when preparing the light emitting device 200 of the display panel 10, at least a part of the material of the light emitting device 200 can be directly evaporated on the whole surface, the protruding portion 312a of the second isolation portion 312 can block at least a part of the material for preparing the light emitting device 200, so as to separate the material of the light emitting devices 200 in the adjacent sub-pixels, thereby facilitating the formation of the plurality of light emitting devices 200 that are spaced apart and located within the isolation openings 310a. Therefore, there is no need to set the mask with high precision when preparing the light emitting devices 200 of the display panel 10, for example, there is no need to set setting the fine metal mask when evaporating the material of the light emitting device 200. Thus, the production and preparation cost of the display panel 10 can be better reduced. Here, the different light emitting devices 200 can be more independently prepared using the isolation structure 310.

The first encapsulation structure 400 is disposed on the side of the light emitting device 200 away from the substrate 100, and the first encapsulation structure 400 may be used to encapsulate the light emitting device 200. The first encapsulation structure 400 includes the first sub-portion 410, the second sub-portion 421a and the third sub-portion 421b, the first sub-portion 410 covers on the side of the light emitting device 200 away from the substrate 100, the second sub-portion 421a covers on the side of the first isolation portion 311 facing the isolation opening 310a, the third sub-portion 421b is at least partially located on the side of the second isolation portion 312 facing the substrate 100 and is at least partially attached on the protruding portion 312a, so that the first encapsulation structure 400 may have a large size to better extend the encapsulation path of the first encapsulation structure 400.

The first sub-portion 410, the second sub-portion 421a and the third sub-portion 421b enclose and form the gap space 400a, which can reduce the interference influence of the first sub-portion 410, the second sub-portion 421a and the third sub-portion 421b when forming the first encapsulation structure 400. Therefore, the first sub-portion 410 can be better formed on the side of the light emitting device 200 away from the substrate 100, the second sub-portion 421a can be better formed on the side of the first isolation portion 311 facing the isolation opening 310a, and the third sub-portion 421b can be better formed on the side of the second isolation portion 312 facing the substrate 100, thereby better improving the encapsulation effect of the first encapsulation structure 400 on the display panel 10.

The first sub-portion 410 and the third sub-portion 421b in at least a part of the isolation openings 310a are at least partially spaced apart and form the communication opening 400b. By setting that the minimum size of the communication opening 400b in the thickness direction of the display panel 10 is less than or equal to the product of the sum of the thicknesses of the light emitting unit 220 and the first electrode 230 of at least a part of the light emitting devices 200 and the sealing coefficient, when independently preparing the different light emitting devices 200 during the preparation process of the display panel 10, the materials of the light emitting unit 220 and the first electrode 230 of the later prepared light emitting device 200 may better seal the communication opening 400b of the first encapsulation structure 400 above the previously prepared light emitting device 200. That is, the materials of the light emitting unit 220 and the first electrode 230 of the later prepared light emitting device 200 may be better continuous at the communication opening 400b of the first encapsulation structure 400 above the previously prepared light emitting device 200. Therefore, when patterning the film layer structure above the light emitting unit 220 and the first electrode 230 of the later prepared light emitting device 200, the light emitting unit 220 and the first electrode 230 of the later prepared light emitting device 200 can better cover and protect the first encapsulation structure 400 below, so that the etching material does not easily enter into the gap space 400a through the communication opening 400b, thereby better improving the structural stability of the display panel 10.

Specifically, with respect to the beneficial effect of the setting of the minimum size of the communication opening 400b in the thickness direction of the display panel 10 during the preparation process of the display panel 10, please refer to the corresponding preparation method and the corresponding drawings in the following embodiments.

Optionally, the display panel 10 provided by the embodiments of the first aspect of the present application may be the display panel 10 in any of the aforementioned embodiments, and therefore the display panel 10 provided by the embodiments of the present application may have the beneficial effect of the display panel 10 in any of the aforementioned embodiments, which will not be repeated in the present application.

For example, the isolation structure 310 may be the isolation structure 310 described in any of the aforementioned embodiments, and the isolation structure 310 may include the first isolation portion 311, the second isolation portion 312 and the third isolation portion 313 described in any of the aforementioned embodiments. The isolation openings 310a may include the first opening 310aa, the second opening 310ab, and the third opening 310ac described in any of the aforementioned embodiments.

For example, the display panel 10 further includes a pixel definition layer 320 disposed on a side of the substrate 100 facing the light emitting device 200, the pixel definition layer 320 includes a pixel limiting portion 321 and a pixel opening 320a enclosed and formed by the pixel limiting portion 321, the isolation structure 310 is disposed on a side of the pixel limiting portion 321 away from the substrate 100, and the pixel opening 320a may communicate with the isolation opening 310a.

For example, the light emitting device 200 may be the light emitting device 200 described in any of the aforementioned embodiments, and the light emitting devices 200 may include the first light emitting device 200a disposed corresponding to the first opening 310aa, the second light emitting device 200b disposed corresponding to the second opening 310ab, and the third light emitting device 200c disposed corresponding to the third opening 310ac described in any of the aforementioned embodiments.

For example, the first encapsulation structure 400 may include the first encapsulation unit 401 at least partially located in the first opening 310aa, the second encapsulation unit 402 at least partially located in the second opening 310ab, and the third encapsulation unit 403 at least partially located in the third opening 310ac described in any of the aforementioned embodiments.

In some embodiments, the first encapsulation structure 400 of the display panel 10 provided by the embodiments of the first aspect of the present application may be set up with full reference to the first encapsulation structure 400 of the display panel 10 of any of the aforementioned embodiments, that is, the first sub-portion 410 and the third sub-portion 421b of the first encapsulation structure 400 may be at least partially connected to form the connection portion 400c described in any of the aforementioned embodiments. For example, a side of the third sub-portion 421b in the first opening 310aa close to the isolation opening 310a and a surface of the first sub-portion 410 away from the substrate 100 are at least partially connected to form the connection portion 400c, and the orthographic projection of the connection portion 400c in the first opening 310aa on the substrate 100 is in a ring shape, so that the gap space 400a in the first opening 310aa is an enclosed space. For example, a side of the third sub-portion 421b in the second opening 310ab close to the isolation opening 310a and a surface of the first sub-portion 410 away from the substrate 100 are at least partially connected to form the connection portion 400c, and the orthographic projection of the connection portion 400c in the second opening 310ab on the substrate 100 is in a ring shape, so that the gap space 400a in the second opening 310ab is an enclosed gap space 400a.

In other embodiments, the first encapsulation structure 400 of the display panel 10 provided by the embodiments of the first aspect of the present application may be at least partially distinguished from the first encapsulation structure 400 of the display panel 10 of any of the aforementioned embodiments, that is, the first sub-portion 410 of the first encapsulation structure 400 in the isolation openings 310a may be spaced apart from the third sub-portion 421b to form the communication opening 400b, that is, the communication opening 400b in the isolation openings 310a may be in a ring shape. For example, the gap space 400a in the first opening 310aa forms at least one communication opening 400b. For example, the gap space 400a in the second opening 310ab forms at least one communication opening 400b. For example, the gap space 400a in the third opening 310ac forms at least one communication opening 400b.

For ease of description, the following embodiments illustrate that the first sub-portion 410 and the third sub-portion 421b of the first encapsulation structure 400 in the isolation openings 310a shown in FIG. 17 may be spaced apart to form a ring shaped communication opening 400b.

In some embodiments of the present application, the minimum size of the communication opening 400b in the thickness direction of the display panel 10 may be a minimum value of the spacing between the first sub-portion 410 and the third sub-portion 421b in the isolation opening 310a in the thickness direction of the display panel 10.

In some optional embodiments, the minimum size of the communication opening 400b in the thickness direction of the display panel 10 may be less than or equal to an opening size of the light emitting unit 220 and the first electrode 230 of at least a part of the light emitting devices 200 corresponding to the communication opening 400b.

Optionally, the opening size of the light emitting unit 220 and the first electrode 230 of the light emitting device 200 may refer to an allowable maximum value of the minimum size of the communication opening 400b of the previous first encapsulation structure 400 in the thickness direction of the display panel 10 that is sealable by the material of the light emitting unit 220 and the first electrode 230 of the subsequent light emitting devices 200 when completing the preparation of a previous part of the light emitting devices 200 and the previous first encapsulation structure 400 and then preparing the subsequent light emitting devices 200.

Here, the light emitting unit 220 and the first electrode 230 of the light emitting device 200 sealing the opening may mean that, the light emitting unit 220 and the first electrode 230 of the light emitting device 200 may fully fill the opening, or the light emitting unit 220 and the first electrode 230 of the light emitting device 200 may fully cover the opening.

Optionally, the sealing coefficient can be obtained by experimental methods. For example, during the experiment of the display panel 10, after the simulated preparation of the specific light emitting device 200 and a part of the first encapsulation structure 400 located above the specific light emitting device 200, when preparing the film layers of the corresponding virtual light emitting unit 220 and the virtual first electrode 230 by the same method as preparing the light emitting unit 220 and the first electrode 230 of the light emitting devices 200 other than the specific light emitting device 200, and under a condition that these film layers can seal the communication opening 400b of a part of the first encapsulation structure 400 above the specific light emitting device 200 and the film layer corresponding to the first electrode 230 is not disconnected at the communication opening 400b, the allowable maximum value of the minimum size of the communication opening 400b above the specific light emitting device 200 in the thickness direction of the display panel 10 may be a first reference value, and the sum of the thicknesses of the virtual light emitting unit 220 and the virtual first electrode 230 may be a second reference value. The sealing coefficient may refer to a ratio of the first reference value and the second reference value.

Here, the allowable maximum value of the minimum size of the communication opening 400b above the specific light emitting device 200 in the thickness direction of the display panel 10 may refer to a maximum value of multiple minimum sizes of the communication opening 400b above the specific light emitting device 200 in the thickness direction of the display panel 10 that are obtained through multiple experiments and meet the requirements.

Exemplarily, in order to vary the minimum size of the communication opening 400b in the thickness direction of the display panel 10 obtained in each experiment, at least one relevant parameter may be adjusted according to the needs of the product design (such as, only one parameter may be adjusted, and the other parameters may be kept unchanged, such as, only the film layer thickness of the first encapsulation structure 400 may be adjusted). Specifically, in order to achieve that “the minimum size of the communication opening 400b in the thickness direction of the display panel 10 is less than or equal to the product of the sum of the thicknesses of the light emitting unit 220 and the first electrode of at least a part of the light emitting devices 200 and the sealing coefficient”, the corresponding parameters used in the experiments of obtaining “the minimum size of the communication opening 400b in the thickness direction of the display panel 10” may be set as a reference, and one or more parameters capable of reducing “the minimum size of the communication opening 400b in the thickness direction of the display panel 10” may be adjusted, such as increasing the film layer thickness of the first encapsulation structure.

In these optional embodiments, by setting that the minimum size of the communication opening 400b in the thickness direction of the display panel 10 is less than or equal to the product of the sum of the thicknesses of the light emitting unit 220 and the first electrode 230 of at least a part of the light emitting devices 200 and the sealing coefficient, the size of the communication opening 400b may be more accurately adjusted, so that the size of the communication opening 400b is not too large. Therefore, when independently preparing the different light emitting devices 200 during the preparation process of the display panel 10, the materials of the light emitting unit 220 and the first electrode 230 of the later prepared light emitting device 200 may better seal the communication opening 400b of the first encapsulation structure 400 above the previously prepared light emitting device 200.

Optionally, the sealing coefficient can be 1. Optionally, the minimum size of the communication opening 400b in the thickness direction of the display panel 10 may be less than or equal to the sum of the thicknesses of the light emitting unit 220 and the first electrode 230 of at least a part of the light emitting device 200.

In some optional embodiments, in the preparation process of the display panel 10, the preparation step of the first light emitting device 200a may be located before the preparation step of the third light emitting device 200c. For example, in the preparation process of the display panel 10, the first light emitting device 200a and the first encapsulation unit 401 may be prepared firstly, and then the third light emitting device 200c and the third encapsulation unit 403 may be prepared. Specifically, the preparation of the second electrodes 210 of the first light emitting device 200a and the third light emitting device 200c may be completed simultaneously, then the preparation of the light emitting unit 220 and the first electrode 230 of the first light emitting device 200a may be performed to complete the preparation of the first light emitting device 200a, then the first encapsulation unit 401 is prepared on the first light emitting device 200a, then the preparation of the light emitting unit 220 and the first electrode 230 of the third light emitting device 200c may be performed to complete the preparation of the third light emitting device 200c, then the third encapsulation unit 403 is prepared on the third light emitting device 200c.

Optionally, in the preparation process of the display panel 10, the preparation step of the second light emitting device 200b is located between the preparation step of the first light emitting device 200a and the preparation step of the third light emitting device 200c. For example, in the preparation process of the display panel 10, the first light emitting device 200a and the first encapsulation unit 401 may be prepared firstly, then the second light emitting device 200b and the second encapsulation unit 402 may be prepared, and then the third light emitting device 200c and the third encapsulation unit 403 may be prepared. Specifically, the preparation of the second electrodes 210 of the first light emitting device 200a, the second light emitting device 200b and the third light emitting device 200c may be completed simultaneously, then the preparation of the light emitting unit 220 and the first electrode 230 of the first light emitting device 200a may be performed to complete the preparation of the first light emitting device 200a, then the first encapsulation unit 401 is prepared on the first light emitting device 200a, then the preparation of the light emitting unit 220 and the first electrode 230 of the second light emitting device 200b may be performed to complete the preparation of the second light emitting device 200b, then the second encapsulation unit 402 is prepared on the second light emitting device 200b, then the preparation of the light emitting unit 220 and the first electrode 230 of the third light emitting device 200c may be performed to complete the preparation of the third light emitting device 200c, finally, the third encapsulation unit 403 is prepared on the third light emitting device 200c.

In some embodiments of the present application, the sealing coefficient varies with the shape structure of the corresponding communication opening 400b and the film layer materials and thicknesses of the light emitting unit 220 and the first electrode 230 of the corresponding light emitting device 200 of different colors.

In some optional embodiments, the minimum size of the communication opening 400b in the first opening 310aa in the thickness direction of the display panel 10 is less than or equal to the product of the sum of the thicknesses of the light emitting unit 220 and the first electrode 230 of the second light emitting device 200b and the corresponding sealing coefficient; and/or, the minimum size of the communication opening 400b in the first opening 310aa in the thickness direction of the display panel 10 is less than or equal to the product of the sum of the thicknesses of the light emitting unit 220 and the first electrode 230 of the third light emitting device 200c and the corresponding sealing coefficient.

Optionally, the minimum size of the communication opening 400b in the first opening 310aa in the thickness direction of the display panel 10 being less than or equal to the product of the sum of the thicknesses of the light emitting unit 220 and the first electrode 230 of the second light emitting device 200b and the corresponding sealing coefficient may mean that, the minimum size of the communication opening 400b in the first opening 310aa in the thickness direction of the display panel 10 is less than or equal to the product of the sum of the thicknesses of the light emitting unit 220 and the first electrode 230 of the second light emitting device 200b and a first sealing coefficient.

Optionally, the first sealing coefficient can be obtained by experimental methods. For example, during the experiment of the display panel 10, after the simulated preparation of the first light emitting device 200a in the first opening 310aa and the first encapsulation unit 401 located above the first light emitting device 200a, when preparing the film layers of the corresponding virtual light emitting unit 220 and the virtual first electrode 230 by the same method as preparing the light emitting unit 220 and the first electrode 230 of the second light emitting device 200b, and under a condition that these film layers can seal the communication opening 400b of the first encapsulation unit 401 and the film layer corresponding to the first electrode 230 is not disconnected at the communication opening 400b of the first encapsulation unit 401, the allowable maximum value of the minimum size of the communication opening 400b of the first encapsulation unit 401 in the thickness direction of the display panel 10 may be a third reference value, and the sum of the thicknesses of the first electrode 230 of the second light emitting device 200b may be a fourth reference value. The first sealing coefficient may refer to a ratio of the third reference value and the fourth reference value.

Here, the allowable maximum value of the minimum size of the communication opening 400b of the first encapsulation unit 401 in the thickness direction of the display panel 10 may refer to a maximum value of multiple minimum sizes of the communication opening 400b of the first encapsulation unit 401 in the thickness direction of the display panel 10 that are obtained through multiple experiments and meet the requirements.

Optionally, the minimum size of the communication opening 400b in the first opening 310aa in the thickness direction of the display panel 10 being less than or equal to the product of the sum of the thicknesses of the light emitting unit 220 and the first electrode 230 of the third light emitting device 200c and the corresponding sealing coefficient may mean that, the minimum size of the communication opening 400b in the first opening 310aa in the thickness direction of the display panel 10 is less than or equal to the product of the sum of the thicknesses of the light emitting unit 220 and the first electrode 230 of the third light emitting device 200c and a second sealing coefficient.

Optionally, the second sealing coefficient can be obtained by experimental methods. For example, during the experiment of the display panel 10, after the simulated preparation of the first light emitting device 200a in the first opening 310aa and the first encapsulation unit 401 located above the first light emitting device 200a, when preparing the film layers of the corresponding virtual light emitting unit 220 and the virtual first electrode 230 by the same method as preparing the light emitting unit 220 and the first electrode 230 of the third light emitting device 200c, and under a condition that these film layers can seal the communication opening 400b of the first encapsulation unit 401 and the film layer corresponding to the first electrode 230 is not disconnected at the communication opening 400b of the first encapsulation unit 401, the allowable maximum value of the minimum size of the communication opening 400b of the first encapsulation unit 401 in the thickness direction of the display panel 10 may be a fifth reference value, and the sum of the thicknesses of the first electrode 230 of the third light emitting device 200c may be a sixth reference value. The second sealing coefficient may refer to a ratio of the fifth reference value and the sixth reference value.

Here, the allowable maximum value of the minimum size of the communication opening 400b of the first encapsulation unit 401 in the thickness direction of the display panel 10 may refer to a maximum value of multiple minimum sizes of the communication opening 400b of the first encapsulation unit 401 in the thickness direction of the display panel 10 that are obtained through multiple experiments and meet the requirements.

In these optional embodiments, by setting the minimum size of the communication opening 400b in the first opening 310aa in the thickness direction of the display panel 10 according to the thicknesses of the light emitting unit 220 and the first electrode 230 of the second light emitting device 200b and the thicknesses of the light emitting unit 220 and the first electrode 230 of the third light emitting device 200c, the size of the communication opening 400b in the first opening 310aa may be more accurately adjusted. Therefore, when preparing the second light emitting device 200b and the second encapsulation unit 402, the materials of the light emitting unit 220 and the first electrode 230 of the later prepared second light emitting device 200b may better seal the communication opening 400b of the first encapsulation unit 401 above the first light emitting device 200a, that is, the materials of the light emitting unit 220 and the first electrode 230 of the second light emitting device may be better continuous at the communication opening 400b of the first encapsulation unit 401 above the first light emitting device 200a. Therefore, when patterning the material of the second encapsulation unit 402, the materials of the light emitting unit 220 and the first electrode 230 of the second light emitting device 200b may better cover and protect the first encapsulation unit 401 below, so that the etching material does not easily enter into the gap space 400a of the first encapsulation unit 401 through the communication opening 400b, thereby better improving the structural stability of the display panel 10.

Further, when preparing the third light emitting device 200c and the third encapsulation unit 403, the materials of the light emitting unit 220 and the first electrode 230 of the later prepared third light emitting device 200c may better seal the communication opening 400b of the first encapsulation unit 401 above the first light emitting device 200a, that is, the materials of the light emitting unit 220 and the first electrode 230 of the third light emitting device may be better continuous at the communication opening 400b of the first encapsulation unit 401 above the first light emitting device 200a. Therefore, when patterning the material of the third encapsulation unit 403, the materials of the light emitting unit 220 and the first electrode 230 of the third light emitting device 200c may better cover and protect the first encapsulation unit 401 below, so that the etching material does not easily enter into the gap space 400a of the first encapsulation unit 401 through the communication opening 400b, thereby better improving the structural stability of the display panel 10.

Optionally, the first sealing coefficient can be 1, and/or, the second sealing coefficient can be 1. Optionally, the size of the communication opening 400b in the first opening 310aa in the thickness direction of the display panel 10 is less than or equal to the thickness of the light emitting unit 220 of the second light emitting device 200b; and/or the size of the communication opening 400b in the first opening 310aa in the thickness direction of the display panel 10 is less than or equal to the thickness of the light emitting unit 220 of the third light emitting device 200c.

In some optional embodiments, the minimum size of the communication opening 400b in the second opening 310ab in the thickness direction of the display panel 10 is less than or equal to the product of the sum of the thicknesses of the light emitting unit 220 and the first electrode 230 of the third light emitting device 200c and a fourth sealing coefficient.

Optionally, the fourth sealing coefficient can be obtained by experimental methods. For example, during the experiment of the display panel 10, after the simulated preparation of the second light emitting device 200b in the second opening 310ab and the second encapsulation unit 402 located above the second light emitting device 200b, when preparing the film layers of the corresponding virtual light emitting unit 220 and the virtual first electrode 230 by the same method as preparing the light emitting unit 220 and the first electrode 230 of the third light emitting device 200c, and under a condition that these film layers can seal the communication opening 400b of the second encapsulation unit 402 and are not disconnected at the communication opening 400b of the second encapsulation unit 402, the allowable maximum value of the minimum size of the communication opening 400b of the second encapsulation unit 402 in the thickness direction of the display panel 10 may be a seventh reference value, and the sum of the thicknesses of the first electrode 230 of the third light emitting device 200c may be an eighth reference value. The fourth sealing coefficient may refer to a ratio of the seventh reference value and the eighth reference value.

Here, the allowable maximum value of the minimum size of the communication opening 400b of the second encapsulation unit 402 in the thickness direction of the display panel 10 may refer to a maximum value of multiple minimum sizes of the communication opening 400b of the second encapsulation unit 402 in the thickness direction of the display panel 10 that are obtained through multiple experiments and meet the requirements.

In these optional embodiments, by setting the minimum size of the communication opening 400b in the second opening 310ab in the thickness direction of the display panel 10 according to the thicknesses of the light emitting unit 220 and the first electrode 230 of the third light emitting device 200c, the size of the communication opening 400b in the second opening 310ab may be more accurately adjusted. Therefore, when preparing the third light emitting device 200c and the third encapsulation unit 403, the materials of the light emitting unit 220 and the first electrode 230 of the later prepared third light emitting device 200c may better seal the communication opening 400b of the second encapsulation unit 402 above the second light emitting device 200b, that is, the materials of the light emitting unit 220 and the first electrode 230 of the third light emitting device may be better continuous at the communication opening 400b of the second encapsulation unit 402 above the second light emitting device 200b. Therefore, when patterning the material of the third encapsulation unit 403, the materials of the light emitting unit 220 and the first electrode 230 of the third light emitting device 200c may better cover and protect the second encapsulation unit 402 below, so that the etching material does not easily enter into the gap space 400a of the second encapsulation unit 402 through the communication opening 400b, thereby better improving the structural stability of the display panel 10.

Optionally, the fourth sealing coefficient can be 1. Optionally, the size of the communication opening 400b in the second opening 310ab in the thickness direction of the display panel 10 is less than or equal to the thickness of the light emitting unit 220 of the third light emitting device 200c.

In some embodiments of the present application, after the preparation of the third light emitting device 200c and the third encapsulation unit 403, there is no need to perform the preparation of the light emitting device 200 and the first encapsulation structure 400. Therefore, the minimum size of the communication opening 400b in the third encapsulation unit 403 in the thickness direction of the display panel 10 is not specifically limited in the present application. For example, the size of the communication opening 400b in the third encapsulation unit 403 in the thickness direction of the display panel 10 may be relatively large, so as to facilitate the preparation of the third encapsulation unit 403.

In some optional embodiments, the size of the communication opening 400b in the first opening 310aa in the thickness direction of the display panel 10 is less than the size of the communication opening 400b in the third opening 310ac in the thickness direction of the display panel 10, so that the communication opening 400b in the first opening 310aa may have a relatively small size, so as to facilitate the sealing of the light emitting unit 220 and the first electrode 230 of the second light emitting device 200b and the third light emitting device 200c.

Optionally, the size of the communication opening 400b in the second opening 310ab in the thickness direction of the display panel 10 is less than or equal to the size of the communication opening 400b in the third opening 310ac in the thickness direction of the display panel 10, so that the communication opening 400b in the second opening 310ab may have a relatively small size, so as to facilitate the sealing of the light emitting unit 220 and the first electrode 230 of the third light emitting device 200c.

Optionally, the size of the communication opening 400b in the second opening 310ab in the thickness direction of the display panel 10 is greater than or equal to the size of the communication opening 400b in the first opening 310aa in the thickness direction of the display panel 10, so that the communication opening 400b in the first opening 310aa may be relatively small, so as to facilitate the sealing of the communication opening 400b in the first opening 310aa by the light emitting unit 220 and the first electrode 230 of the second light emitting device 200b and the third light emitting device 200c.

Here, there are various methods of regulating the size of the communication opening 400b in the thickness direction of the display panel 10, that is, there are various methods of adjusting the spacing size between the surface of the first sub-portion 410 away from the substrate 100 and the surface of the third sub-portion 421b away from the isolation structure 310.

Optionally, the size of the communication opening 400b in the thickness direction of the display panel 10 may be adjusted with reference to the method described in any of the aforementioned embodiments. For example, the size of the communication opening 400b in the thickness direction of the display panel 10 may be adjusted with reference to the method of adjusting the thickness of the first encapsulation structure 400 described in the aforementioned embodiments. For example, the size of the communication opening 400b in the thickness direction of the display panel 10 may be adjusted with reference to the method of adjusting the morphology of the isolation structure 310 described in the aforementioned embodiments.

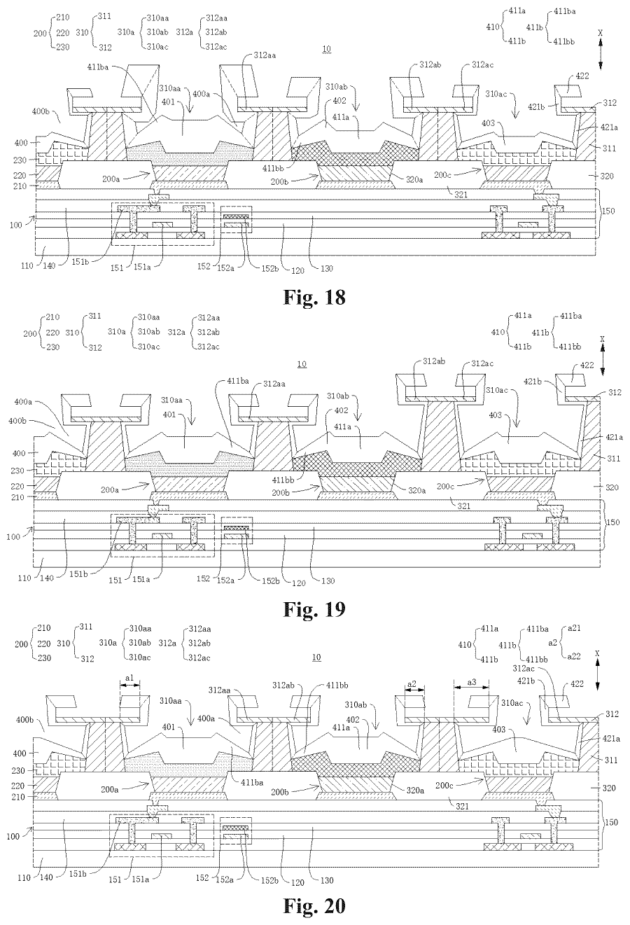

FIG. 18 is a local sectional diagram of a display panel 10 provided by another embodiment of the present application.

As shown in FIG. 18, in some optional embodiments, the maximum thickness of the first encapsulation unit 401 is greater than the maximum thickness of the third encapsulation unit 403.

Optionally, the thickness of the first sub-portion 410 in the first encapsulation unit 401 may represent the maximum thickness of the first encapsulation unit 401, and specifically, the thickness of the first body sub-portion 411a in the first encapsulation unit 401 may represent the maximum thickness of the first encapsulation unit 401.

Optionally, the thickness of the first sub-portion 410 in the third encapsulation unit 403 may represent the maximum thickness of the third encapsulation unit 403, and specifically, the thickness of the first body sub-portion 411a in the third encapsulation unit 403 may represent the maximum thickness of the third encapsulation unit 403.

In these optional embodiments, by setting that the maximum thickness of the first encapsulation unit 401 is greater than the maximum thickness of the third encapsulation unit 403, in the preparation process of the display panel 10, the first encapsulation unit 401 is not easily damaged by the subsequent etching process. For example, the first encapsulation unit 401 is not easily damaged by the etching material during the etching process of the second light emitting device 200b, the second encapsulation unit 402, the third light emitting device 200c, and the third encapsulation unit 403, so that the encapsulation stability of the first encapsulation unit 401 can be better improved. At the same time, the first sub-portion 410 of the first encapsulation unit 401 can be close to the third sub-portion 421b of the first encapsulation unit 401, and the size of the communication opening 400b of the first encapsulation unit 401 in the thickness direction of the display panel 10 is relatively small, thereby facilitating the sealing of the communication opening 400b of the first encapsulation unit 401 by the light emitting unit 220 and the first electrode 230 of the second light emitting device 200b and the third light emitting device 200c.

In some optional embodiments, the maximum thickness of the second encapsulation unit 402 is greater than or equal to the maximum thickness of the third encapsulation unit 403.

Optionally, the maximum thickness of the second encapsulation unit 402 is less than or equal to the maximum thickness of the first encapsulation unit 401.

Optionally, the thickness of the first sub-portion 410 in the second encapsulation unit 402 may represent the maximum thickness of the second encapsulation unit 402, and specifically, the thickness of the first body sub-portion 411a in the second encapsulation unit 402 may represent the maximum thickness of the second encapsulation unit 402.

In these optional embodiments, by setting that the maximum thickness of the second encapsulation unit 402 is greater than the maximum thickness of the third encapsulation unit 403, in the preparation process of the display panel 10, the second encapsulation unit 402 is not easily damaged by the subsequent etching process. For example, the second encapsulation unit 402 is not easily damaged by the etching material during the etching process of the third light emitting device 200c and the third encapsulation unit 403, thereby better improving the encapsulation stability of the second encapsulation unit 402. At the same time, the first sub-portion 410 of the second encapsulation unit 402 can be close to the third sub-portion 421b of the second encapsulation unit 402, and the size of the communication opening 400b of the second encapsulation unit 402 in the thickness direction of the display panel 10 is relatively small, thereby facilitating the sealing of the communication opening 400b of the second encapsulation unit 402 by the light emitting unit 220 and the first electrode 230 of the third light emitting device 200c.

In some optional embodiments, a first spacing is provided between a surface of the protruding portion 312a facing the substrate 100 and a surface of the pixel limiting portion 321 away from the substrate 100, and a ratio of a maximum thickness of at least a part of the first body sub-portion 411a of the first encapsulation unit 401 to the first spacing is not less than 1; and/or a ratio of a maximum thickness of at least a part of the second body sub-portion 411b of the first encapsulation unit 401 to the first spacing is not less than 1.

Optionally, the protruding portion 312a includes a first protruding portion 312aa corresponding to the first opening 310aa, a second protruding portion 312ab corresponding to the second opening 310ab, and a third protruding portion 312ac corresponding to the third opening 310ac. The first spacing may refer to a spacing between the surface of the first protruding portion 312aa facing the substrate 100 and the surface of the pixel limiting portion 321 away from the substrate 100. The ratio of the maximum thickness of the first body sub-portion 411a of the first encapsulation unit 401 to the first spacing corresponding to the first protruding portion 312aa is not less than 1, and/or the ratio of the maximum thickness of the second body sub-portion 411b of the first encapsulation unit 401 to the first spacing corresponding to the first protruding portion 312aa is not less than 1.

In these optional embodiments, by reasonably setting the ratio of the maximum thickness of the first body sub-portion 411a of the first encapsulation unit 401 to the first spacing, and by reasonably setting the ratio of the maximum thickness of the second body sub-portion 411b of the first encapsulation unit 401 to the first spacing, the thicknesses of at least a part of the first body sub-portion 411a and at least a part of the second body sub-portion 411b in the first encapsulation unit 401 may be better adjusted in accordance with the blocking capability of the protruding portion 312a to the first encapsulation structure 400, which is facilitate to reduce the size of the communication opening 400b of the first encapsulation unit 401 in the thickness direction of the display panel 10, thereby facilitating the sealing of the communication opening 400b of the first encapsulation unit 401 by the light emitting unit 220 and the first electrode 230 of the second light emitting device 200b and the third light emitting device 200c.

Specifically, under a condition that the first spacing is relatively large, in the process of preparing the first encapsulation structure 400, the protruding portion 312a will be relatively close to the preparation apparatus of the first encapsulation structure 400, so that the protruding portion 312a has a great blocking influence on the material of the first encapsulation structure 400, that is, the protruding portion 312a can have a better blocking capability. Therefore, according to the relatively large first spacing, the first body sub-portion 411a and at least a part of the second body sub-portion 411b of the first encapsulation unit 401 may be set to have a relatively large thickness, so that the first sub-portion 410 of the first encapsulation unit 401 can be relatively close to the third sub-portion 421b, thereby facilitating to reduce the size of the communication opening 400b of the first encapsulation unit 401 in the thickness direction of the display panel 10.

Under a condition that the first spacing is relatively small, in the process of preparing the first encapsulation structure 400, the protruding portion 312a will be relatively away from the preparation apparatus of the first encapsulation structure 400, so that the protruding portion 312a has a little blocking influence on the material of the first encapsulation structure 400, that is, the protruding portion 312a has a poor blocking capability for the first encapsulation structure 400. Therefore, according to the relatively small first spacing, at least a part of the first body sub-portion 411a and at least a part of the second body sub-portion 411b of the first encapsulation unit 401 may be set to have a reasonable thickness, so that the first sub-portion 410 of the first encapsulation unit 401 can be relatively close to the third sub-portion 421b, and at the same time, it is not easy to increase the thickness of the display panel 10.

FIG. 19 is a local sectional diagram of a display panel 10 provided by another embodiment of the present application.

As shown in FIG. 19, in some optional embodiments, a spacing between the substrate 100 and at least a part of the second isolation portion 312 involved in enclosing and forming the first opening 310aa is less than a spacing between the substrate 100 and the second isolation portion 312 involved in enclosing and forming the third opening 310ac.

Optionally, the spacing between the second isolation portion 312 and the substrate 100 may refer to a spacing between a surface of the second isolation portion 312 facing the substrate 100 and the substrate 100.

Optionally, the spacing between the first protruding portion 312aa and the substrate 100 may be less than the spacing between the third protruding portion 312ac and the substrate 100.

In these optional embodiments, by setting that the spacing between the substrate 100 and at least a part of the second isolation portion 312 involved in enclosing and forming the first opening 310aa is less than the spacing between the substrate 100 and the second isolation portion 312 involved in enclosing and forming the third opening 310ac, in the preparation process of the first encapsulation structure 400, compared to the first protruding portion 312aa, the third protruding portion 312ac can be closer to the preparation apparatus of the first encapsulation structure 400, so that the first protruding portion 312aa has a small blocking effect on the material of the first encapsulation structure 400, which can facilitate to reduce the size of the communication opening 400b of the first encapsulation unit 401 in the thickness direction of the display panel 10, thereby facilitating the sealing of the communication opening 400b of the first encapsulation unit 401 by the light emitting unit 220 and the first electrode 230 of the second light emitting device 200b and the third light emitting device 200c.

Here, there are various ways of regulating the spacing between the second isolation portion 312 and the substrate 100. For example, the spacing between the second isolation portion 312 and the substrate 100 may be adjusted by adjusting the size of the first isolation portion 311 in the thickness direction.

Optionally, the size of at least a part of the first isolation portion 311 involved in enclosing and forming the first opening 310aa in the thickness direction of the display panel 10 may be smaller than the size of the first isolation portion 311 involved in enclosing and forming the second opening 310ab in the thickness direction of the display panel 10, which can facilitate to realize that the spacing between the substrate 100 and at least a part of the second isolation portion 312 involved in enclosing and forming the first opening 310aa is less than the spacing between the substrate 100 and the second isolation portion 312 involved in enclosing and forming the third opening 310ac.

In some optional embodiments, the spacing between the substrate 100 and at least a part of the second isolation portion 312 involved in enclosing and forming the second opening 310ab is greater than or equal to the spacing between the substrate 100 and the second isolation portion 312 involved in enclosing and forming the first opening 310aa; and/or, the spacing between the substrate 100 and at least a part of the second isolation portion 312 involved in enclosing and forming the second opening 310ab is less than or equal to the spacing between the substrate 100 and the second isolation portion 312 involved in enclosing and forming the third opening 310ac.

Optionally, the spacing between at least a part of the second protruding portion 312ab and substrate 100 is greater than or equal to the spacing between the first protruding portion 312aa and substrate 100; or the spacing between at least a part of the second protruding portion 312ab and substrate 100 is less than or equal to the spacing between the third protruding portion 312ac and substrate 100.

Optionally, the size of at least a part of the first isolation portion 311 involved in enclosing and forming the second opening 310ab in the thickness direction of the display panel 10 is greater than or equal to the size of the first isolation portion 311 involved in enclosing and forming the first opening 310aa in the thickness direction of the display panel 10, so as to facilitate to realize that the spacing between the substrate 100 and at least a part of the second isolation portion 312 involved in enclosing and forming the second opening 310ab is greater than or equal to the spacing between the substrate 100 and the second isolation portion 312 involved in enclosing and forming the first opening 310aa; and/or, the size of at least a part of the first isolation portion 311 involved in enclosing and forming the second opening 310ab in the thickness direction of the display panel 10 is less than or equal to the size of the first isolation portion 311 involved in enclosing and forming the third opening 310ac in the thickness direction of the display panel 10, so as to facilitate to realize that the spacing between the substrate 100 and at least a part of the second isolation portion 312 involved in enclosing and forming the second opening 310ab is less than or equal to the spacing between the substrate 100 and the second isolation portion 312 involved in enclosing and forming the third opening 310ac.

In these optional embodiments, by setting that the spacing between the substrate 100 and at least a part of the second isolation portion 312 involved in enclosing and forming the second opening 310ab is less than the spacing between the substrate 100 and the second isolation portion 312 involved in enclosing and forming the third opening 310ac, in the preparation process of the first encapsulation structure 400, compared to the second protruding portion 312ab, the third protruding portion 312ac can be closer to the preparation apparatus of the first encapsulation structure 400, so that the second protruding portion 312ab has a small blocking influence on the material of the first encapsulation structure 400, which can facilitate to reduce the size of the communication opening 400b of the second encapsulation unit 402 in the thickness direction of the display panel 10, thereby facilitating the sealing of the communication opening 400b of the second encapsulation unit 402 by the light emitting unit 220 and the first electrode 230 of the third light emitting device 200c.

FIG. 20 is a local sectional diagram of a display panel 10 provided by another embodiment of the present application.

As shown in FIG. 20, in some optional embodiments, the protruding length of the first protruding portion 312aa is less than the protruding length of the third protruding portion 312ac, that is, the protruding length of the side of the second isolation portion 312 facing the first opening 310aa relative to the first isolation portion 311 is less than the protruding length of the side of the second isolation portion 312 facing the third opening 310ac relative to the first isolation portion 311.

Optionally, the protruding length of the first protruding portion 312aa may refer to a minimum spacing between the orthographic projection of the edge of the first protruding portion 312aa facing the first opening 310aa on the substrate 100 and the orthographic projection of the surface of the first isolation portion 311 facing the first protruding portion 312aa on the substrate 100. Optionally, the length of a1 in FIG. 20 may represent the protruding length of the first protruding portion 312aa.

Optionally, the protruding length of the third protruding portion 312ac may refer to a minimum spacing between the orthographic projection of the edge of the third protruding portion 312ac facing the third opening 310ac on the substrate 100 and the orthographic projection of the surface of the first isolation portion 311 facing the third protruding portion 312ac on the substrate 100. Optionally, the length of a3 in FIG. 20 may represent the protruding length of the third protruding portion 312ac.

In these optional embodiments, under the small blocking influence provided by the first protruding portion 312aa having a relatively short protruding length, it can facilitate to reduce the size of the communication opening 400b of the first encapsulation unit 401 in the thickness direction of the display panel 10, thereby facilitating the sealing of the communication opening 400b of the first encapsulation unit 401 by the light emitting unit 220 and the first electrode 230 of the second light emitting device 200b and the third light emitting device 200c.

In some optional embodiments, the protruding length of the second protruding portion 312ab is less than or equal to the protruding length of the third protruding portion 312ac; and/or the protruding length of the second protruding portion 312ab is greater than or equal to the protruding length of the first protruding portion 312aa.

That is, the protruding length of the second isolation portion 312 facing the second opening 310ab relative to the first isolation portion 311 is less than or equal to the protruding length of the second isolation portion 312 facing the third opening 310ac relative to the first isolation portion 311, and/or the protruding length of the second isolation portion 312 facing the second opening 310ab relative to the first isolation portion 311 is greater than or equal to the protruding length of the second isolation portion 312 facing the first opening 310aa relative to the first isolation portion 311.

Optionally, the protruding length of the second protruding portion 312ab may refer to a minimum spacing between the orthographic projection of the edge of the second protruding portion 312ab facing the second opening 310ab on the substrate 100 and the orthographic projection of the surface of the first isolation portion 311 facing the second protruding portion 312ab on the substrate 100. Optionally, the length of a2 in FIG. 20 may represent the protruding length of the second protruding portion 312ab.

In these optional embodiments, under the large blocking influence provided by the second protruding portions 312ab having a relatively long protruding length, it can facilitate to reduce the size of the communication opening 400b of the second encapsulation unit 402 in the thickness direction of the display panel 10, thereby facilitating the sealing of the communication opening 400b of the second encapsulation unit 402 by the light emitting unit 220 and the first electrode 230 of the third light emitting device 200c.

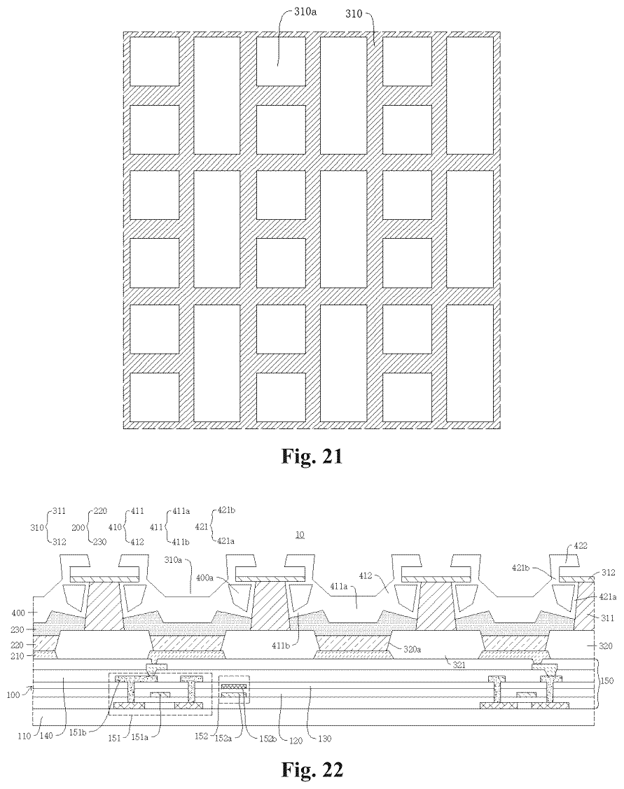

FIG. 21 is a local structure schematic diagram of an isolation structure 310 provided by an embodiment of the present application, and FIG. 22 is a local sectional diagram of a display panel 10 provided by another embodiment of the present application.

Please refer to FIG. 1 to FIG. 22, the embodiments of the first aspect of the present application also provide a display panel 10, including: a substrate 100; an isolation structure 310 disposed on a side of the substrate 100 and enclosing and forming an isolation opening 310a; a light emitting device 200, at least a part of the light emitting device 200 being located within the isolation opening 310a; a first encapsulation structure 400 disposed on a side of the light emitting device 200 away from the substrate 100, the first encapsulation structure 400 including a first sub-portion 410 and a second sub-section 421, the first sub-portion 410 being disposed in the isolation opening 310a and on the side of the light emitting device 200 away from the substrate 100, the second sub-section 421 being disposed on a side of the isolation structure 310 facing the isolation opening 310a, a surface of the first sub-portion 410 away from the substrate 100 being at least partially connected with a surface of the second sub-section 421 away from the isolation structure 310 to enclose and form a gap space 400a.

In the display panel 10 provided by the embodiments of the present application, the display panel 10 includes the substrate 100, the isolation structure 310, the light emitting devices 200, and the first encapsulation structure 400. The isolation structure 310 is disposed on a side of the substrate 100 and encloses and forms the isolation opening 310a, the light emitting device 200 is at least partially located in the isolation opening 310a, and the isolation structure 310 can be used to divide the sub-pixels of the display panel 10.

The first encapsulation structure 400 is disposed on the side of the light emitting device 200 away from the substrate 100, the first encapsulation structure 400 includes the first sub-portion 410 and the second sub-section 421, the first sub-portion 410 is located in the isolation opening 310a and disposed on the side of the light emitting device 200 away from the substrate 100, the second sub-section 421 is located on the side of the isolation structure 310 facing the isolation opening 310a, and the first encapsulation structure 400 may be used to encapsulate the light emitting device 200. By setting that the surface of the first sub-portion 410 away from the substrate 100 is at least partially connected with the surface of the second sub-section 421 away from the isolation structure 310 to enclose and form the gap space 400a, the first sub-portion 410 can provide a better supporting role on the second sub-section 421, so that the second sub-section 421 is not easy to be separated from the isolation structure 310, thereby improving the encapsulation effect of the first encapsulation structure 400 on the display panel 10.

Optionally, the display panel 10 provided by the embodiments of the first aspect of the present application may be the display panel 10 in any of the aforementioned embodiments, and therefore the display panel 10 provided by the embodiments of the present application may have the beneficial effect of the display panel 10 in any of the aforementioned embodiments, which will not be repeated in the present application.

In some embodiments of the present application, the shape of the isolation structure 310 is arranged in various ways, and the shape of the isolation structure 310 may be any of the shapes that are capable of blocking and separating the material of the light emitting device 200, so as to facilitate the preparation of the light emitting device 200.

In some optional embodiments, the isolation structure 310 includes a first isolation portion 311 and a second isolation portion 312 located on the side of the first isolation portion 311 away from the substrate 100, and the second isolation portion 312 protrudes from the first isolation portion 311 toward the isolation opening 310a. By setting that the second isolation portion 312 protrudes from the first isolation portion 311 toward the isolation opening 310a, when preparing the light emitting device 200 of the display panel 10, the material of the light emitting device 200 can be directly evaporated on the whole surface, the second isolation portion 312 can block at least a part of the material for preparing the light emitting device 200, so as to separate the material of the light emitting devices 200 in the adjacent sub-pixels, thereby facilitating the formation of the plurality of light emitting devices 200 that are spaced apart and located within the isolation openings 310a. Therefore, there is no need to set the mask with high precision when preparing the light emitting devices 200 of the display panel 10, for example, there is no need to set setting the fine metal mask when evaporating the material of the light emitting device 200. Thus, the production and preparation cost of the display panel 10 can be better reduced.

Optionally, as shown in FIG. 21, the isolation structure 310 may be in a grid shape to facilitate the division of the sub-pixels of the display panel 10 by the isolation structure 310. Specifically, the hollow region in the isolation structure 310 in the grid shape may be the isolation openings 310a.

In some optional embodiments, the material of the isolation structure 310 may include a conductive material. The first electrode 230 can be connected to the isolation structure 310, so that the first electrodes 230 of the adjacent sub-pixels can be electrically connected by the isolation structure 310. That is, the first electrodes 230 of the adjacent sub-pixels can be electrically connected by the isolation structure 310 to form a surface electrode, thereby facilitating the control of the first electrodes 230 in the display panel 10. Optionally, the material of the first isolation portion 311 may include a conductive material, and the first electrode 230 may be connected to the first isolation portion 311, so that the first electrodes 230 of the adjacent sub-pixels may be electrically connected by the first isolation portion 311.

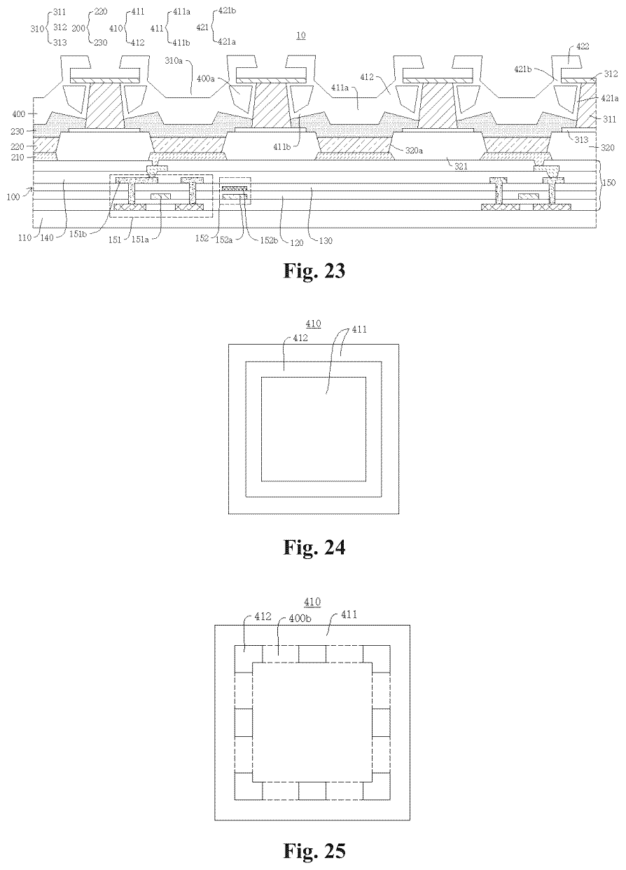

FIG. 23 is a local sectional diagram of a display panel 10 provided by another embodiment of the present application.

As shown in FIG. 23, in some optional embodiments, the isolation structure 310 also includes a third isolation portion 313 disposed at a side of the first isolation portion 311 facing the substrate 100. The third isolation portion 313 is disposed protruding from the first isolation portion 311 toward the isolation opening 310a. Here, the material of the third isolation portion 313 may include a conductive material, and the first electrode 230 may be connected to the third isolation portion 313, so that the first electrodes 230 of the adjacent sub-pixels may be electrically connected by the third isolation portion 313. By setting the third isolation portion 313 as protruding from the first isolation portion 311 toward the isolation opening 310a, the third isolation portion 313 may have a large size to facilitate the connection with the first electrode 230.

Optionally, the display panel 10 may also include a pixel definition layer 320 disposed on a side of the substrate 100 facing the second electrode 210, the pixel definition layer 320 may include a pixel limiting portion 321 and a pixel opening 320a enclosed and formed by the pixel limiting portion 321, and an orthographic projection of the pixel opening 320a on the substrate 100 may be located in an orthographic projection of the isolation opening 310a on the substrate 100. The orthographic projection of the pixel opening 320a on the substrate 100 may refer to an orthographic projection region enclosed and formed by an orthographic projection of an inner wall enclosing and forming the pixel opening 320a on the substrate 100. The orthographic projection of the isolation opening 310a on the substrate 100 may refer to an orthographic projection region enclosed and formed by an orthographic projection of an inner wall enclosing and forming the isolation opening 310a on the substrate 100.

Optionally, the pixel limiting portion 321 may be disposed between the adjacent second electrodes 210, the adjacent second electrodes 210 may be insulated by the pixel limiting portion 321, and the setting of the pixel limiting portion 321 may also facilitate the division of the sub-pixels in the display panel 10. Optionally, the pixel limiting portion 321 may be located between the second electrode 210 and the isolation structure 310, and the isolation structure 310 and the second electrode 210 may be insulated by the pixel limiting portion 321, so that the first electrode 230 and the second electrode 210 do not have short-circuit connection through the isolation structure 310, which is facilitate to improve the operation reliability of the display panel 10.

In this optional embodiment, the relative position between the isolation structure 310 and the pixel limiting portion 321 may be set in a variety of ways. Optionally, as shown in FIG. 22, the isolation structure 310 may be disposed at a side of the pixel limiting portion 321 away from the substrate 100, or the pixel limiting portion 321 is provided with an accommodating groove, and at least a part of the isolation structure 310 is located in the accommodating groove, so that the isolation structure 310 does not have a large height compared to the substrate 100, thereby better reducing the thickness of the display panel 10. For ease of description, the latter embodiments illustrate the isolation structure 310 as being disposed on the side of the pixel limiting portion 321 away from the substrate 100.

In some embodiments of the present application, the material of the first encapsulation structure 400 may include an inorganic material, such that the first encapsulation structure 400 has a better encapsulation capability to reduce the influence of water vapor on the light emitting device 200. Optionally, the first encapsulation structure 400 may be prepared by a chemical vapor deposition process.

As shown in FIG. 22, in some optional embodiments, the first sub-portion 410 may include a body portion 411 and a support portion 412 protruding from the body portion 411 toward the second sub-section 421, the support portion 412 and the second sub-section 421 are connected with each other, so that the first sub-portion 410 and the second sub-section 421 enclose and form the gap space 400a.

Optionally, one end of the body portion 411 facing the isolation structure 310 and one end of the second sub-section 421 facing the substrate 100 are connected with each other, so that the gap space 400a may be enclosed and formed by the body portion 411, the support portion 412, and the second sub-section 421, and there may be two connections between the first sub-portion 410 and the second sub-section 421, which can better improve the structural stability of the first encapsulation structure 400, and make it difficult to be separated from the isolation structure 310. Thus, the encapsulation effect of the first encapsulation structure 400 on the display panel 10 can be better improved.

Optionally, the body portion 411 may include a first body sub-portion 411a and a second body sub-portion 411b that are interconnected, the orthographic projection of the first body sub-portion 411a on the substrate 100 may be located within the orthographic projection of the pixel opening 320a on the substrate 100, and the orthographic projection of the second body sub-portion 411b on the substrate 100 may be located within the orthographic projection of the pixel limiting portion 321 on the substrate 100. One end of the body portion 411 facing the isolation structure 310 and one end of the second sub-section 421 facing the substrate 100 being connected with each other may mean that, one end of the second body sub-portion 411b facing the isolation structure 310 and one end of the second sub-section 421 facing the substrate 100 are connected with each other. Specifically, the gap space 400a may be enclosed and formed by the second body sub-portion 411b, the support portion 412, and the second sub-section 421.

Optionally, the orthographic projection of the support portion 412 on the substrate 100 may at least partially overlap with the orthographic projection of the pixel limiting portion 321 on the substrate 100, that is, at least a part of the support portion 412 may be located at a side of the pixel limiting portion 321 away from the substrate 100, so that the pixel limiting portion 321 may raise the position of the support portion 412 to facilitate the connection between the support portion 412 and the second sub-section 421.

In some optional embodiments, the second sub-section 421 may include a third sub-portion 421b disposed on the side of the second isolation portion 312 facing the isolation opening 310a, and the support portion 412 and the third sub-portion 421b are connected with each other to enclose and form the gap space 400a. Optionally, at least a part of the gap space 400a is located between the second isolation portion 312 and the substrate 100. Here, because that the second isolation portion 312 protrudes from the first isolation portion 311 toward the isolation opening 310a, the third sub-portion 421b disposed on the side of the second isolation portion 312 facing the isolation opening 310a can be easily connected to the support portion 412, that is, the support portion 412 can support the second sub-section 421, so that the second sub-section 421 is not easy to be separated from the isolation structure 310.

Optionally, the second sub-section 421 also includes a second sub-portion 421a disposed at a side of the first isolation portion 311 facing the isolation opening 310a, the third sub-portion 421b is spaced apart from the body portion 411, the second sub-portion 421a is spaced apart from the support portion 412, and the third sub-portion 421b, the second sub-portion 421a, the support portion 412, and the body portion 411 enclose and form the gap space 400a.

Optionally, one end of the second sub-portion 421a away from the substrate 100 may be connected to the third sub-portion 421b, specifically, it may mean that, one end of the second sub-portion 421a away from the substrate 100 may be integratedly connected to the third sub-portion 421b covering the surface of the second isolation portion 312 facing the substrate 100. Optionally, one end of the second sub-portion 421a facing the substrate 100 may be interconnected with one end of the body portion 411 facing the isolation structure 310, for example, one end of the second sub-portion 421a facing the substrate 100 may be interconnected with one end of the second body sub-portion 411b facing the isolation structure 310. Optionally, the gap space 400a may be enclosed and formed by the third sub-portion 421b, the second sub-portion 421a, the second body sub-portion 411b, and the support portion 412.

FIG. 24 is a structure schematic diagram of a first sub-section 610 provided by an embodiment of the present application.

As shown in FIG. 22 to FIG. 24, in some optional embodiments, an orthographic projection of the support portion 412 on the substrate 100 is in a ring shape, and the support portion 412 is interconnected with the second sub-section 421, so that the first sub-portion 410 and the second sub-section 421 enclose and form an enclosed gap space 400a.

Optionally, the orthographic projection of the support portion 412 on the substrate 100 being in the ring shape may mean that the orthographic projection of the support portion 412 on the substrate 100 is in a closed ring shape, so as to facilitate the formation of the enclosed gap space 400a. Here, the enclosed gap space 400a enclosed and formed by the first sub-portion 410 and the second sub-section 421 may not be communicated with other external spaces, thereby further enhancing the structural stability of the first sub-portion 410 and the second sub-section 421.

Optionally, the orthographic projection of the support portion 412 on the substrate 100 may surround the orthographic projection of the pixel opening 320a on the substrate 100. Optionally, the orthographic projection of the second sub-section 421 on the substrate 100 may surround the orthographic projection of the support portion 412 on the substrate 100.

In these optional embodiments, by setting that the orthographic projection of the support portion 412 on the substrate 100 is in the ring shape, the support portion 412 in the isolation opening 310a and the second sub-section 421 on the peripheral side of the isolation structure 310 may have a large connection area, that is, the support portion 412 in the isolation opening 310a can better support the second sub-section 421 on the peripheral side of the isolation structure 310. Therefore, the supporting effect of the support portion 412 on the second sub-section 421 can be better improved, and the first sub-portion 410 is not easily detached from the isolation structure 310, which can better improve the encapsulation effect of the first encapsulation structure 400 on the display panel 10.

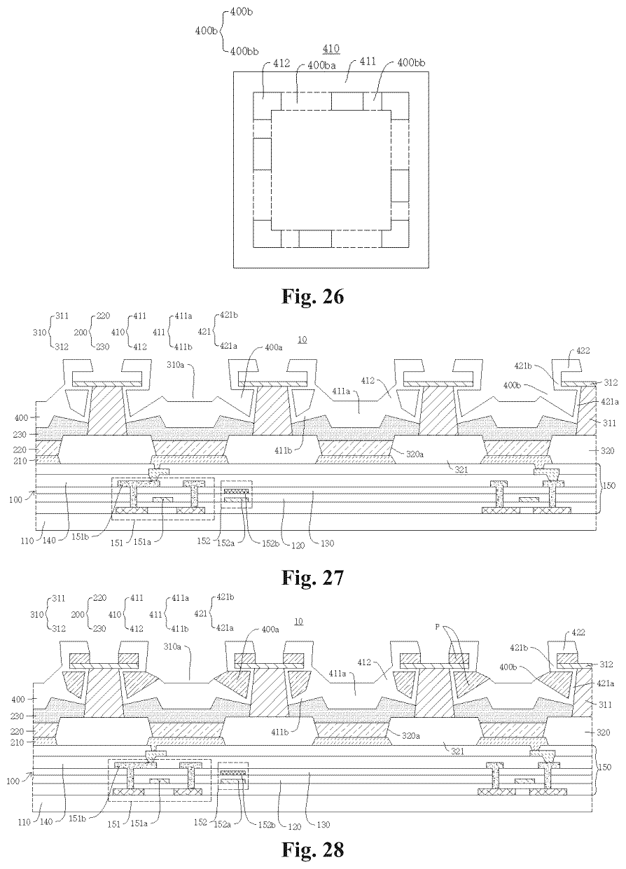

FIG. 25 is a structure schematic diagram of a first sub-section 610 provided by another embodiment of the present application, FIG. 26 is a structure schematic diagram of a first sub-section 610 provided by another embodiment of the present application, and FIG. 27 is a local sectional diagram of a display panel 10 provided by another embodiment of the present application.

As shown in FIG. 25 to FIG. 27, in other optional embodiments, the orthographic projection of the support portion 412 on the substrate 100 may not be in the ring shape, for example, there may be a plurality of support portions 412, and the plurality of support portions 412 may be spaced apart at the peripheral side of the pixel opening 320a.

Optionally, the surface of the first sub-portion 410 away from the substrate 100 and the surface of at least a part of the second sub-section 421 away from the isolation structure 310 may be spaced apart, so as to form a communication opening 400b located at a side of the gap space 400a away from the substrate 100. Optionally, the communication opening 400b may be located between the adjacent support portions 412.

FIG. 28 is a local sectional diagram of a display panel 10 provided by another embodiment of the present application.

As shown in FIG. 28, in some optional embodiments, the gap space 400a can be filled with a support structure P. The support structure P can play a better supporting role for the second sub-section 421, specifically, the support structure P can play a better supporting role for the third sub-portion 421b, so that the second sub-section 421 is not easy to be separated from the isolation structure 310, thereby better improving the encapsulation effect of the first encapsulation structure 400 on the display panel 10.

Optionally, when preparing the display panel 10, the material of the support structure P may be filled to the gap space 400a through the communication opening 400b.

Optionally, the material of the support structure P may include an organic material, such that the material of the support structure P may have good fluidity to allow the support structure P to fill into the gap space 400a through the communication opening 400b.

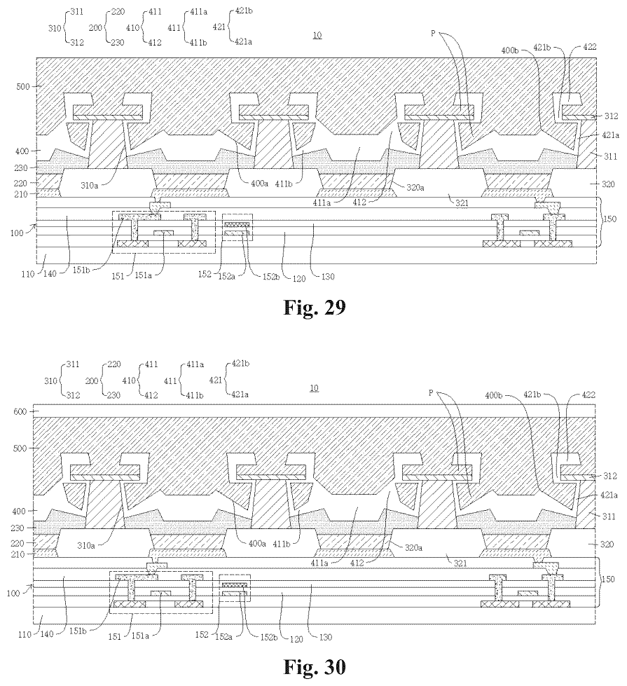

FIG. 29 is a local sectional diagram of a display panel 10 provided by another embodiment of the present application.

As shown in FIG. 29, the display panel 10 also includes a second encapsulation layer 500 disposed on a side of the first encapsulation structure 400 away from the substrate 100, and the material of at least a part of the second encapsulation layer 500 extends into the gap space 400a through the communication opening 400b, so as to form the support structure P.

In these optional embodiments, the second encapsulation layer 500 may also be used to encapsulate the light emitting device 200 of the display panel 10. When preparing the second encapsulation layer 500, the material of the second encapsulation layer 500 may enter into the gap space 400a through the communication opening 400b to form the support structure P, so that a part of the material of the second encapsulation layer 500 can also be used to support the second sub-section 421, thereby further enhancing the structural stability of the first encapsulation structure 400 at the gap space 400a. Moreover, the setting of the second encapsulation layer 500 can further enhance the encapsulation effect of the display panel 10.

Optionally, the material of the second encapsulation layer 500 includes an organic material, such that the second encapsulation layer 500 may have good fluidity to facilitate the extension of the material of the second encapsulation layer 500 into the gap space 400a through the communication opening 400b when the second encapsulation layer 500 is prepared. Optionally, the second encapsulation layer 500 may be prepared by the ink jet printing technology.

In some optional embodiments, as shown in FIG. 25 and FIG. 26, there are a plurality of communication openings 400b, and the plurality of communication openings 400b are spaced apart. For example, the plurality of communication openings 400b may be spaced apart at the peripheral side of the pixel opening 320a. By reasonably setting the number of the communication openings 400b, the connection area of the support portion 412 and the second sub-section 421 can be better regulated. Therefore, the support portion 412 can provide better support for the second sub-section 421 to enhance the structural stability of the first encapsulation structure 400, and at the same time, it can reduce the blocking influence of the support portion 412 on the material of the support structure P, so that the material of the support structure P can be sufficiently filled into the gap space 400a, thereby improving the encapsulation effect of the first encapsulation structure 400 and the second encapsulation layer 500 on the light emitting device 200.

In some optional embodiments, the plurality of communication openings 400b may be equally spaced apart.

Here, the size of the communication opening 400b can be set in various ways. Optionally, as shown in FIG. 25, the areas of the orthographic projections of the communication openings 400b on the substrate 100 may be equal, or the shapes of the orthographic projections of the communication openings 400b on the substrate 100 may be the same. So that, the support portion 412 can be used to uniformly support the second sub-section 421 located at the side of the isolation structure 310 facing the isolation opening 310a, so as to enhance the structural stability of the first encapsulation structure 400. Further, the material of the support structure P can be uniformly filled through the communication opening 400b into the gap space 400a located at the side of the isolation structure 310 facing the isolation opening 310a.

Optionally, as shown in FIG. 26, the communication openings 400b include a first type communication opening 400ba and a second type communication opening 400bb, and the area of the orthographic projection of the first type communication opening 400ba on the substrate 100 is greater than the area of the orthographic projection of the second type communication opening 400bb on the substrate 100. By providing the first type communication opening 400ba and the second type communication opening 400bb having different areas, the first type communication opening 400ba having a larger area can facilitate the sufficient filling of the material of the support structure P into the gap space 400a, and the support portion 412 on two sides of the second type communication opening 400bb having a smaller area may better support the second sub-section 421. Therefore, the support portion 412 can provide better support for the second sub-section 421 to enhance the structural stability of the first encapsulation structure 400, and at the same time, it can reduce the blocking influence of the support portion 412 on the material of the support structure P, so that the material of the support structure P can be sufficiently filled into the gap space 400a.

Optionally, the first type communication opening 400ba is located between adjacent second type communication openings 400bb, and/or, and the second type communication opening 400bb may be located between adjacent first type communication openings 400ba. For example, in the side of the isolation structure 310 facing the isolation opening 310a, the first type communication openings 400ba and the second type communication openings 400bb may be arranged alternately, so as to better balance the structural strength of the first encapsulation structure 400 and the ability of the first encapsulation structure 400 facilitating the filling of the material of the support structure P.

In some optional embodiments, the first encapsulation structure 400 also includes a fourth sub-portion 422 located on the side of the isolation structure 310 away from the substrate 100 and spaced apart from the isolation structure 310. The fourth sub-portion 422 located on the side of the isolation structure 310 away from the substrate 100 may better improve the path of water vapor (including the etching material) to the light emitting device 200, thereby better improving the encapsulation effect of the first encapsulation structure 400 on the light emitting device 200.

Optionally, the fourth sub-portion 422 may be connected to one end of the second sub-section 421 away from the substrate 100. By setting that the surface of the first sub-portion 410 away from the substrate 100 is at least partially interconnected with the surface of the second sub-section 421 away from the isolation structure 310 to enclose and form the gap space 400a, the first sub-portion 410 may play a better supporting role for the second sub-section 421, so that the fourth sub-portion 422 spaced apart from the isolation structure 310 does not easily break off toward the pixel opening 320a, which can better improve the structural stability of the display panel 10.

Optionally, the support structure P may be filled between the fourth sub-portion 422 and the isolation structure 310, and the support structure P filled between the fourth sub-portion 422 and the isolation structure 310 may play a better limiting effect on the fourth sub-portion 422. For example, the support structure P filled between the fourth sub-portion 422 and the isolation structure 310 can be used to support the fourth sub-portion 422, so that the fourth sub-portion 422 does not easily break off toward the isolation structure 310, thereby better improving the structural stability of the first encapsulation structure 400.

Optionally, the material of at least a part of the second encapsulation layer 500 may extend between the fourth sub-portion 422 and the isolation structure 310 to form the support structure P, so that a part of the material of the second encapsulation layer 500 can also be used to support the fourth sub-portion 422.

Optionally, at least a part of the second encapsulation layer 500 may also be located on the side of the fourth sub-portion 422 away from the isolation structure 310, so that the fourth sub-portion 422 may be better wrapped by the second encapsulation layer 500 to further enhance the limiting effect of the second encapsulation layer 500 on the fourth sub-portion 422. Therefore, the second encapsulation layer 500 may limit the breaking of the fourth sub-portion 422 toward the pixel opening 320a, thereby better improving the structural stability of the first encapsulation structure 400.

Optionally, the adjacent fourth sub-portions 422 are spaced apart, for example, the side of the isolation structure 310 away from the substrate 100 may have at least two fourth sub-portions 422, and the fourth sub-portions 422 may be respectively connected to the second sub-section 421 within different isolation openings 310a. By setting that the adjacent fourth sub-portions 422 are spaced apart, when preparing the second encapsulation layer 500, the material of the second encapsulation layer 500 can extend between the fourth sub-portion 422 and the isolation structure 310 through the interval between the adjacent fourth sub-portions 422, thereby facilitating the formation of the second encapsulation layer 500 better wrapping the peripheral side of the fourth sub-portion 422.

FIG. 30 is a local sectional diagram of a display panel 10 provided by another embodiment of the present application.

As shown in FIG. 30, in some optional embodiments, the display panel 10 may also include a third encapsulation layer 600 disposed on a side of the second encapsulation layer 500 away from the substrate 100, so as to further enhance the encapsulation effect of the light emitting device 200.

Optionally, the material of the third encapsulation layer 600 may include an inorganic material, such that the third encapsulation layer 600 has a better encapsulation capability to reduce the influence of water vapor on the light emitting device 200. Optionally, the third encapsulation layer 600 may be prepared by a chemical vapor deposition process.

It is understood that the display panel 10 may also include a light filter layer, an optical adhesive or a cover plate structure located at a side of the third encapsulation layer 600 away from the second encapsulation layer 500.

Please refer to FIG. 1 to FIG. 30, the embodiments of the first aspect of the present application also provide a display panel 10, including: a substrate 100; an isolation structure 310 disposed on a side of the substrate 100 and enclosing and forming an isolation opening 310a, the isolation structure 310 including a first isolation portion 311 and a second isolation portion 312 located on a side of the first isolation portion 311 away from the substrate 100, the second isolation portion 312 protruding from the first isolation portion 311 toward the isolation opening 310a; a light emitting device 200, at least a part of the light emitting device 200 being located within the isolation opening 310a; a first encapsulation structure 400 disposed on a side of the light emitting device 200 away from the substrate 100, the first encapsulation structure 400 including a first sub-portion 410 and a second sub-section 421, the first sub-portion 410 being disposed in the isolation opening 310a and on the side of the light emitting device 200 away from the substrate 100, at least a part of the second sub-section 421 covering a side of the second isolation portion 312 facing the isolation opening 310a and being interconnected with the first sub-portion 410.

In the display panel 10 provided by the embodiments of the present application, the display panel 10 includes the substrate 100, the isolation structure 310, the light emitting devices 200, and the first encapsulation structure 400. The isolation structure 310 is disposed on a side of the substrate 100 and encloses and forms the isolation opening 310a, the light emitting device 200 is at least partially located in the isolation opening 310a, and the isolation structure 310 can be used to divide the sub-pixels of the display panel 10. The first encapsulation structure 400 is disposed on the side of the light emitting device 200 away from the substrate 100, the first encapsulation structure 400 includes the first sub-portion 410 and the second sub-section 421, the first sub-portion 410 is located in the isolation opening 310a and disposed on the side of the light emitting device 200 away from the substrate 100, and the first encapsulation structure 400 may be used to encapsulate the light emitting device 200. By setting that at least a part of the second sub-section 421 covers a side of the second isolation portion 312 facing the isolation opening 310a and is interconnected with the first sub-portion 410, the first sub-portion 410 can provide a better supporting role on the second sub-section 421, so that the second sub-section 421 is not easy to be separated from the isolation structure 310, thereby improving the encapsulation effect of the first encapsulation structure 400 on the display panel 10.

Optionally, the display panel 10 provided by the embodiments of the first aspect of the present application may be the display panel 10 in any of the aforementioned embodiments, and therefore the display panel 10 provided by the embodiments of the present application may have the beneficial effect of the display panel 10 in any of the aforementioned embodiments, which will not be repeated in the present application. For example, the isolation structure 310 may be the isolation structure 310 described in any of the aforementioned embodiments, and the isolation structure 310 may include the first isolation portion 311, the second isolation portion 312 and the third isolation portion 313 described in any of the aforementioned embodiments, so that the isolation structure 310 may be used to block the material of the light emitting unit 220 and the first electrode 230 when preparing the light emitting unit 220 and the first electrode 230 of the light emitting device 200. For example, the first encapsulation structure 400 may be the first encapsulation structure 400 described in any of the aforementioned embodiments. Under the support of the first sub-portion 410, the second sub-section 421 may not be easily separated from the isolation structure 310, and the first sub-portion 410 and the second sub-section 421 may enclose and form the gap space 400a described in any of the aforementioned embodiments. Here, the first sub-portion 410 and the second sub-section 421 may enclose and form an enclosed gap space 400a, or the first sub-portion 410 and the second sub-section 421 may enclose and form a gap space 400a having a communication opening 400b, and the shape and size of the communication opening 400b may be arranged with reference to any of the aforementioned embodiments.

Optionally, the display panel 10 provided by the embodiments of the first aspect of the present application may also include the support structure P described in any of the aforementioned embodiments, and the support structure P may play a better supporting role for the second sub-section 421 and the fourth sub-portion 422, so that the second sub-section 421 and the fourth sub-portion 422 are not easily separated from the isolation structure 310. Optionally, the display panel 10 provided by the embodiments of the first aspect of the present application may also include the second encapsulation layer 500 described in any of the aforementioned embodiments, the second encapsulation layer 500 may extend through the communication opening 400b into the gap space 400a or extend between the fourth sub-portion 422 and the isolation structure 310 to form the support structure P, and the second encapsulation layer 500 may also extend between the fourth sub-portion 422 of the first encapsulation structure 400 and the isolation structure 310, thereby further enhancing the encapsulation effect and structural stability of the display panel 10.

Optionally, the display panel 10 provided by the embodiments of the first aspect of the present application may also include the third encapsulation layer 600 and the pixel definition layer 320 described in any of the aforementioned embodiments.

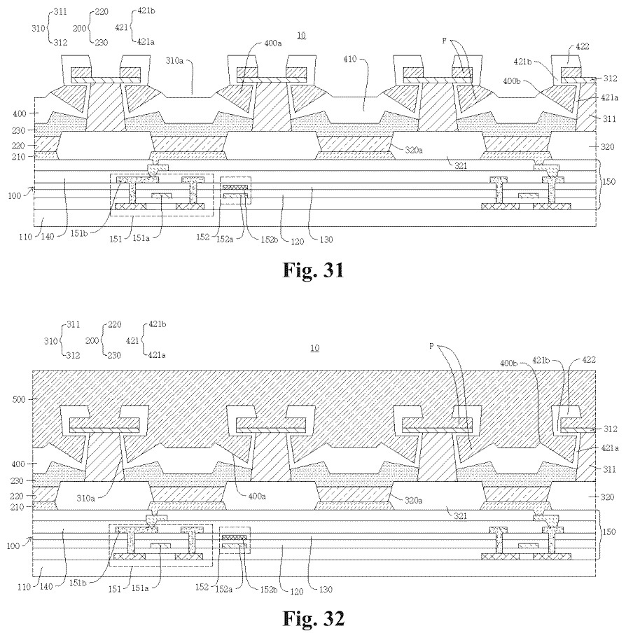

FIG. 31 is a local sectional diagram of a display panel 10 provided by another embodiment of the present application, and FIG. 32 is a local sectional diagram of a display panel 10 provided by another embodiment of the present application.

Please combine FIG. 1 to FIG. 30 and refer to FIG. 31 and FIG. 32, the embodiments of the first aspect of the present application also provide a display panel 10, including: a substrate 100; an isolation structure 310 disposed on a side of the substrate 100 and enclosing and forming an isolation opening 310a; a light emitting device 200, at least a part of the light emitting device 200 being located within the isolation opening 310a; a first encapsulation structure 400 disposed on a side of the light emitting device 200 away from the substrate 100, the first encapsulation structure 400 including a first sub-portion 410 and a second sub-section 421, the first sub-portion 410 being disposed in the isolation opening 310a and on the side of the light emitting device 200 away from the substrate 100, the second sub-section 421 being disposed on a side of the isolation structure 310 facing the isolation opening 310a, the first sub-portion 410 and the second sub-section 421 enclosing and forming a gap space 400a, and the gap space 400a being filled with a support structure P.

In the display panel 10 provided by the embodiments of the present application, the display panel 10 includes the substrate 100, the isolation structure 310, the light emitting devices 200, and the first encapsulation structure 400. The isolation structure 310 is disposed on a side of the substrate 100 and encloses and forms the isolation opening 310a, the light emitting device 200 is at least partially located in the isolation opening 310a, and the isolation structure 310 can be used to divide the sub-pixels of the display panel 10.

The first encapsulation structure 400 is disposed on the side of the light emitting device 200 away from the substrate 100, the first encapsulation structure 400 includes the first sub-portion 410 and the second sub-section 421, the first sub-portion 410 is located in the isolation opening 310a and disposed on the side of the light emitting device 200 away from the substrate 100, the second sub-section 421 is located on the side of the isolation structure 310 facing the isolation opening 310a, and the first encapsulation structure 400 may be used to encapsulate the light emitting device 200. The first sub-portion 410 and the second sub-section 421 enclose and form the gap space 400a. By filling the support structure P in the gap space 400a, the support structure P can play a better supporting role for the second sub-section 421, so that the second sub-section 421 is not easy to be separated from the isolation structure 310, thereby improving the encapsulation effect of the first encapsulation structure 400 on the display panel 10.

Optionally, the display panel 10 provided by the embodiments of the first aspect of the present application may be the display panel 10 in any of the aforementioned embodiments, and therefore the display panel 10 provided by the embodiments of the present application may have the beneficial effect of the display panel 10 in any of the aforementioned embodiments, which will not be repeated in the present application. For example, the isolation structure 310 may be the isolation structure 310 described in any of the aforementioned embodiments, and the isolation structure 310 may include the first isolation portion 311, the second isolation portion 312 and the third isolation portion 313 described in any of the aforementioned embodiments, so that the isolation structure 310 may be used to block the material of the light emitting unit 220 and the first electrode 230 when preparing the light emitting unit 220 and the first electrode 230 of the light emitting device 200. For example, the support structure P may be the support structure P described in any of the aforementioned embodiments, and the support structure P supports the second sub-section 421 and the fourth sub-portion 422.

Optionally, the first sub-portion 410 may not be used to support the second sub-section 421. For example, as shown in FIG. 31 and FIG. 32, the second sub-section 421 covering the side of the second isolation portion 312 facing the isolation opening 310a may not be connected to the first sub-portion 410, or as shown in FIG. 1 to FIG. 30, the first encapsulation structure 400 may be the first encapsulation structure 400 described in any of the aforementioned embodiments, and the first sub-portion 410 may be used to support at least a part of the second sub-section 421, so that the second sub-section 421 may not be easily separated from the isolation structure 310.

Optionally, the first sub-portion 410 and the second sub-section 421 may enclose and form the gap space 400a described in any of the aforementioned embodiments. Here, the first sub-portion 410 and the second sub-section 421 may enclose and form an enclosed gap space 400a, or the first sub-portion 410 and the second sub-section 421 may enclose and form a gap space 400a having a communication opening 400b, and the shape and size of the communication opening 400b may be arranged with reference to any of the aforementioned embodiments.

Optionally, the display panel 10 provided by the embodiments of the first aspect of the present application may also include the second encapsulation layer 500 described in any of the aforementioned embodiments, the second encapsulation layer 500 may extend through the communication opening 400b into the gap space 400a or extend between the fourth sub-portion 422 and the isolation structure 310 to form the support structure P, and the second encapsulation layer 500 may also extend between the fourth sub-portion 422 of the first encapsulation structure 400 and the isolation structure 310, thereby further enhancing the encapsulation effect and structural stability of the display panel 10.

Optionally, the display panel 10 provided by the embodiments of the first aspect of the present application may also include the third encapsulation layer 600 and the pixel definition layer 320 described in any of the aforementioned embodiments.

It should be understood that, the arrangement mode of the first encapsulation structure 400 in the display panel 10 may be adjusted according to the actual situation. That is, within a part of the isolation openings 310a, the surface of the first sub-portion 410 away from the substrate 100 is at least partially interconnected with the surface of the second sub-section 421 away from the isolation structure 310; within a part of the isolation openings 310a, the surface of the first sub-portion 410 away from the substrate 100 is completely interconnected with the surface of the second sub-section 421 away from the isolation structure 310; within a part of the isolation openings 310a, the surface of the first sub-portion 410 away from the substrate 100 is not connected to the surface of the second sub-section 421 away from the isolation structure 310.

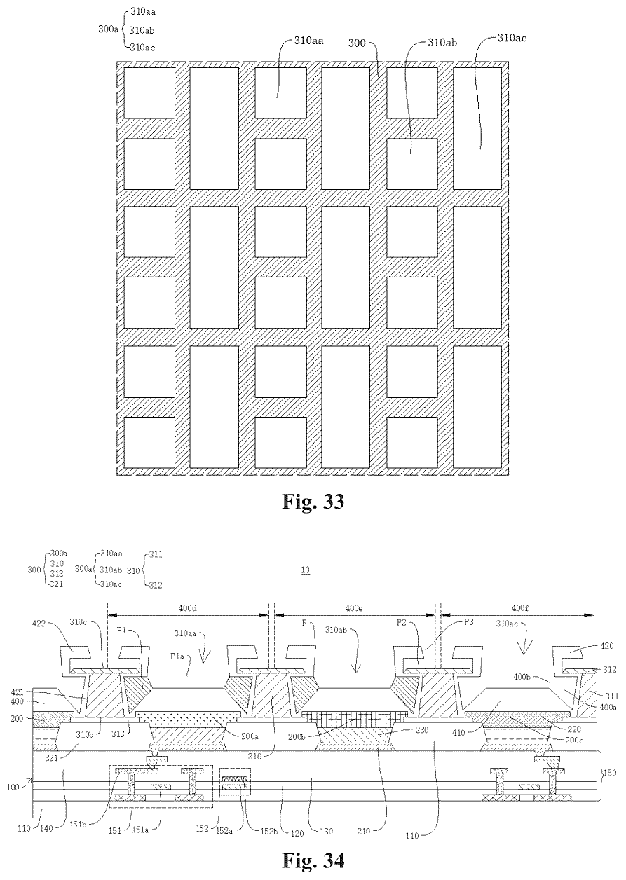

FIG. 33 is a local schematic diagram of a limiting structure 300 provided by another embodiment of the present application, and FIG. 34 is a local sectional diagram of a display panel 10 provided by another embodiment of the present application.

As shown in FIG. 33 and FIG. 34, the embodiments of the first aspect of the present application also provides a display panel 10, including: a substrate 100; a limiting structure 300 disposed on a side of the substrate 100 and enclosing and forming a limiting opening 300a, the limiting structure 300 including an isolation structure 310, the isolation structure 310 having a first end portion 310b and a second end portion 310c that are opposite, the second end portion 310c being located at a side of the first end portion 310b away from the substrate 100, an orthographic projection of the first end portion 310b on the substrate 100 being located in an orthographic projection of the second end portion 310c on the substrate 100; a light emitting device 200 located in the limiting opening 300a; a first encapsulation structure 400 disposed on a side of the light emitting device 200 away from the substrate 100, the first encapsulation structure 400 including a first sub-portion 410 and a side section 420 that are interconnected, the first sub-portion 410 being located in the limiting opening 300a and being disposed on the side of the light emitting device 200 away from the substrate 100, at least a part of the side section 420 being located on a side of the limiting structure 300 facing the limiting opening 300a, the first sub-portion 410 and the side section 420 enclosing and forming a gap space 400a, the gap space 400a being at least partially located on a lower side of the second end portion 310c, and a side of the gap space 400a away from the substrate 100 having a communication opening 400b; a support structure P including a first encapsulation portion P1 disposed at a side of the side section 420 facing the limiting opening 300a, at least a part of the first encapsulation portion P1 being disposed in the gap space 400a and being located between the second end portion 310c and the substrate 100.

In the display panel 10 provided by the embodiments of the present application, the display panel 10 includes the substrate 100, the limiting structure 300, the light emitting device 200, the first encapsulation structure 400, and the support structure P. The limiting structure 300 is disposed on a side of the substrate 100 and encloses and forms the limiting opening 300a, the light emitting device 200 is disposed in the limiting opening 300a, and the limiting structure 300 can be used to divide the sub-pixels of the display panel 10. The limiting structure 300 includes the isolation structure 310, the isolation structure 310 has the first end portion 310b and the second end portion 310c that are opposite, the second end portion 310c is located at the side of the first end portion 310b away from the substrate 100. By setting that the orthographic projection of the first end portion 310b on the substrate 100 is located in the orthographic projection of the second end portion 310c on the substrate 100, when preparing the light emitting device 200 of the display panel 10, the material of the light emitting device 200 can be directly evaporated on the whole surface, the second end portion 310c can block at least a part of the material for preparing the light emitting device 200, so as to separate the material of the light emitting devices 200 in the adjacent sub-pixels, thereby facilitating the formation of the plurality of light emitting devices 200 that are spaced apart and located within the limiting opening 300a. Therefore, there is no need to set the mask with high precision when preparing the light emitting devices 200 of the display panel 10, for example, there is no need to set setting the fine metal mask when evaporating the material of the light emitting device 200. Thus, the production and preparation cost of the display panel 10 can be better reduced.

Optionally, the limiting structure 300 may be in a grid shape to facilitate the division of the sub-pixels of the display panel 10 by the limiting structure 300. Here, the hollow region in the limiting structure 300 in the grid shape may be the limiting openings 300a.

Optionally, the limiting openings 300a may include the isolation opening 310a enclosed and formed by the isolation structure 310.

The first encapsulation layer is disposed on the side of the light emitting device 200 away from the substrate 100, the first encapsulation structure 400 includes the first sub-portion 410 and the side section 420 that are interconnected, the first sub-portion 410 is located in the limiting opening 300a and disposed on the side of the light emitting device 200 away from the substrate 100, at least a part of the side section 420 is located on the side of the limiting structure 300 facing the limiting opening 300a, and the first encapsulation structure 400 may be used to encapsulate the light emitting device 200. The first sub-portion 410 and the side section 420 may enclose and form the gap space 400a, the gap space 400a is at least partially located on the lower side of the second end portion 310c, and the side of the gap space 400a away from the substrate 100 has the communication opening 400b. The support structure P includes the first encapsulation portion P1 disposed at the side of the side section 420 facing the limiting opening 300a, here, at least a part of the first encapsulation portion P1 is disposed in the gap space 400a and is located between the second end portion 310c and the substrate 100. Therefore, the first encapsulation portion P1 can be used to protect a part of the first encapsulation structure 400 located between the second end portion 310c and the substrate 100, so that when patterning the subsequent formed film layer structure using the etching material, the etching material is not easily accessible into the gap space 400a to etch the first encapsulation structure 400. Thus, the side section 420 may have a better structural stability, thereby better improving the encapsulation effect of the first encapsulation structure 400.

Optionally, the display panel 10 provided by the embodiments of the first aspect of the present application may be the display panel 10 in any of the aforementioned embodiments, and therefore the display panel 10 provided by the embodiments of the present application may have the beneficial effect of the display panel 10 in any of the aforementioned embodiments, which will not be repeated in the present application.

In some embodiments of the present application, the first sub-portion 410 may be mainly used to encapsulate the light emitting device 200, so that interference factors such as external water vapor may not easily affect the working reliability of the light emitting device 200, and the side section 420 connected to the first sub-portion 410 and at least partially located on the side of the limiting structure 300 facing the limiting opening 300a may be used to extend the intrusion path of the interference factors, thereby improving the encapsulation effect of the display panel 10.

Here, since a part of the first encapsulation structure 400 will cover the surface of the limiting structure 300, the shape of the first encapsulation structure 400 is susceptible to the shape of the limiting structure 300. For example, under the influence of the shape of the isolation structure 310, the first sub-portion 410 and the side section 420 may easily enclose and form the gap space 400a at the position between the second end portion 310c and the substrate 100. Therefore, under a condition that the other film layer structure is formed directly on the first encapsulation structure 400, the material of the other film layer structure does not easily fall into the gap space 400a under the blocking influence of the second end portion 310c. That is, the first encapsulation structure 400 in at least a part of the gap space 400a is susceptible to exposure from the fracture of the film layer structure, so that when subsequently patterning the film layer structure on the first encapsulation structure 400 using the etching material, the first encapsulation structure 400 is susceptible to destruction by etching, thereby easily affecting the encapsulation effect of the first encapsulation structure 400. Therefore, by setting at least a part of the first encapsulation portion P1 in the gap space 400a and between the second end portion 310c and the substrate 100, the first encapsulation portion P1 can be used to protect at least a part of the first encapsulation structure 400 located between the second end portion 310c and the substrate 100, thereby better improving the encapsulation effect of the display panel 10.

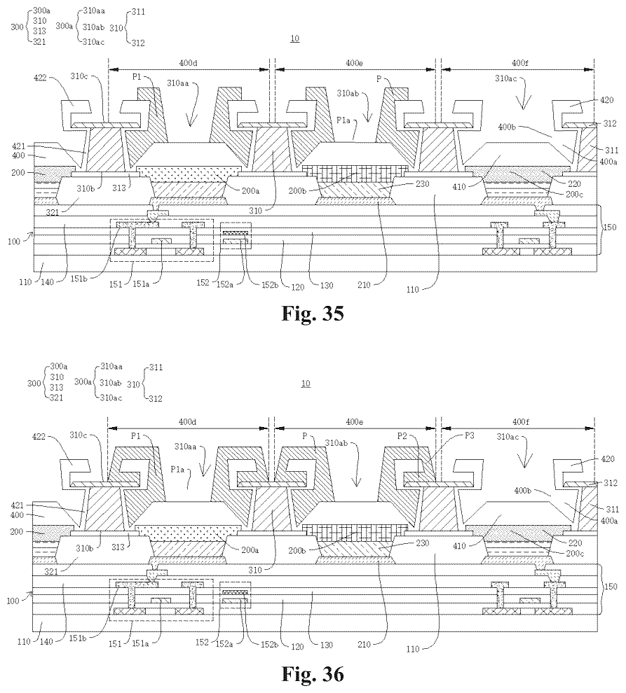

FIG. 35 is a local sectional diagram of a display panel provided by another embodiment of the present application.

As shown in FIG. 35, a part of the first encapsulation portion P1 may be located outside the gap space 400a. Optionally, in a direction away from the substrate 100, a surface of the first encapsulation portion P1 located outside the gap space 400a and away from the side section 420 is inclined toward the side section 420.

Optionally, under the influence of the shape of the isolation structure 310, in the direction away from the substrate 100, the side section 420 located at a side of the second end portion 310c facing the limiting opening 300a in the first encapsulation structure 400 is easily inclined toward the limiting opening 300a. That is, in the direction away from the substrate 100, a surface of the side section 420 facing the limiting opening 300a and located at the side of the second end portion 310c facing the limiting opening 300a is easily inclined toward the limiting opening 300a. Therefore, under a condition that the other film layer structure is formed directly on the first encapsulation structure 400, the other film layer structure is prone to fracture on the surface of the side section 420 facing the limiting opening 300a. That is, at least a part of the side section 420 is susceptible to exposure from the fracture of the film layer structure, so that when subsequently patterning the film layer structure on the side section 420 using the etching material, the side section 420 is susceptible to destruction by etching, thereby easily affecting the encapsulation effect of the first encapsulation structure 400. By providing the first encapsulation portion P1 on the surface of the side section 420 facing the limiting opening 300a, and by setting that the surface of the first encapsulation portion P1 away from the side section 420 is inclined toward the side section 420, the first encapsulation portion P1 may smooth the surface of the side section 420 facing the limiting opening 300a, so that in the subsequent formation of other film layer structures, the other film layer structures may be better formed on the first encapsulation portion P1 and can be continuously on the first encapsulation portion P1. Therefore, the first encapsulation structure 400 and the support structure P are not easily damaged by etching, thereby better improving the encapsulation effect of the display panel 10.

Optionally, there are various ways of setting the material of the support structure P. For example, the support structure P may include an organic material, so that the material of the support structure P has a better fluidity to facilitate the formation of the support structure P, for example, it may facilitate the flow of the support structure P into the gap space 400a. Optionally, the material of the support structure P may also be set according to the etching material for etching the other subsequently formed film layer structures, so that the support structure P is not easy to be destroyed by the etching material when etching the other subsequently formed film layer structures. Optionally, the material of the support structure P may include at least one of the OC adhesive of the peel resistant solution and the polyimide adhesive.

FIG. 36 is a local sectional diagram of a display panel 10 provided by another embodiment of the present application.

As shown in FIG. 36, in some optional embodiments, at least a part of the side section 420 is located at a side of the limiting structure 300 away from the substrate 100 and is spaced apart from the limiting structure 300, and at least a part of the support structure P is located between the side section 420 and the limiting structure 300.

Optionally, the side section 420 includes a fourth sub-portion 422 spaced apart from the limiting structure 300 and a second sub-section 421 located at a side of the limiting structure 300 facing the limiting opening 300a, the support structure P includes a second encapsulation portion P2 and a third encapsulation portion P3 that are interconnected, the second encapsulation portion P2 is located between the fourth sub-portion 422 and the limiting structure 300, and the third encapsulation portion P3 is disposed on a surface of the fourth sub-portion 422 away from the limiting opening 300a.

In these optional embodiments, by setting that at least a part of the support structure P is located between the side section 420 and the limiting structure 300, that is, by setting the second encapsulation portion P2 located between the fourth sub-portion 422 and the limiting structure 300, the support structure P can be used to support a part of the side section 420 located on the side of the limiting structure 300 away from the substrate 100, so that the part of the side section 420 spaced apart from the limiting structure 300 does not easily fall off toward the limiting structure 300. And/or, the support structure P can be used to connect the part of the side section 420 located on the side of the limiting structure 300 away from the substrate 100, so that the side section 420 does not easily fall off toward the limiting opening 300a relative to the limiting structure 300, which can better improve the structural stability of the side section 420.

By setting the third encapsulation portion P3 connected to the second encapsulation portion P2 and disposed on the surface of the fourth sub-portion 422 away from the limiting opening 300a, the connection area between the support structure P and the side section 420 can be further increased, so as to further limit the movement of the side section 420 with respect to the limiting structure 300, thereby further enhancing the structural stability of the side section 420.

Optionally, the first encapsulation portion P1 is disposed on the surfaces of the fourth sub-portion 422 and the second sub-section 421 facing the limiting opening 300a, and the third encapsulation portion P3 is connected with the first encapsulation portion P1, so that the support structure P can better surround the outside of the side section 420, so as to further limit the movement of the side section 420 with respect to the limiting structure 300, thereby further enhancing the structural stability of the side section 420.

Optionally, the gap space 400a may be enclosed and formed by the end portion of the first sub-portion 410 facing the limiting structure 300 and the fourth sub-portion 422.

In these optional embodiments, when preparing the support structure P, the material of the support structure P may enter into the gap space 400a through the communication opening 400b to form at least a part of the first encapsulation portion P1. By providing the first encapsulation portion P1 filled in the gap space 400a, when preparing the other film layer structures on the support structure P, the material of the other film layer structures do not easily enter into the gap space 400a and do not easily break at the communication opening 400b. Therefore, when patterning the film layer structures on the support structure P using the etching material, the etching material may better contact with the film layer structures, which can facilitate the patterning of the film layer structures.

In some embodiments of the present application, the display panel 10 may include light emitting devices 200 of multiple light emitting colors. For example, the display panel 10 may have light emitting devices 200 capable of emitting different color lights such as a red light, a green light, and a blue light.

Optionally, the light emitting devices 200 may include a first light emitting device 200a, a second light emitting device 200b, and a third light emitting device 200c respectively disposed in different limiting openings 300a. Optionally, the light emitting colors of the first light emitting device 200a, the second light emitting device 200b and the third light emitting device 200c are different. For example, the first light emitting device 200a can be used for emitting the red light, the second light emitting device 200b can be used for emitting the green light, and the third light emitting device 200c can be used for emitting the blue light.

Optionally, the limiting openings 300a may include a first opening 310aa for accommodating the first light emitting device 200a, a second opening 310ab for accommodating the second light emitting device 200b, and a third opening 310ac for accommodating the third light emitting device 200c. For example, the isolation openings 310a may include the first opening 310aa, the second opening 310ab, and the third opening 310ac.

In some optional embodiments, the first encapsulation structure 400 has a first encapsulation region 400d, a second encapsulation region 400e, and a third encapsulation region 400f disposed corresponding to the light emitting devices 200 of different light emitting colors.

In this optional embodiment, the first encapsulation structure 400 having the first encapsulation region 400d, the second encapsulation region 400e and the third encapsulation region 400f disposed corresponding to the light emitting devices 200 of different light emitting colors may mean that, the first encapsulation structure 400 located in the first encapsulation region 400d, the first encapsulation structure 400 located in the second encapsulation region 400e, and the first encapsulation structure 400 located in the third encapsulation region 400f may be used to encapsulate the light emitting devices 200 of different light emitting colors.

Optionally, the first encapsulation structure 400 in the first encapsulation region 400d corresponds to the light emitting device 200 for emitting the red light, and the first encapsulation structure 400 located in the first encapsulation region 400d may be used to encapsulate the light emitting device 200 for emitting the red light; the first encapsulation structure 400 in the second encapsulation region 400e corresponds to the light emitting device 200 for emitting the green light, and the first encapsulation structure 400 located in the second encapsulation region 400e may be used to encapsulate the light emitting device 200 for emitting the green light; the first encapsulation structure 400 in the third encapsulation region 400f corresponds to the light emitting device 200 for emitting the blue light, and the first encapsulation structure 400 located in the third encapsulation region 400f may be used to encapsulate the light emitting device 200 for emitting the blue light.

Optionally, the first encapsulation structure 400 in the first encapsulation region 400d corresponds to the first light emitting device 200a, the first encapsulation structure 400 in the second encapsulation region 400e corresponds to the second light emitting device 200b, and the first encapsulation structure 400 in the third encapsulation region 400f corresponds to the third light emitting device 200c.

Optionally, the first encapsulation structure 400 in the first encapsulation region 400d may be located within the first opening 310aa, and may be located at the side of the limiting structure 300 enclosing and forming the first opening 310aa away from the substrate 100; the first encapsulation structure 400 in the second encapsulation region 400e may be located within the second opening 310ab, and may be located at the side of the limiting structure 300 enclosing and forming the second opening 310ab away from the substrate 100; the first encapsulation structure 400 in the third encapsulation region 400f may be located within the third opening 310ac, and may be located at the side of the limiting structure 300 enclosing and forming the third opening 310ac away from the substrate 100.

Optionally, in the first encapsulation region 400d, the second encapsulation region 400e and the third encapsulation region 400f, the side sections 420 in at least two of them are spaced apart, so that the second encapsulation portion P2 and the third encapsulation portion P3 of the support structure P can pass through the interval between the side sections 420 of the adjacent two of the first encapsulation region 400d, the second encapsulation region 400e and the third encapsulation region 400f, and cover the surface of the side section 420 away from the limiting opening 300a, thereby improving the structural stability of the side section 420.

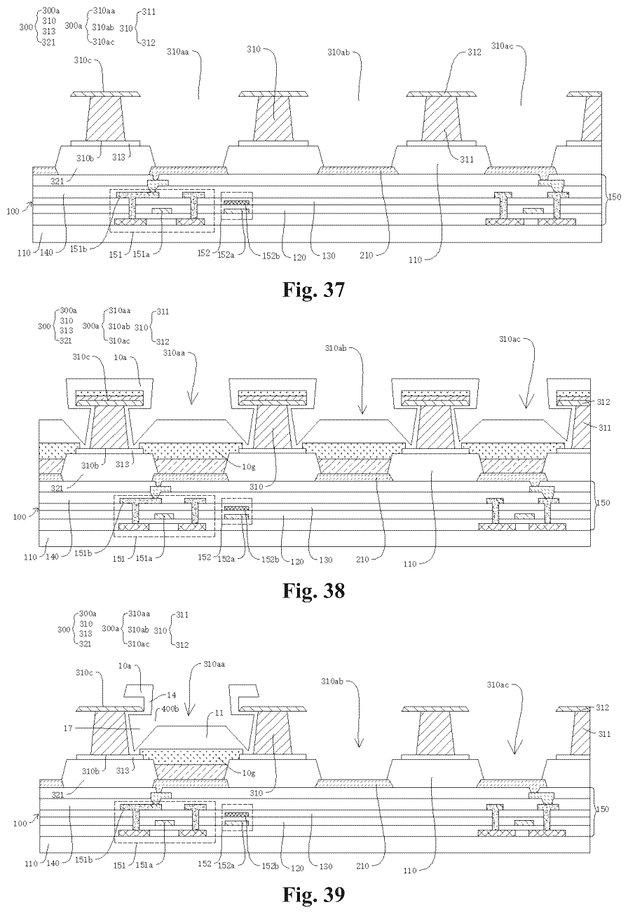

FIG. 37 to FIG. 46 are preparation process schematic diagrams of a preparation method for a display panel 10 provided by an embodiment of the present application.

In these optional embodiments, the formation of the light emitting device 200 and the first encapsulation structure 400 are varied. For example, as shown in FIG. 37 to FIG. 46, in the preparation process of the display panel 10, under the blocking influence of the isolation structure 310 to the material of the light emitting device 200, the light emitting devices 200 of different light emitting colors and a part of the corresponding first encapsulation structure 400 in the display panel 10 may be independently prepared. Here, after completing the preparation of the light emitting device 200 of one light emitting color and the material of a part of the first encapsulation structure 400 thereon, the material of the support structure P can be independently prepared above the material of the part of the first encapsulation structure 400, so that the material of the first encapsulation portion P1 can be formed above the material of the part of the first encapsulation structure 400. Therefore, the first encapsulation structure 400 is not easily damaged by the etching during the patterning process of the subsequent film layer structures, thereby enhancing the structural stability of the first encapsulation structure 400.

In some optional embodiments, in the first encapsulation region 400d, the second encapsulation region 400e, and the third encapsulation region 400f, the first encapsulation portion P1 is located in the gap space 400a within at least two of them.

Optionally, a part of the first encapsulation portion P1 is located in the accommodating space 500d in the first encapsulation region 400d, and a part of the first encapsulation portion P1 is located in the accommodating space 500d in the second encapsulation region 400e.

In these optional embodiments, in the preparation process of the display panel 10, for example, when preparing the light emitting devices 200 in the display panel 10, as shown in FIG. 37 and FIG. 38, the material of the first light emitting device 200a (the first device material layer 10g in the figure) may be firstly evaporated on the whole surface, so that the material of the first light emitting device 200a may be provided in each of the limiting openings 300a. Then, the material of the first encapsulation structure 400 (the first encapsulation material layer 10a in the figure) may be prepared on the whole surface, so that the material of the first light emitting device 200a in each of the limiting openings 300a can be covered by the material of the first encapsulation structure 400. Then, as shown in FIG. 39, the material of the first light emitting device 200a and the material of the first encapsulation structure 400 in the limiting openings 300a other than the first opening 310aa may be removed, so as to form the material of the first light emitting device 200a at least partially located in the first opening 310aa and the material of the first encapsulation structure 400 at least partially located in the first opening 310aa, here, the material of the part of the first encapsulation structure 400 may be used to participate in forming the first encapsulation structure 400 located in the first encapsulation region 400d.

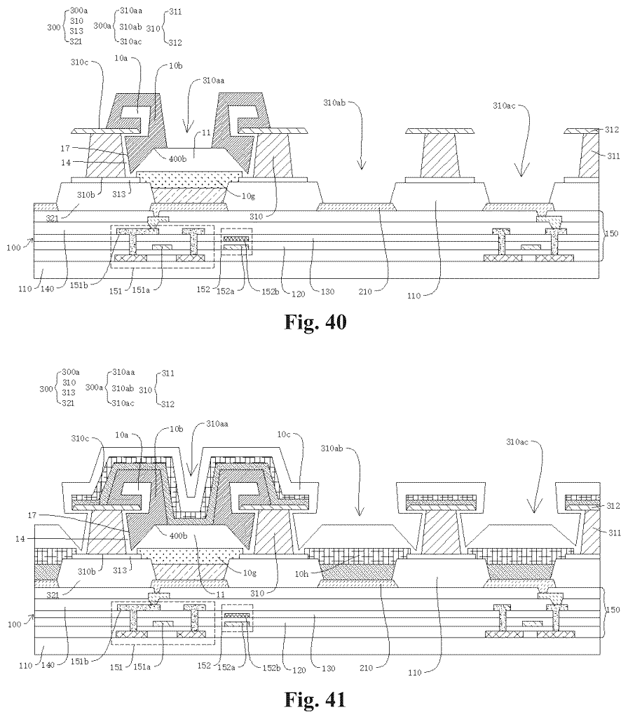

Then, as shown in FIG. 40, the material of the support structure P (the first support material layer 10b in the figure) may be prepared above the material of the first encapsulation structure 400 corresponding to the first light emitting device 200a, so as to form a part of the support structure P, for example, to form a part of the first encapsulation portion P1 located in the accommodating space 500d, or, to form a part of the second encapsulation portion P2 and a part of the third encapsulation portion P3 located on the limiting structure 300 enclosing and forming the first opening 310aa.

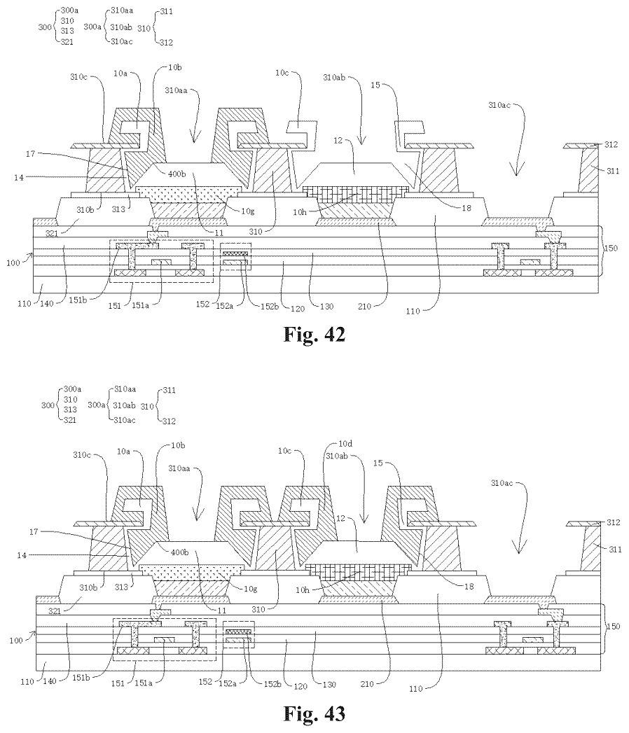

As shown in FIG. 41, the material of the second light emitting device 200b (the second device material layer 10h in the figure) is then evaporated on the whole surface, so that the material of the second light emitting device 200b may be provided in each of the limiting openings 300a. Then, the material of the first encapsulation structure 400 (the second encapsulation material layer 10c in the figure) may be prepared on the whole surface, so that the material of the second light emitting device 200b in each of the limiting openings 300a can be covered by the material of the first encapsulation structure 400. Then, as shown in FIG. 42, the material of the second light emitting device 200b and the material of the first encapsulation structure 400 in the limiting openings 300a other than the second opening 310ab may be removed, so as to form the material of the second light emitting device 200b at least partially located in the second opening 310ab and the material of the first encapsulation structure 400 at least partially located in the second opening 310ab, here, the material of the part of the first encapsulation structure 400 may be used to participate in forming the first encapsulation structure 400 located in the second encapsulation region 400e.

In this process, when preparing the material of the second light emitting device 200b and the material of the first encapsulation structure 400 on the whole surface, by providing at least a part of the first encapsulation portion P1 above the material involved in forming the first encapsulation structure 400 located in the first encapsulation region 400d, the first encapsulation structure 400 enclosing and forming the gap space 400a may be protected by the first encapsulation portion P1, and the material of the second light emitting device 200b and the material of the first encapsulation structure 400 above the communication opening 400b of the gap space 400a may have a better continuity. Therefore, when removing the material of the second light emitting device 200b and the material of the first encapsulation structure 400 in the limiting openings 300a other than the second opening 300ab, the etching material is not prone to cause excessive etching damage to the part of the first encapsulation structure 400, which can better improve the structural stability of the first encapsulation structure 400, thereby improving the encapsulation reliability of the display panel 10, and further improving the encapsulation effect of the display panel 10.

Then, as shown in FIG. 43, the material of the support structure P (the second support material layer 10d in the figure) can be prepared again above the material of the first encapsulation structure 400 corresponding to the second light emitting device 200b, so as to form another part of the support structure P, for example, to form another part of the first encapsulation portion P1 located in the gap space 400a, and/or, to form another part of the second encapsulation portion P2 and another part of the third encapsulation portion P3 located on the limiting structure 300 enclosing and forming the first opening 310aa.

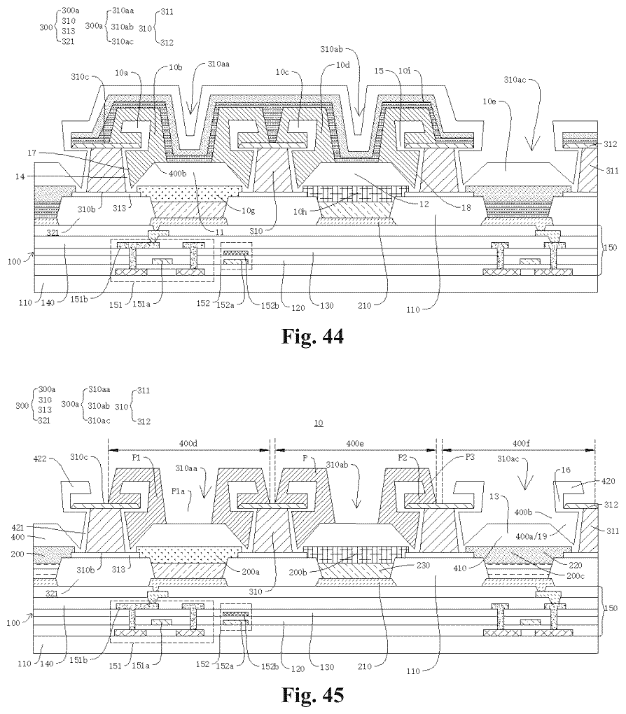

As shown in FIG. 44, the material of the third light emitting device 200c is then evaporated on the whole surface, so that the material of the third light emitting device 200c (the third device material layer 10i in the figure) may be provided in each of the limiting openings 300a. Then, the material of the first encapsulation structure 400 (the third encapsulation material layer 10e in the figure) may be prepared on the whole surface, so that the material of the third light emitting device 200c in each of the limiting openings 300a can be covered by the material of the first encapsulation structure 400. Then, as shown in FIG. 45, the material of the third light emitting device 200c and the material of the first encapsulation structure 400 in the limiting openings 300a other than the third opening 310ac may be removed, so as to form the material of the third light emitting device 200c at least partially located in the third opening 310ac and the material of the first encapsulation structure 400 at least partially located in the third opening 310ac, here, the material of the part of the first encapsulation structure 400 may be used to participate in forming the first encapsulation structure 400 located in the third encapsulation region 400f.

In this process, when preparing the material of the third light emitting device 200c and the material of the first encapsulation structure 400 on the whole surface, by providing at least a part of the first encapsulation portion P1 above the material involved in forming the first encapsulation structure 400 located in the second encapsulation region 400e, the first encapsulation structure 400 enclosing and forming the gap space 400a may be protected by the first encapsulation portion P1, and the material of the third light emitting device 200c and the material of the first encapsulation structure 400 above the communication opening 400b of the gap space 400a may have a better continuity. Therefore, when removing the material of the third light emitting device 200c and the material of the first encapsulation structure 400 in the limiting openings 300a other than the third opening 310ac, the etching material is not prone to cause excessive etching damage to the part of the first encapsulation structure 400, which can better improve the structural stability of the first encapsulation structure 400, thereby improving the encapsulation reliability of the display panel 10, and further improving the encapsulation effect of the display panel 10.

In some optional embodiments, the support structure P is not provided above the first encapsulation structure 400 located in the third encapsulation region 400f, so as to reduce the material cost and reduce the preparation process steps of the support structure P, thereby improving the preparation efficiency of the display panel 10.

In other optional embodiments, a part of the first encapsulation portion P1 may also be located on a surface of the side section 420 facing the limiting opening 300a in the third encapsulation region 400f.

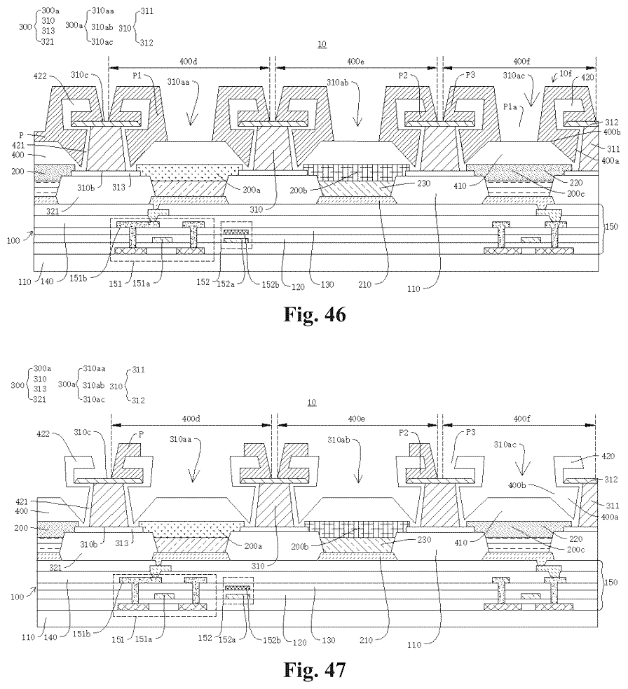

In this optional embodiment, as shown in FIG. 46, after completing the preparing of the third light emitting device 200c and the first encapsulation structure 400 in the third region above the third light emitting device 200c, the material of the support structure P (the third support material layer 10f in the figure) may also be prepared above the first encapsulation structure 400 in the third region, so as to form another part of the support structure P, for example, to form another part of the first encapsulation portion P1 located in the accommodating space 500d, and/or, to form another part of the second encapsulation portion P2 and another part of the third encapsulation portion P3 located on the limiting structure 300 enclosing and forming the first opening 310aa. Therefore, when subsequently preparing other film layer structures on the first encapsulation structure 400 in the third region, the first encapsulation structure 400 enclosing and forming the gap space 400a may be protected by the first encapsulation portion P1, and the other film layer structures may be better formed above the communication opening 400b of the gap space 400a in the third region and can have a better continuity. Therefore, when patterning the film layer structures on the first encapsulation structure 400 in the third region using the etching material, the first encapsulation structure 400 is not susceptible to etching damage by the etching material, so that the first encapsulation structure 400 can have a better structural stability, which can further improve the overall encapsulation effect of the display panel 10.

FIG. 47 is a local sectional diagram of a display panel 10 provided by another embodiment of the present application.

Please combine FIG. 33 to FIG. 46 and refer to FIG. 47, the embodiments of the first aspect of the present application also provides a display panel 10, including: a substrate 100; a limiting structure 300 disposed on a side of the substrate 100 and enclosing and forming a limiting opening 300a, the limiting structure 300 including an isolation structure 310, the isolation structure 310 having a first end portion 310b and a second end portion 310c that are opposite, the second end portion 310c being located at a side of the first end portion 310b away from the substrate 100, an orthographic projection of the first end portion 310b on the substrate 100 being located in an orthographic projection of the second end portion 310c on the substrate 100; a light emitting device 200 located in the limiting opening 300a; a first encapsulation structure 400 disposed on a side of the light emitting device 200 away from the substrate 100, the first encapsulation structure 400 including a first sub-portion 410 and a side section 420 that are interconnected, the first sub-portion 410 being located in the limiting opening 300a and being disposed on the side of the light emitting device 200 away from the substrate 100, at least a part of the side section 420 being located on a side of the limiting structure 300 away from the substrate 100 and being spaced apart from the limiting structure 300; a support structure P at least partially located between the side section 420 and the limiting structure 300.

In the display panel 10 provided by the embodiments of the present application, the display panel 10 includes the substrate 100, the limiting structure 300, the light emitting device 200, the first encapsulation structure 400, and the support structure P. Here, the light emitting device 200 may be the light emitting device 200 described in any of the aforementioned embodiments. Optionally, the display panel 10 may also include a second electrode 210 disposed in the limiting opening 300a, and the second electrode 210 may be located between the light emitting device 200 and the substrate 100. Optionally, the first electrode 230 and the second electrode 210 of the light emitting device 200 may be used as the pixel electrodes of the display panel 10, one of the first electrode 230 and the second electrode 210 may be used as an anode, and the other may be used as a cathode, so as to drive the light emitting unit 220 of the light emitting device 200 to emit light. The first encapsulation structure 400 may also be the first encapsulation structure 400 described in any of the aforementioned embodiments, and which the first encapsulation structure 400 may be used to encapsulate the light emitting device 200.

Further, the limiting structure 300 may be the limiting structure 300 described in any of the aforementioned embodiments. The limiting structure 300 can be used to divide the sub-pixels of the display panel 10, and can be used to block the material of the light emitting device 200, thereby facilitating the formation of the plurality of light emitting devices 200 that are spaced apart and located within the limiting opening 300a. Therefore, there is no need to set the mask with high precision when preparing the light emitting devices 200 of the display panel 10, for example, there is no need to set setting the fine metal mask when evaporating the material of the light emitting device 200. Thus, the production and preparation cost of the display panel 10 can be better reduced.

By setting that at least a part of the support structure P is located between the side section 420 and the limiting structure 300, the support structure P can be used to support a part of the side section 420 located on the side of the limiting structure 300 away from the substrate 100, so that the part of the side section 420 spaced apart from the limiting structure 300 does not easily fall off toward the limiting structure 300. And/or, the support structure P can be used to connect the part of the side section 420 located on the side of the limiting structure 300 away from the substrate 100, so that the side section 420 does not easily fall off toward the limiting opening 300a relative to the limiting structure 300, which can better improve the structural stability of the side section 420. Thus, the encapsulation effect of the display panel 10 can be better improved.

There are various ways of setting the material of the support structure P. For example, the support structure P may include an organic material, so that the material of the support structure P has a better fluidity to facilitate the formation of the support structure P.

In some optional embodiments, the side section 420 includes a fourth sub-portion 422 spaced apart from the limiting structure 300 and a second sub-section 421 located at a side of the limiting structure 300 facing the limiting opening 300a, the support structure P includes a second encapsulation portion P2 and a third encapsulation portion P3 that are interconnected, the second encapsulation portion P2 is located between the fourth sub-portion 422 and the limiting structure 300, and the third encapsulation portion P3 is disposed on a surface of the fourth sub-portion 422 away from the limiting opening 300a.

By setting the second encapsulation portion P2 located between the fourth sub-portion 422 and the limiting structure 300, and by setting the third encapsulation portion P3 connected to the second encapsulation portion P2 and disposed on the surface of the fourth sub-portion 422 away from the limiting opening 300a, the connection area between the support structure P and the side section 420 can be further increased, so as to further limit the movement of the side section 420 with respect to the limiting structure 300, thereby further enhancing the structural stability of the side section 420.

In some optional embodiments, the support structure P includes a first encapsulation portion P1, and at least a part of the first encapsulation portion P1 is disposed at a surface of the side section 420 facing the limiting opening 300a.

Optionally, in a direction away from the substrate 100, a surface of the first encapsulation portion P1 away from the side section 420 is inclined toward the side section 420.

In these optional embodiments, the first encapsulation portion P1 may be used to smooth the surface of the side section 420 facing the limiting opening 300a. By setting that the surface of the first encapsulation portion P1 away from the side section 420 is inclined toward the side section 420, when preparing other film layer structures on the first encapsulation portion P1, the other film layer structures may be better formed on the first encapsulation portion P1 and can be continuously on the first encapsulation portion P1. Therefore, when patterning the film layer structures on the first encapsulation portion P1 using the etching material, the first encapsulation portion P1 is not susceptible to etching damage by the etching material. Thus, the side section 420 may have a better structural stability, thereby better improving the encapsulation effect of the first encapsulation structure 400.

Optionally, the first encapsulation portion P1 is disposed on the surfaces of the fourth sub-portion 422 and the second sub-section 421 facing the limiting opening 300a, and the third encapsulation portion P3 is connected with the first encapsulation portion P1, so that the support structure P can better surround the outside of the side section 420, so as to further limit the movement of the side section 420 with respect to the limiting structure 300, thereby further enhancing the structural stability of the side section 420.

In some optional embodiments, the first sub-portion 410 and the side section 420 may enclose and form the gap space 400a, the gap space 400a is at least partially located on the lower side of the second end portion 310c, the side of the gap space 400a away from the substrate 100 has the communication opening 400b, and at least a part of the first encapsulation portion P1 is disposed in the gap space 400a and is located between the second end portion 310c and the substrate 100.

Optionally, the gap space 400a may be enclosed and formed by the end portion of the first sub-portion 410 facing the limiting structure 300 and the fourth sub-portion 422.

In these optional embodiments, when preparing the support structure P, the material of the support structure P may enter into the gap space 400a through the communication opening 400b to form at least a part of the first encapsulation structure 400. By providing the first encapsulation structure 400 filled in the gap space 400a, when preparing the other film layer structures on the support structure P, the material of the other film layer structures do not easily enter into the gap space 400a and do not easily break at the communication opening 400b. Therefore, when patterning the film layer structures on the support structure P using the etching material, the etching material may better contact with the film layer structures, which can facilitate the patterning of the film layer structures.

In some optional embodiments, the first encapsulation structure 400 may be similar to the first encapsulation structure 400 described in any of the aforementioned embodiments, having a first encapsulation region 400d, a second encapsulation region 400e, and a third encapsulation region 400f disposed corresponding to the light emitting devices 200 of different light emitting colors.

Optionally, the first encapsulation structure 400 in the first encapsulation region 400d corresponds to the light emitting device 200 for emitting the red light, and the first encapsulation structure 400 located in the first encapsulation region 400d may be used to encapsulate the light emitting device 200 for emitting the red light; the first encapsulation structure 400 in the second encapsulation region 400e corresponds to the light emitting device 200 for emitting the green light, and the first encapsulation structure 400 located in the second encapsulation region 400e may be used to encapsulate the light emitting device 200 for emitting the green light; the first encapsulation structure 400 in the third encapsulation region 400f corresponds to the light emitting device 200 for emitting the blue light, and the first encapsulation structure 400 located in the third encapsulation region 400f may be used to encapsulate the light emitting device 200 for emitting the blue light.

Optionally, the first encapsulation structure 400 in the first encapsulation region 400d corresponds to the first light emitting device 200a, the first encapsulation structure 400 in the second encapsulation region 400e corresponds to the second light emitting device 200b, and the first encapsulation structure 400 in the third encapsulation region 400f corresponds to the third light emitting device 200c.

Optionally, in the first encapsulation region 400d, the second encapsulation region 400e and the third encapsulation region 400f, the side sections 420 in at least two of them are spaced apart, so that the second encapsulation portion P2 and the third encapsulation portion P3 of the support structure P can pass through the interval between the side sections 420 of the adjacent two of the first encapsulation region 400d, the second encapsulation region 400e and the third encapsulation region 400f, and cover the surface of the side section 420 away from the limiting opening 300a, thereby improving the structural stability of the side section 420.

In these optional embodiments, the formation of the light emitting device 200 and the first encapsulation structure 400 are varied. For example, as shown in FIG. 37 to FIG. 46, in the preparation process of the display panel 10, under the blocking influence of the isolation structure 310 to the material of the light emitting device 200, the light emitting devices 200 of different light emitting colors and a part of the corresponding first encapsulation structure 400 in the display panel 10 may be independently prepared. Here, after completing the preparation of the light emitting device 200 of one light emitting color and the material of a part of the first encapsulation structure 400 thereon, the material of the support structure P can be independently prepared above the material of the part of the first encapsulation structure 400, so that the material of the second encapsulation portion P2 can be formed above the material of the part of the first encapsulation structure 400. Therefore, in the preparation or patterning of the subsequent film layer structures, the prepared part of the side section 420 is not prone to fall off or drop relative to the limiting structure 300, which can better improve the structural stability of the side section 420, and the encapsulation effect of the display panel 10 can be better improved.

In some optional embodiments, in the first encapsulation region 400d, the second encapsulation region 400e, and the third encapsulation region 400f, at least a part of the support structure P is located between the side section 420 and the limiting structure 300 within at least two of them.

Optionally, at least a part of the support structure P is located between the side section 420 and the limiting structure 300 in the first encapsulation region 400d, and at least a part of the support structure P is located between the side section 420 and the limiting structure 300 in the second encapsulation region 400e.

In these optional embodiments, in the preparation process of the display panel 10, for example, when preparing the light emitting devices 200 in the display panel 10, as shown in FIG. 37 and FIG. 38, the material of the first light emitting device 200a may be firstly evaporated on the whole surface, so that the material of the first light emitting device 200a may be provided in each of the limiting openings 300a. Then, the material of the first encapsulation structure 400 may be prepared on the whole surface, so that the material of the first light emitting device 200a in each of the limiting openings 300a can be covered by the material of the first encapsulation structure 400. Then, as shown in FIG. 39, the material of the first light emitting device 200a and the material of the first encapsulation structure 400 in the limiting openings 300a other than the first opening 310aa may be removed, so as to form the material of the first light emitting device 200a at least partially located in the first opening 310aa and the material of the first encapsulation structure 400 at least partially located in the first opening 310aa, here, the material of the part of the first encapsulation structure 400 may be used to participate in forming the first encapsulation structure 400 located in the first encapsulation region 400d.

Then, as shown in FIG. 40, the material of the support structure P may be prepared above the material of the first encapsulation structure 400 corresponding to the first light emitting device 200a, so as to form a part of the support structure P, for example, to form a part of the first encapsulation portion P1 located in the first opening 310aa, and/or, to form a part of the second encapsulation portion P2 and a part of the third encapsulation portion P3 located on the limiting structure 300 enclosing and forming the first opening 310aa. Here, the material of at least a part of the support structure P may be located between the material of the limiting structure 300 enclosing and forming the first opening 310aa and the material of the first encapsulation structure 400.

As shown in FIG. 41, the material of the second light emitting device 200b is then evaporated on the whole surface, so that the material of the second light emitting device 200b may be provided in each of the limiting openings 300a. Then, the material of the first encapsulation structure 400 may be prepared on the whole surface, so that the material of the second light emitting device 200b in each of the limiting openings 300a can be covered by the material of the first encapsulation structure 400. Then, as shown in FIG. 42, the material of the second light emitting device 200b and the material of the first encapsulation structure 400 in the limiting openings 300a other than the second opening 310ab may be removed, so as to form the material of the second light emitting device 200b at least partially located in the second opening 310ab and the material of the first encapsulation structure 400 at least partially located in the second opening 310ab, here, the material of the part of the first encapsulation structure 400 may be used to participate in forming the first encapsulation structure 400 located in the second encapsulation region 400e.

In this process, when preparing the material of the second light emitting device 200b and the material of the first encapsulation structure 400 on the whole surface, by providing the material of at least a part of the support structure P between the material of the limiting structure 300 enclosing and forming the first opening 310aa and the material of the first encapsulation structure 400, the material of the part of the support structure P can better support and connect with the material of the first encapsulation structure 400 spaced apart from the limiting structure 300 enclosing and forming the first opening 310aa. Therefore, when preparing or patterning the material of the second light emitting device 200b and the material of the first encapsulation structure 400, the material of the part of the first encapsulation structure 400 is not prone to fall off or drop, which can better improve the structural stability of the finally formed first encapsulation structure 400 and the support structure P, thereby improving the encapsulation reliability of the display panel 10, and further improving the encapsulation effect of the display panel 10.

As shown in FIG. 43, the material of the support structure P can be prepared again above the material of the first encapsulation structure 400 corresponding to the second light emitting device 200b, so as to form another part of the support structure P, for example, to form another part of the first encapsulation portion P1 located in the first opening 310aa, and/or, to form another part of the second encapsulation portion P2 and another part of the third encapsulation portion P3 located on the limiting structure 300 enclosing and forming the first opening 310aa. Here, the material of at least a part of the support structure P may be located between the material of the limiting structure 300 enclosing and forming the second opening 310ab and the material of the first encapsulation structure 400.

As shown in FIG. 44, the material of the third light emitting device 200c is then evaporated on the whole surface, so that the material of the third light emitting device 200c may be provided in each of the limiting openings 300a. Then, the material of the first encapsulation structure 400 may be prepared on the whole surface, so that the material of the third light emitting device 200c in each of the limiting openings 300a can be covered by the material of the first encapsulation structure 400. Then, as shown in FIG. 45, the material of the third light emitting device 200c and the material of the first encapsulation structure 400 in the limiting openings 300a other than the third opening 310ac may be removed, so as to form the material of the third light emitting device 200c at least partially located in the third opening 310ac and the material of the first encapsulation structure 400 at least partially located in the third opening 310ac, here, the material of the part of the first encapsulation structure 400 may be used to participate in forming the first encapsulation structure 400 located in the third encapsulation region 400f.

In this process, when preparing the material of the third light emitting device 200c and the material of the first encapsulation structure 400 on the whole surface, by providing the material of at least a part of the support structure P between the material of the limiting structure 300 enclosing and forming the second opening 310ab and the material of the first encapsulation structure 400, the material of the part of the support structure P can better support and connect with the material of the first encapsulation structure 400 spaced apart from the limiting structure 300 enclosing and forming the second opening 310ab. Therefore, when preparing or patterning the material of the third light emitting device 200c and the material of the first encapsulation structure 400, the material of the part of the first encapsulation structure 400 is not prone to fall off or drop, which can better improve the structural stability of the finally formed first encapsulation structure 400 and the support structure P, thereby improving the encapsulation reliability of the display panel 10, and further improving the encapsulation effect of the display panel 10.

In some optional embodiments, the support structure P is not provided above the first encapsulation structure 400 located in the third encapsulation region 400f, so as to reduce the material cost and reduce the preparation process steps of the support structure P, thereby improving the preparation efficiency of the display panel 10.

In other optional embodiments, at least a part of the support structure P may also be located between the side section 420 and the limiting structure 300 in the third encapsulation region 400f.

In this optional embodiment, as shown in FIG. 46, after completing the preparing of the third light emitting device 200c and the first encapsulation structure 400 in the third region above the third light emitting device 200c, the material of the support structure P may also be prepared above the first encapsulation structure 400 in the third region, so as to form another part of the support structure P, for example, to form another part of the first encapsulation portion P1 located in the first opening 310aa, and/or, to form another part of the second encapsulation portion P2 and another part of the third encapsulation portion P3 located on the limiting structure 300 enclosing and forming the first opening 310aa. Here, at least a part of the support structure P is located between the side section 420 and the limiting structure 300 in the third encapsulation region 400f, so that the material of the part of the support structure P can better support and connect with the material of the first encapsulation structure 400 spaced apart from the limiting structure 300 enclosing and forming the third opening 310ac. Therefore, when subsequently preparing or patterning the other film layer structures, the material of the part of the first encapsulation structure 400 is not prone to fall off or drop, which can better improve the structural stability of the finally formed first encapsulation structure 400 and the support structure P, thereby improving the encapsulation reliability of the display panel 10, and further improving the encapsulation effect of the display panel 10.

In the display panel 10 of any of the aforementioned embodiments, the first encapsulation portion P1 may enclose and form a transparent opening P1a, and the orthographic projection of the transparent opening P1a on the substrate 100 is at least partially overlapped with the orthographic projection of the light emitting device 200 on the substrate 100, so that the light emitted by the light emitting device 200 can be emitted outward through the transparent opening P1a, thereby reducing the blocking influence of the support structure P on the light emitted by the light emitting device 200, and better improving the display effect of the display panel 10.

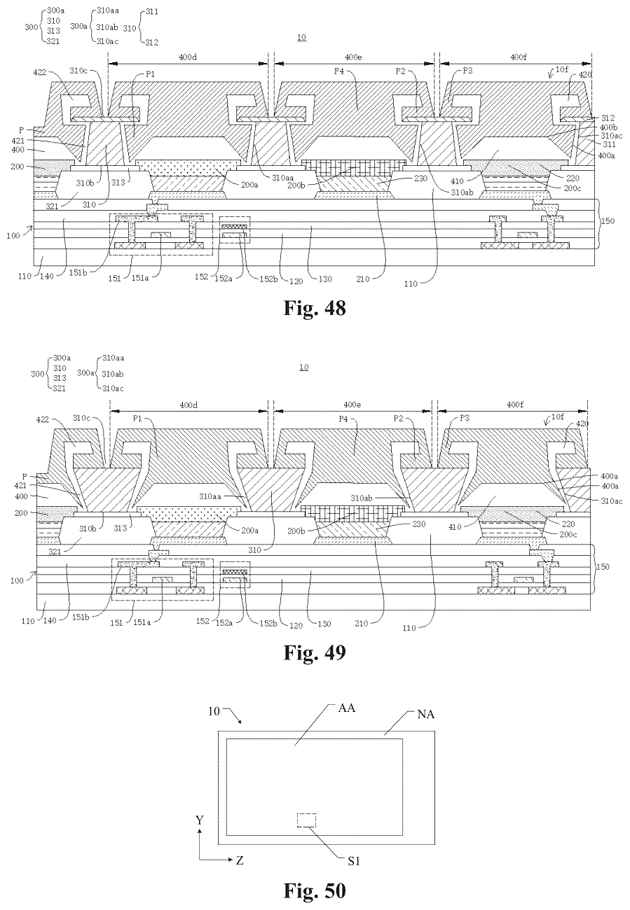

FIG. 48 is a local sectional diagram of a display panel 10 provided by another embodiment of the present application.

Optionally, as shown in FIG. 48, the support structure P is not provided with the transparent opening P1a. For example, the support structure P also includes a fourth encapsulation portion P4 disposed at a side of the first sub-portion 410 away from the substrate 100 and connected to the first encapsulation portion P1, so that when preparing the support structure P, it is not necessary to add the process step of providing the transparent opening P1a, which can increase the preparation efficiency of the support structure P. Here, the fourth encapsulation portion P4 may be prepared together with at least one of the first encapsulation portion P1, the second encapsulation portion P2 and the third encapsulation portion P3, for example, the first encapsulation portion P1, the second encapsulation portion P2, the third encapsulation portion P3 and the fourth encapsulation portion P4 may be integratedly prepared.

Optionally, the material of the support structure P includes a transparent organic material, so that the light emitted by the light emitting device 200 can better pass through the support structure P, so as to reduce the blocking effect of the support structure P on the light emitted by the light emitting device 200.

In some optional embodiments, the limiting structure 300 may also include a third isolation portion 313 disposed at a side of the isolation structure 310 facing the substrate 100, and at least a part of the third isolation section 313 protrudes toward the limiting opening 300a relative to the isolation structure 310, so as to connect to the first electrode 230.

Optionally, the material of the third isolation portion 313 may include a conductive material.

In these optional embodiments, by setting the third isolation portion 313 below the isolation structure 310, and by setting that the third isolation portion 313 is connected to the first electrode 230, the first electrodes 230 in the adjacent limiting openings 300a may be electrically connected by the third isolation portion 313, so as to facilitate the control of the first electrodes 230. By setting that at least a part of the third isolation section 313 protrudes toward the limiting opening 300a relative to the isolation structure 310, it is possible to facilitate the contact between the first electrode 230 and the third isolation portion 313, and it is possible to better increase the contact area between the first electrode 230 and the third isolation portion 313, thereby reducing the resistance of the display panel 10.

Optionally, the limiting structure 300 also includes a pixel limiting portion 321 disposed between the adjacent second electrodes 210, the adjacent second electrodes 210 may be insulated by the pixel limiting portion 321, and the setting of the pixel limiting portion 321 may facilitate the division of the sub-pixels in the display panel 10.

Optionally, the limiting opening 300a may also include a pixel opening 320a enclosed and formed by the pixel limiting portion 321.

In the embodiments of the present application, the specific shape of the isolation structure 310 can be set in a variety of ways, and the shape of the isolation structure 310 may be any shape capable of blocking and isolating the material of the light emitting device 200.

In some optional embodiments, as shown in FIG. 34 to FIG. 48, the isolation structure 310 includes the first isolation portion 311 and the second isolation portion 312 located on the side of the first isolation portion 311 away from the substrate 100, the orthographic projection of the first isolation portion 311 on the substrate 100 is located in the orthographic projection of the second isolation portion 312 on the substrate 100, and the second isolation portion 312 protrudes from the first isolation portion 311 toward the first limiting opening 300a, so that the blocking effect of the second isolation portion 312 on the material of the light emitting device 200 can be better improved. Here, the first end portion 310b may be located in the first isolation portion 311, and the second end portion 310c may be located in the second isolation portion 312.

Optionally, the first isolation portion 311 may include a conductive material, and the first electrode 230 may be electrically connected to the first isolation portion 311.

FIG. 49 is a local sectional diagram of a display panel 10 provided by another embodiment of the present application.

In other optional embodiments, as shown in FIG. 49, in the direction away from the substrate 100, the distance between the two surfaces of the isolation structure 310 facing the limiting opening 300a gradually increases, so as to form a shape that the orthographic projection of the first end portion 310b on the substrate 100 is located within the orthographic projection of the second end portion 310c on the substrate 100.

The embodiments of the first aspect of the present application also provides a display panel 10. In some attached drawings, the spatial rectangular coordinate system is established based on the substrate, so as to present the position relationship of the relevant structures in the display panel more intuitively. In the spatial rectangular coordinate system, the Z axis and the Y axis are parallel to the plane of the substrate, and the X axis is perpendicular to the plane of the substrate.

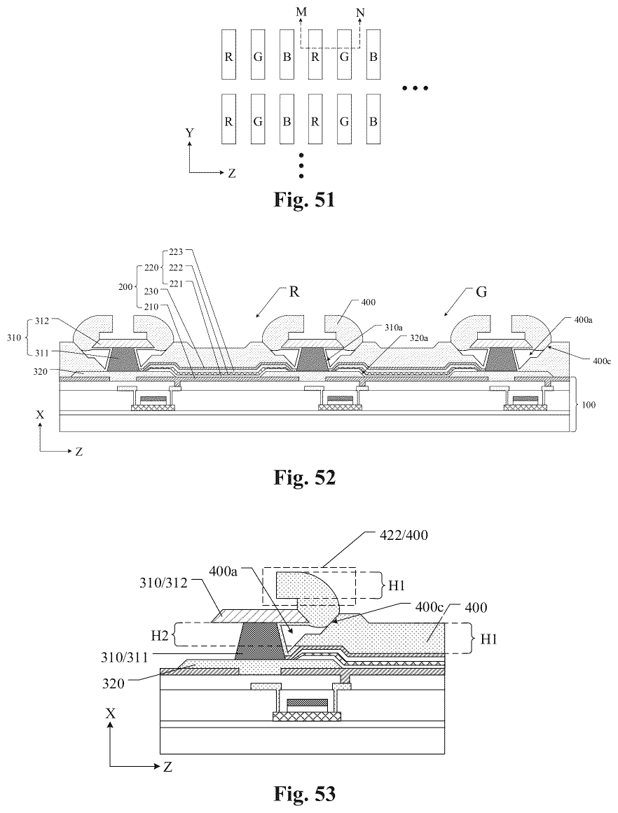

As shown in FIG. 50 to FIG. 53, the plane region of the display panel 10 can be divided into a display region AA and a frame region NA surrounding the display region AA. Sub-pixels (may be called small pixels) are arranged in the display region AA, such as R, G, and B sub-pixels. The physical structure of the sub-pixel may be a light emitting device, and the adjacent sub-pixels with different light emitting colors constitute a pixel (may be called a pixel unit, a large pixel, etc.), and the arrangement density of the pixels in the display region AA represents the pixel density PPI. It should be noted that, in some embodiments of the present application, a part of the wirings in the frame region NA can be arranged into the display region AA, so that the frame region NA can be designed as a unilateral frame.

The physical structure of the display panel 10 may include a substrate 100 as well as a display function layer and an isolation structure 310 located on the substrate 100, and the display function layer includes a plurality of light emitting devices 200.

The isolation structure 310 is located at the substrate 100 and defines a plurality of isolation openings 310a, that is, the flat shape of the isolation structure 310 is presented as a grid pattern, and the isolation openings 310a are a mesh with a grid pattern. The isolation structure 310 includes a first isolation portion 311 facing the substrate 100 and a second isolation portion 312 away from the substrate 100. The orthographic projection of the first isolation portion 311 is located within the orthographic projection of the substrate 100. That is, the isolation structure 310 as a whole is wide at the top and narrow at the bottom, so that when vaporizing some of the film layers in the light emitting device 200 (such as the following light emitting unit), it may be disconnected at the edge of the isolation structure 310, so as to reduce the crosstalk risk of the adjacent light emitting devices.

One side of the light emitting device 200 and the isolation structure 310 away from the substrate 100 is covered with the first encapsulation structure 400, because that the isolation structure 310 is wide at the top and narrow at the bottom, the first encapsulation structure 400 forms a gap space 400a on the side of the isolation structure 310. Further, the part of the first encapsulation structure 400 covering the second isolation portion 312 and the part of the first encapsulation structure 400 covering the light emitting device 200 are enclosed (contacted), so that the gap space 400a is an enclosed space. Therefore, in the preparation process of different types of light emitting devices, harmful materials such as corrosive fluids or etching gases do not flow into the enclosed space.

It should be noted that, the first encapsulation structure 400 may be formed in a manner of vapor deposition (such as chemical vapor deposition, CVD). During this film formation process, the encapsulation material is deposited on the surface of the isolation structure 310 and the surface of the light emitting device 200. At the position where the gap space 400a is located, the encapsulation material will form a thin film layer, and in this case, the gap space 400a is still an open space (which is communicated with the outside world). Further, with the increase of the deposition thickness of the material, the width of the opening of the gap space 400a gradually decreases, thereby preventing the encapsulation material from entering into the gap space 400a. Therefore, the thickness of the part of the first encapsulation structure 400 located in the gap space 400a is much less than the thickness of the part of the first encapsulation structure 400 located outside of the gap space 400a.

In the embodiments of the present application, by designing the height of the isolation structure 410 and the thickness of the first encapsulation structure 400 for the purpose of the first encapsulation structure 400 to close the gap space 400a, in this case, even if the thickness of the part of the first encapsulation structure 400 located in the gap space 400a is relatively thin, it will not reduce the encapsulation effect of the first encapsulation structure 400 on the light emitting device 200.

As shown in FIG. 52 and FIG. 53, the isolation structure 310 is used to block a part of the film layers in the light emitting device 200, and correspondingly, the part of the film layers of the light emitting device 200 extend to the edge of the isolation structure 310. At the edge, the light emitting device 200 has a certain thickness to affect the height of the first encapsulation structure 400 covering the light emitting device 200, that is, the thickness of the first encapsulation structure 400 required for affecting the confining of the gap space 400a.

Thus, in at least one embodiment of the present application, as shown in FIG. 52 and FIG. 53, the thickness of the part of the first encapsulation structure 400 covering the surface of the second isolation portion 312 away from the substrate 100 (the fourth sub-portion 422 shown in FIG. 53) is the first thickness H1, and at the edge of the second isolation portion 312, the distance of the edge of the surface of the second isolation portion 312 facing the substrate 100 to the surface of the light emitting device 200 away from the substrate 100 is the second spacing H2, and the ratio of the first thickness H1 to the second spacing H2 is not less than 1. Thus, under a condition that the ratio of the first thickness H1 to the second spacing H2 is not less than 1, it can guarantee that the first packing structure 400 can completely confine the gap space 400a formed at the edge of the isolation structure 310 in the actual process.

Optionally, the display panel 10 provided by the embodiments of the first aspect of the present application may be the display panel 10 in any of the aforementioned embodiments, and therefore the display panel 10 provided by the embodiments of the present application may have the beneficial effect of the display panel 10 in any of the aforementioned embodiments, which will not be repeated in the present application.

As shown in FIG. 52 and FIG. 53, a larger ratio of the first thickness H1 to the second spacing H2 means that the thickness of the first encapsulation structure 400 is larger relative to the second spacing H2, which also increases the width of the connection portion 400c of the first encapsulation structure 400 at the sealing position of the gap space 400a, thereby improving the sealing effect.

In at least one embodiment of the present application, the ratio of the first thickness H1 to the second spacing H2 may be set as being not less than 1.1. Thus, as shown in FIG. 52 and FIG. 53, the width of the connection portion 400c between the portion of the first encapsulation structure 400 covering the second isolation portion 312 and the portion of the first encapsulation structure 400 covering the light emitting device 200 is greater than zero. Thus, it can guarantee that the first encapsulation structure 400 has a relatively large sealing width at the sealing position, thereby improving the sealing effect of the first encapsulation structure 400.

In at least one embodiment of the present application, the ratio of the first thickness H1 to the second spacing H2 may be set as being not less than 1.4, in this case, the width of the connection portion 400c between the portion of the first encapsulation structure 400 covering the second isolation portion 312 and the portion of the first encapsulation structure 400 covering the light emitting device 200 is not less than 3000 angstroms. In the preparation process of different types of light emitting devices, the corrosive fluids (or etching gases) may corrode the first encapsulation structure 400 to a certain extent. In these embodiments, the connection portion 400c can have a sufficient width to ensure that the gap space 400a is completely enclosed even if the first encapsulation structure 400 is thinned by corrosion.

In at least one embodiment, the ratio of the first thickness H1 to the second spacing H2 is 1.4 to 2.4, and the width of the contact interface between the portion of the first encapsulation layer covering the crown portion and the portion of the first encapsulation layer covering the light emitting device is 3000 to 8000 angstroms. Under a condition that the thickness of the first encapsulation structure 400 is too large, it will increase the stress generated by deformation (for example, the display panel is a flexible display panel), and the first encapsulation structure 400 is prone to damage due to stress concentration. Under a condition that the ratio of the first thickness H1 to the second spacing H2 is within the above numerical range, it can guarantee that the first encapsulation structure 400 has a sufficient sealing width at the sealing position, and at the same time, it can avoid the excessive thickness of the first encapsulation structure 400 from causing adverse effects on the performance of the display panel (for example, flexibility, and encapsulation).

There are many arrangement modes of the isolation structure, and the types of the film layers in the light emitting device can be selected according to different requirements, and these designs may affect the calculation of the second spacing. Therefore, the following is a brief introduction to the specific structures of the light emitting device and the isolation structure, so as to explain the calculation method of the second spacing H2.

As shown in FIG. 52 and FIG. 53, the light emitting device 200 includes a second electrode 210, a light emitting unit 220, and a first electrode 230 that are sequentially stacked on the substrate 100. The light emitting unit 220 and the first electrode 230 of each light emitting device 200 are located in the corresponding isolation opening 310a, and the orthographic projection of the edge of the second isolation portion 312 on the substrate 100 is located within the orthographic projections of the light emitting unit 220 and the first electrode 230 on the substrate 100. That is, when calculating the second spacing H2, it is necessary to consider the thicknesses of the light emitting unit 220 and the first electrode 230.

For example, the light emitting unit may also include a light emitting layer 222 and a second function layer 223, and the first function layer 221, the light emitting layer 222 and the second function layer 223 are sequentially stacked on the second electrode 210. The first function layer 221 may include a hole inject layer, a hole transport layer, an electron barrier layer, and the like. The second function layer 223 may include an electron inject layer, an electron transport layer, a hole barrier layer, and the like. It should be noted that since the carriers (holes, and electrons) are mainly crosstalk between the adjacent light emitting devices 200 through the first function layer 221, the arrangement of the isolation structure 310 requires that the first function layers 221 of the light emitting devices 200 are electrically disconnected from each other.

For example, in at least one embodiment of the present application, the first electrode may be set as an anode, and the second electrode may be set as a cathode.

Since the isolation structure 310 is wide at the top and narrow at the bottom, the first function layer 221 is disconnected at the edge of the second isolation portion 312 during the evaporation. That is, the first function layer 221 is not connected to the conductive portion of the isolation structure 310 (for example, the first isolation portion 311) to cause crosstalk between the adjacent light emitting devices 200.

In the embodiments of the present application, the isolation structure is used to connect the second electrode, and in order to avoid connecting the isolation structure with the first electrode, the size of the first electrode may be reduced to separate the first electrode from the isolation structure, or, an insulating layer may be provided between the first electrode and the isolation structure.

For example, in some embodiments of the present application, as shown in FIG. 52 and FIG. 53, the display panel may also include a pixel definition layer 320 located between the substrate 100 and the isolation structure 310, and the pixel definition layer 320 defines a plurality of pixel openings 320a respectively corresponding to the isolation openings 310a. The orthographic projection of the pixel opening 320a on the substrate 100 is located within the orthographic projection of the corresponding isolation opening 310a on the substrate 100, the light emitting unit 220 and the first electrode 230 fill the pixel opening 320a and extend to the surface of the pixel definition layer 320 away from the substrate 100, and the difference between the sum of the thicknesses of the parts of the light emitting unit 220 and the first electrode 230 overlapping with the pixel definition layer 320 and the height of the first isolation portion 311 may equal to the second spacing H2.

It should be noted that in the embodiments of the present application, “the height of the support portion” is a spacing from the surface of the support portion facing the substrate to the surface of the support portion in contact with the crown portion.

For example, in some designs, the first isolation portion 311 and the second isolation portion 312 may be an integrated structure, the isolation structure 310 is a conductive structure, and the first electrode 230 of the light emitting device 200 is connected to the first isolation portion 311. The integrated structure may be an independent film layer, and there is no physical interface in the film layer, and the first isolation portion 311 and the second isolation portion 312 are two parts of the integrated structure. For example, further, along the direction perpendicular to the substrate 100, the section shape of the second isolation portion 312 is an inverted trapezoid, and the top side of the inverted trapezoid is facing the substrate 100, that is, the top side of the inverted trapezoid is located between the substrate 100 and the bottom side of the inverted trapezoid.

For example, in some other designs, the first isolation portion 311 and the second isolation portion 312 are two independent film layers, the first isolation portion 311 is a conductive structure, and the first electrode 230 of the light emitting device 200 is connected to the support portion. For example, further, along the direction perpendicular to the substrate 100, the section shape of the support portion is trapezoid, and the crown portion is located at the top side of the support portion. In this case, it can facilitate the deposition of the evaporation material of the first electrode 230 on the side wall of the support portion, so as to improve the contact yield of the first electrode 230 and the support portion.

For example, in some embodiments of the present application, for example, the support portion of the isolation structure is located in the gap between the adjacent first electrodes and spaced from the first electrodes, and the difference between the sum of the thicknesses of the parts of the first electrode, the light emitting unit and the second electrode overlapping with the edge of the crown portion and the height of the support portion may be equal to the second spacing.

The present application provides a display panel in which the space on one side of the isolation structure is not sealed as a contrast example, so as to state the reason why the first encapsulation layer is prone to encapsulation failure during the preparation process of the display panel without the design mentioned in the above embodiments, which will be specifically described in the following.

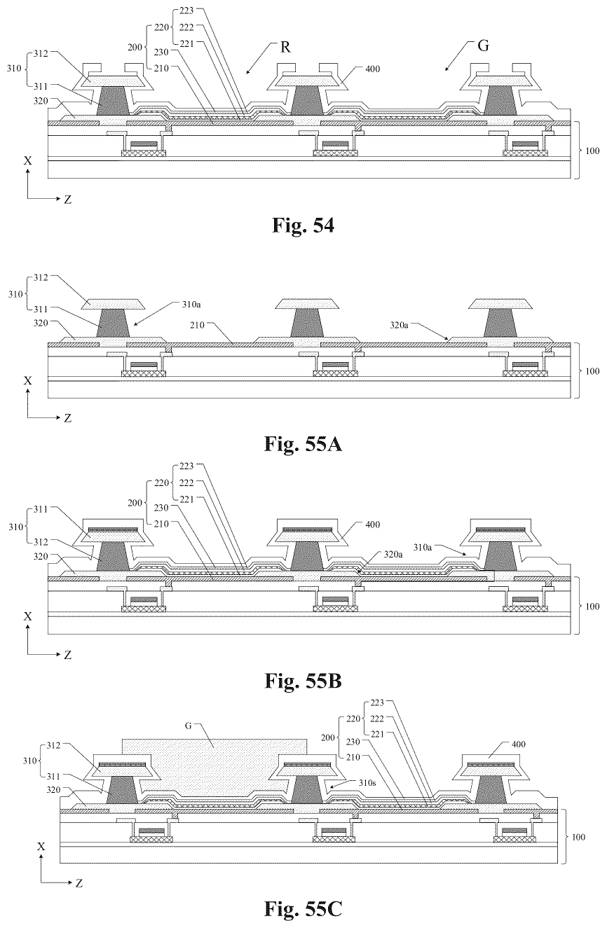

As shown in FIG. 54, on the side of the isolation structure 310, the space enclosed by the first encapsulation structure 400 is not sealed. It should be noted that the light emitting devices 200 with different outgoing light are prepared independently, but the film layer in the light emitting devices 200 (the evaporated film layer, such as the light emitting units) are evaporated on the whole surface on the display panel during evaporation. For example, the light emitting devices 200 are classified as the light emitting devices for emitting the red light (R), the light emitting devices for emitting the green light (G), and the light emitting devices for emitting the blue light (B) respectively. In the preparation process, the light emitting devices R, G, and B are prepared sequentially. When preparing the light emitting devices R, the light emitting device R is formed in each isolation opening 310a, the first encapsulation structure 400 is prepared on the display panel to cover the light emitting devices R, then, the first encapsulation structure 400 and the second electrode and the light emitting unit of the light emitting device R in a part of the isolation openings 310a (for forming the light emitting device G and B in the final product) are removed, and in this process, the first encapsulation structure 400 is used to protect the light emitting devices R in other isolation openings 310a. Based on this method, the light emitting devices G and B are prepared sequentially, thereby finally forming the first encapsulation structure 400 as shown in FIG. 54. That is, the first encapsulation structure 400 on the entire display panel is obtained in multiple processes, that is, the first encapsulation structure 400 formed in the process of preparing the light emitting devices R will be damaged by corrosion in the processes of preparing the light emitting devices G and B.

It should be noted that in the embodiments of the present application, the preparation order of the three types of light emitting devices R, G, and B is not specifically limited, and can be designed according to the needs of the actual process. For example, the preparation process may be implemented based on the sequence of the light emitting devices B, the light emitting devices G, and the light emitting devices R.

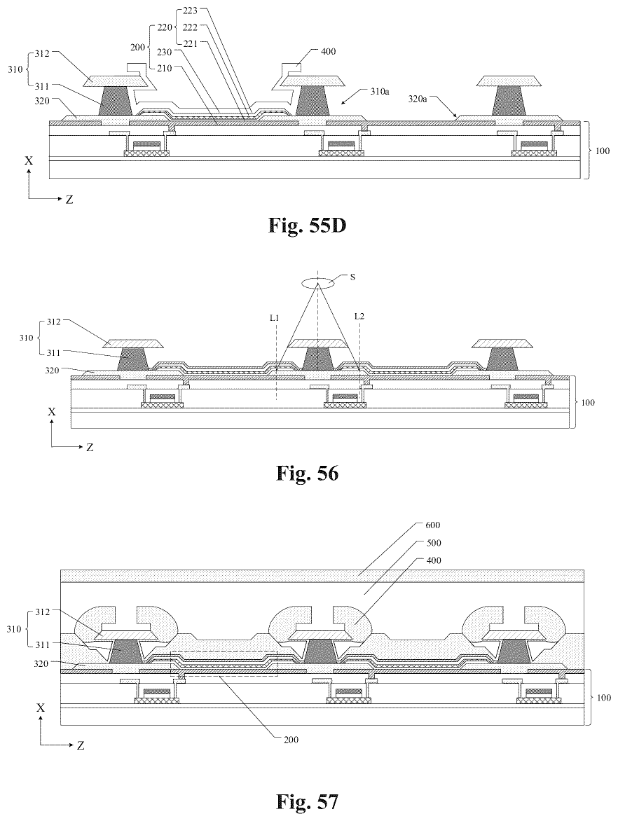

The preparation process of the display panel may refer to the following description in the embodiments shown in FIG. 55A to FIG. 55D.

As shown in FIG. 55A, a substrate 100 is provided, and second electrodes 210 arranged in an array are formed on the substrate 100; an insulating material film layer (such as an inorganic material film layer) is deposited on the substrate 100 formed with the second electrodes 210; a first isolation portion 311 and a second isolation layer 312 are formed on a display panel; a patterning process is performed on the insulating material film layer to form a pixel definition layer 320 (a plane shape thereof is a mesh), the pixel definition layer 320 covers a gap between the adjacent second electrodes 210, so that the plane shape of the pixel definition layer 320 is a mesh.

In the embodiments of the present application, the patterning process can be a photo-etching patterning process, for example including: coating a photoresist on a structure layer that needs to be patterned; exposing the photoresist with a mask plate; developing the exposed photoresist to obtain a photoresist pattern; etching the structure layer by using the photoresist pattern (either wet etching or dry etching); and then optionally removing the photoresist pattern. It should be noted that in the case where the material of the structure layer (such as the photoresist pattern G below) includes the photoresist, the structure layer can be directly exposed by using the mask plate, so as to form the desired pattern.

As shown in FIG. 55B, the light emitting unit 220 and the first electrode 230 are evaporated on the substrate 100 to form the light emitting device 200 in each isolation opening 310a of the isolation structure 310, and the evaporation in this process does not use the mask plate, so that the evaporated material is also deposited on the second isolation portion 312; and then the first encapsulation structure 400 is deposited to cover the light emitting device 200. For example, the light emitting layer in the evaporated light emitting unit 220 may emit the red light, that is, in this stage, the light emitting device 200 capable of emitting the red light is formed in each isolation opening 310a of the isolation structure 310.

As shown in FIG. 55C, the photoresist is formed (such as coated) on the substrate 100 formed with the first encapsulation structure 400, the patterning process is then performed on the photoresist to form the photoresist pattern G, and the photoresist pattern G covers only a part of the isolation openings 310a of the isolation structure 310.

As shown in FIG. 55D, the surface of the display panel is etched by using the photoresist pattern G as a mask, so as to remove the first encapsulation structure 400, the first electrode 230 and the light emitting unit 220 that are not covered by the photoresist pattern G; and the residual photoresist pattern G is then removed.

In this process, the corrosive fluids (or etching gases) are used when removing the residual photoresist pattern G, and the corrosive fluids may enter the space at the side wall of the first isolation portion 311, which may cause damage to the first encapsulation structure 400.

The above steps from FIG. 55A to FIG. 55D are repeated to form the light emitting devices 200 for emitting the green light and the light emitting devices 200 for emitting the blue light in the other isolation openings 310a, respectively, and to form the display panel shown in FIG. 5.

In the process of forming the light emitting devices 200 for emitting the green light and the light emitting devices 200 for emitting the blue light, the two steps of photo-etching to form the photoresist pattern G and removing the residual photoresist pattern G may be performed twice again, the twice used corrosive fluids (or etching gases) will again enter the space at the side wall of the first isolation portion 311 (the space in the isolation opening 310a corresponding to the light emitting device 200 for emitting the green light), which may cause repeated damages to the first encapsulation structure 400.

In the embodiments of the present application, as shown in FIG. 52 and FIG. 53, during the step shown in FIG. 55B, the space has been sealed by the first encapsulation structure 400, so that the corrosive fluids (or etching gases) can be prevented from entering the gap space 400a.

It should be noted that in the edge region of the light emitting device, the thickness of the film layer included in the light emitting device is small. Therefore, when calculating the second spacing in the actual process, the thickness of the light emitting device can be directly ignored, thus directly using the thickness of the support portion as the second spacing, the specific analysis may be as follows.

As shown in FIG. 56, when evaporating the light emitting unit (such as the first function layer therein), under a condition that the evaporation source S moves to the opposite side of the isolation structure 310, the corresponding position of the boundary of the evaporation angle of the evaporation source S on the display panel may be line L1 and line L2, that is, the region between the line L1 and line L2 is not evaporated in this case, and the regions on the side of the line L1 away from the isolation structure 310 and on the side of the line L2 away from the isolation structure 310 may be evaporated regardless of where the evaporation source S moves. That is, starting from the line L1 or line L2 region, and the closer to the isolation structure 310, the smaller the thickness of the light emitting unit.

In at least one embodiment of the present application, as shown in FIG. 57, the substrate 100 may include a baseplate and a drive circuit layer located on the baseplate, the drive circuit layer includes a plurality of pixel drive circuits located in the display region, and the display function layer is located on the drive circuit layer. For example, the pixel drive circuit may include a plurality of transistors TFT, a capacitor and the like, for example, it may be formed as a plurality of forms, such as 2T1C (that is, two transistors (TFT) and one capacitor (C)), 3T1C, or 7T1C. The pixel drive circuit is connected to the light emitting device 200 to control the switching state and the light emitting luminance of the light emitting device 200.

In at least one embodiment of the present application, as shown in FIG. 57, the display panel may also include a second encapsulation layer 500 and a third encapsulation layer 600 covering the first encapsulation structure 400, the second encapsulation layer 500 is located between the first encapsulation structure 400 and the first encapsulation layer 600, the first encapsulation structure 400 and the third encapsulation layer 600 are inorganic layers with high density to isolate water and oxygen, and the second encapsulation layer 500 is an organic layer, thus having a large thickness to flatten the surface of the display panel.

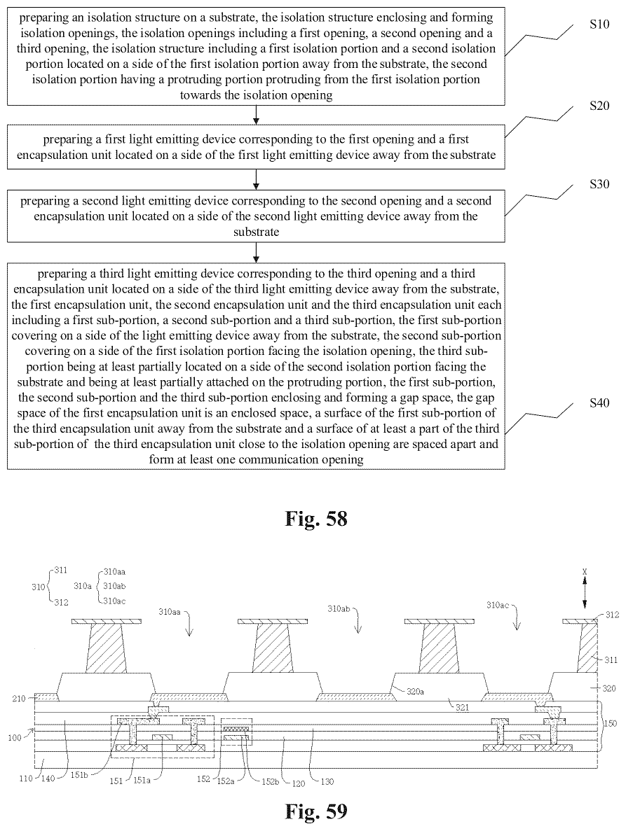

FIG. 58 is a flowchart diagram of a preparation method for a display panel provided by an embodiment of the present application, and FIG. 59 to FIG. 62 are preparation process schematic diagrams of a preparation method for a display panel provided by another embodiment of the present application.

The embodiments of a second aspect of the present application further provide a preparation method for a display panel 10, and the display panel 10 may be the display panel 10 provided in any of the aforementioned embodiments of the first aspect. Please combine FIG. 58 and refer to FIG. 59 to FIG. 62, the preparation method includes:

Step S01: as shown in FIG. 59, preparing an isolation structure 310 on a substrate 100, the isolation structure 310 enclosing and forming isolation openings 310a, the isolation openings 310a including a first opening 310aa, a second opening 310ab, and a third opening 310ac, the isolation structure 310 including a first isolation portion 311 and a second isolation portion 312 located on a side of the first isolation portion 311 away from the substrate 100, the second isolation portion 312 having a protruding portion 312a protruding from the first isolation portion 311 towards the isolation opening 310a;

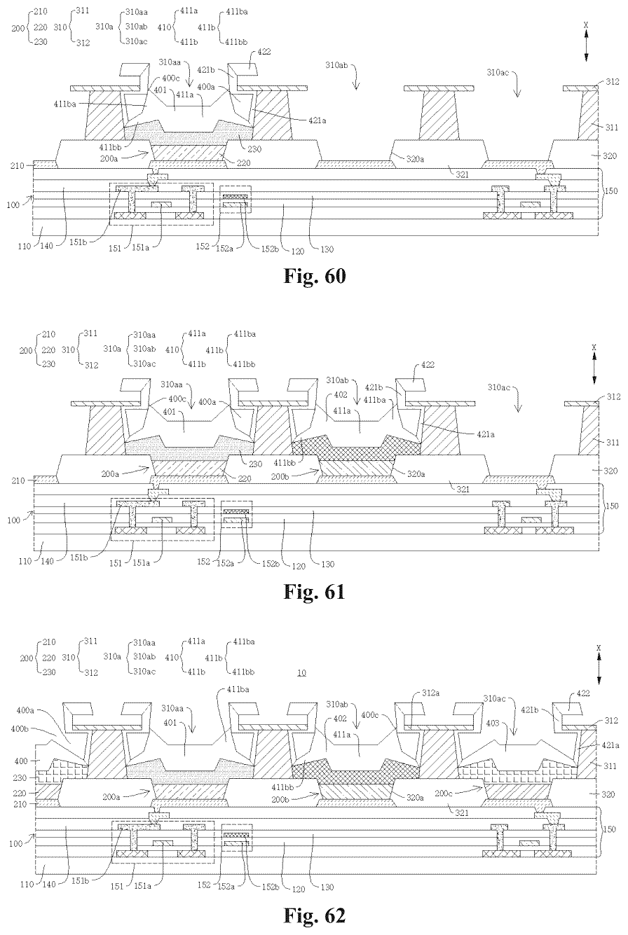

Step S02: as shown in FIG. 60, preparing a first light emitting device 200a corresponding to the first opening 310aa and a first encapsulation unit 401 located on a side of the first light emitting device 200a away from the substrate 100;

Step S03: as shown in FIG. 61, preparing a second light emitting device 200b corresponding to the second opening 310ab and a second encapsulation unit 402 located on a side of the second light emitting device 200b away from the substrate 100;

Step S04: as shown in FIG. 62, preparing a third light emitting device 200c corresponding to the third opening 310ac and a third encapsulation unit 403 located on a side of the third light emitting device 200c away from the substrate 100, the first encapsulation unit 401, the second encapsulation unit 402, and the third encapsulation unit 403 each including a first sub-portion 410, a second sub-portion 421a, and a third sub-portion 421b, the first sub-portion 410 covering on the side of the light emitting device 200 away from the substrate 100, the second sub-portion 421a covering on the side of the first isolation portion 311 facing the isolation opening 310a, the third sub-portion 421b being at least partially located on the side of the second isolation portion 312 facing the substrate 100 and being at least partially attached to the protruding portion 312a, the first sub-portion 410, the second sub-portion 421a and the third sub-portion 421b enclosing and forming a gap space 400a, the gap space 400a formed by the first encapsulation unit 401 being an enclosed space, and a surface of the first sub-portion 410 of the third encapsulation unit 403 away from the substrate 100 and a surface of at least a part of the third sub-portion 421b of the third encapsulation unit 403 close to the isolation opening 310a being at least partially spaced apart and forming at least one communication opening 400b.

Optionally, the gap space 400a formed by the first encapsulation unit 401 being the enclosed space may specifically mean that, the first sub-portion 410, the second sub-portion 421a and the third sub-portion 421b in at least a part of the isolation openings 310a may enclose and form an enclosed gap space 400a.

Optionally, the third sub-portion 421b in the first opening 310aa is connected with the first sub-portion 410 to form the connection portion 400c, and the orthographic projection of the connection portion 400c in the first opening 310aa on the substrate 100 is in a ring shape. For example, the surface of the first sub-portion 410 of the first encapsulation unit 401 away from the substrate 100 and the surface of the third sub-portion 421b away from the first isolation portion 311 and covering the second isolation portion 312 may connect with each other, and form a ring shaped connection portion 400c.

In the preparation method for the display panel 10 provided in the embodiments of the present application, by setting the gap space 400a in the first opening 310aa as an enclosed space, the first sub-portion 410 in the first encapsulation unit 401 may play a better supporting role for the third sub-portion 421b, so that the first encapsulation unit 401 may have better structural stability. Thus, the first encapsulation unit 401 is not easily damaged by subsequent processes. For example, the first encapsulation unit 401 is not easily damaged when preparing the second light emitting device 200b, the second encapsulation unit 402, the third light emitting device 200c and the third encapsulation unit 403, thereby better improving the encapsulation stability of the first encapsulation unit 401.

Further, when the subsequent film layer is prepared on the first encapsulation unit 401, the material of the subsequent film layer can be better continuous at the connection portion 400c, which can facilitate the formation of the subsequent film layer or facilitate the patterning of the subsequent film layer. Therefore, the subsequent film layer can better cover the first encapsulation unit 401, and the subsequent film layer can provide certain protection to the first encapsulation unit 401.

For example, in the subsequent preparation process of the light emitting unit 220 and the second electrode 210 of the second light emitting device 200b as well as the second encapsulation unit 402, after preparing the material of the light emitting unit 220 and the second electrode 210 of the second light emitting device 200b on the whole surface, the material of the light emitting unit 220 and the second electrode 210 of the second light emitting device 200b may be relatively continuous on the first encapsulation unit 401. Therefore, when patterning the second encapsulation unit 402 on the light emitting unit 220 and the second electrode 210 of the second light emitting device 200b, that is, when removing the material of the second encapsulation unit 402 outside of the second opening 310ab, the material of the light emitting unit 220 and the second electrode 210 of the second light emitting device 200b may be used to protect the first encapsulation unit 401 in the first opening 310aa, so that the etching material is not easy to damage the first encapsulation unit 401, thereby better improving the structural stability of the first encapsulation unit 401. Moreover, when preparing the second light emitting device 200b or the second encapsulation unit 402, the etching material is not easily accessible into the gap space 400a of the first encapsulation unit 401, thereby better reducing the etching damage of the inner wall of the gap space 400a in the first encapsulation unit 401 by the etching material, and better improving the structural stability of the first encapsulation structure 400.

For example, in the subsequent preparation process of the light emitting unit 220 and the second electrode 210 of the third light emitting device 200c as well as the third encapsulation unit 403, after preparing the material of the light emitting unit 220 and the second electrode 210 of the third light emitting device 200c on the whole surface, the material of the light emitting unit 220 and the second electrode 210 of the third light emitting device 200c may be relatively continuous on the first encapsulation unit 401. Therefore, when patterning the third encapsulation unit 403 on the light emitting unit 220 and the second electrode 210 of the third light emitting device 200c, that is, when removing the material of the third encapsulation unit 403 outside of the third opening 310ac, the material of the light emitting unit 220 and the second electrode 210 of the third light emitting device 200c may be used to protect the first encapsulation unit 401 in the first opening 310aa, so that the etching material is not easy to damage the first encapsulation unit 401, thereby better improving the structural stability of the first encapsulation unit 401. Moreover, when preparing the third light emitting device 200c or the third encapsulation unit 403, the etching material is not easily accessible into the gap space 400a of the first encapsulation unit 401, thereby better reducing the etching damage of the inner wall of the gap space 400a in the first encapsulation unit 401 by the etching material, and better improving the structural stability of the first encapsulation structure 400.

Optionally, the gap space 400a formed by the second encapsulation unit 402 is an enclosed space, that is, the gap space 400a of the second encapsulation unit 402 corresponding to the second opening 310ab may be an enclosed space. For example, the first sub-portion 410 of the second encapsulation unit 402, the second sub-portion 421a of the second encapsulation unit 402 and the third sub-portion 421b of the second encapsulation unit 402 may enclose and form an enclosed gap space 400a.

Optionally, the third sub-portion 421b in the second opening 310ab is connected with the first sub-portion 410 to form the connection portion 400c, and the orthographic projection of the connection portion 400c in the second opening 310ab on the substrate 100 is in a ring shape. For example, the surface of the first sub-portion 410 of the second encapsulation unit 402 away from the substrate 100 and the surface of the third sub-portion 421b away from the first isolation portion 311 and covering the second isolation portion 312 may connect with each other, and form a ring shaped connection portion 400c.

In these optional embodiments, by setting that the first sub-portion 410 of the second encapsulation unit 402, the second sub-portion 421a of the second encapsulation unit 402 and the third sub-portion 421b of the second encapsulation unit 402 enclose and form an enclosed gap space 400a, the first sub-portion 410 in the second encapsulation unit 402 may play a better supporting role for the third sub-portion 421b, so that the second encapsulation unit 402 may have better structural stability. Thus, the second encapsulation unit 402 is not easily damaged by subsequent processes. For example, the second encapsulation unit 402 is not easily damaged when preparing the third light emitting device 200c and the third encapsulation unit 403, thereby better improving the encapsulation stability of the second encapsulation unit 402.

Further, when the subsequent film layer is prepared on the second encapsulation unit 402, the material of the subsequent film layer can be better continuous at the connection portion 400c, which can facilitate the formation of the subsequent film layer or facilitate the patterning of the subsequent film layer. Therefore, the subsequent film layer can better cover the second encapsulation unit 402, and the subsequent film layer can provide certain protection to the second encapsulation unit 402.

For example, in the subsequent preparation process of the light emitting unit 220 and the second electrode 210 of the third light emitting device 200c as well as the third encapsulation unit 403, after preparing the material of the light emitting unit 220 and the second electrode 210 of the third light emitting device 200c on the whole surface, the material of the light emitting unit 220 and the second electrode 210 of the third light emitting device 200c may be relatively continuous on the second encapsulation unit 402. Therefore, when patterning the third encapsulation unit 403 on the light emitting unit 220 and the second electrode 210 of the third light emitting device 200c, that is, when removing the material of the third encapsulation unit 403 outside of the third opening 310ac, the material of the light emitting unit 220 and the second electrode 210 of the third light emitting device 200c may be used to protect the second encapsulation unit 402 in the second opening 310ab, so that the etching material is not easy to damage the second encapsulation unit 402, thereby better improving the structural stability of the second encapsulation unit 402. Moreover, when preparing the third light emitting device 200c or the third encapsulation unit 403, the etching material is not easily accessible into the gap space 400a of the second encapsulation unit 402, thereby better reducing the etching damage of the inner wall of the gap space 400a in the second encapsulation unit 402 by the etching material, and better improving the structural stability of the second encapsulation unit.

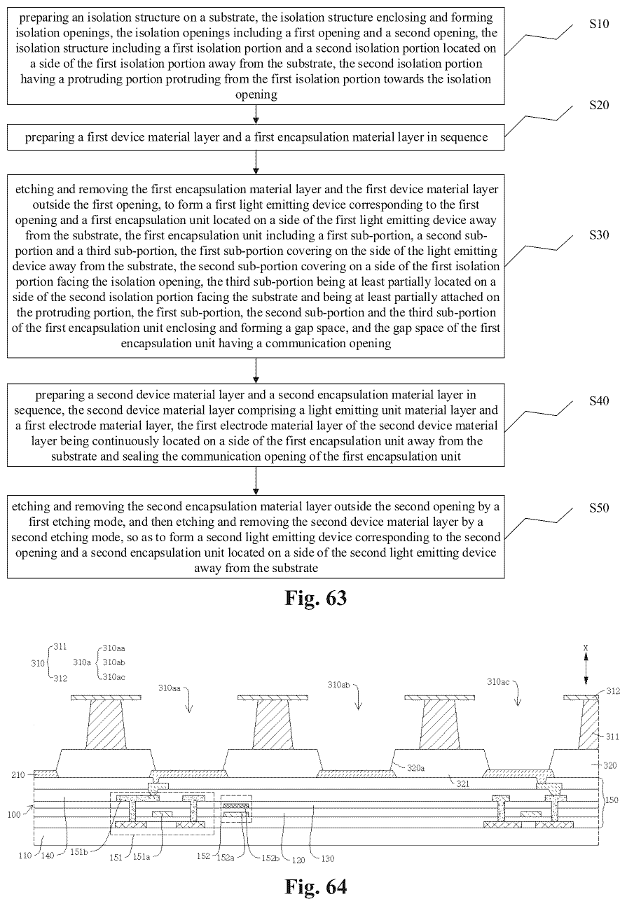

FIG. 63 is a flowchart diagram of a preparation method for a display panel provided by another embodiment of the present application, and FIG. 64 to FIG. 70 are preparation process schematic diagrams of a preparation method for a display panel provided by another embodiment of the present application.

The embodiments of the second aspect of the present application further provide a preparation method for a display panel 10, and the display panel 10 may be the display panel 10 provided in any of the aforementioned embodiments of the first aspect. Please combine FIG. 63 and refer to FIG. 64 to FIG. 70, the preparation method includes Step S01-S05.

Step S01: as shown in FIG. 64, preparing an isolation structure 310 on A substrate 100, the isolation structure 310 enclosing and forming isolation openings 310a, the isolation openings 310a including a first opening 310aa and a second opening 310ab, the isolation structure 310 includes a first isolation portion 311 and a second isolation portion 312 located on a side of the first isolation portion 311 away from the substrate 100, and the second isolation portion 312 having a protruding portion 312a protruding from the first isolation portion 311 toward the isolation opening 310a.

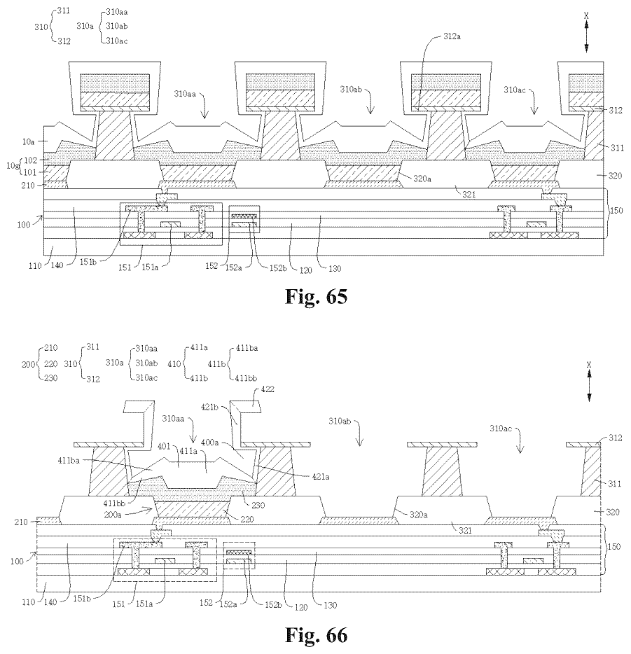

Step S02: as shown in FIG. 65, preparing a first device material layer 10g and a first encapsulation material layer 10a in sequence.

Optionally, the first device material layer 10g may be used to form the light emitting unit 220 and the first electrode 230 of the first light emitting device 200a, thus, the first device material layer 10g may include a light emitting unit material layer 101 and a first electrode material layer 102. Here, the light emitting unit material layer 101 of the first device material layer 10g may be used to form the light emitting unit 220 of the first light emitting device 200a, and the first electrode material layer 102 of the first device material layer 10g may be used to form the first electrode 230 of the first light emitting device 200a.

Step S03: as shown in FIG. 66, etching and removing the first encapsulation material layer 10a and the first device material layer 10g outside the first opening 310aa, so as to form a first light emitting device 200a corresponding to the first opening 310aa and a first encapsulation unit 401 located on a side of the first light emitting device 200a away from the substrate 100, the first encapsulation unit 401 including a first sub-portion 410, a second sub-portion 421a, and a third sub-portion 421b, the first sub-portion 410 covering on the side of the light emitting device 200 away from the substrate 100, the second sub-portion 421a covering on a side of the first isolation portion 311 facing the isolation opening 310a, the third sub-portion 421b being at least partially located on a side of the second isolation portion 312 facing the substrate 100 and being at least partially attached to the protruding portion 312a, the first sub-portion 410, the second sub-portion 421a, and the third sub-portion 421b of the first encapsulation unit 401 enclosing and forming a gap space 400a, and the gap space 400a of the first encapsulation unit 401 having a communication opening 400b.

Optionally, the surface of the first sub-portion 410 of the first encapsulation unit 401 away from the substrate 100 and the surface of at least a part of the third sub-portion 421b of the first encapsulation unit 401 close to the isolation opening 310a are spaced apart, so as to form at least one communication opening 400b.

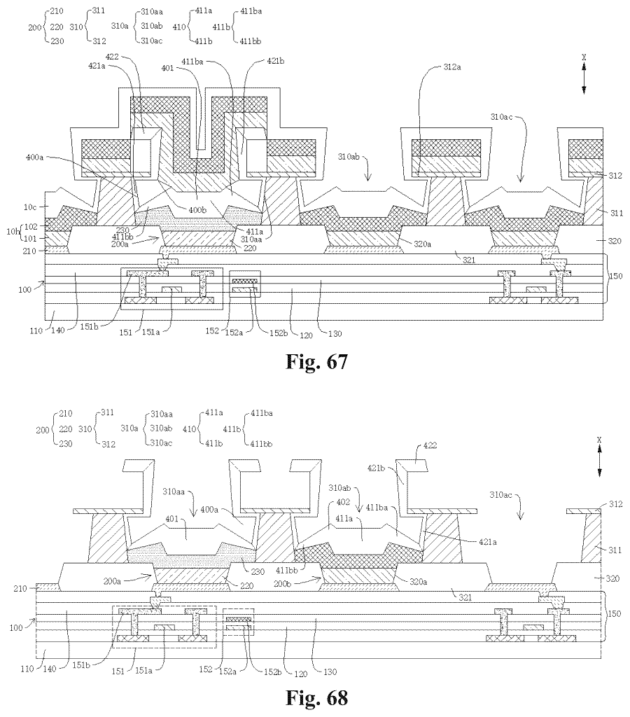

Step S04: as shown in FIG. 67, preparing a second device material layer 10h and a second encapsulation material layer 10c in sequence, the second device material layer 10h including a light emitting unit material layer 101 and a first electrode material layer 102, the first electrode material layer 102 of the second device material layer 10h being continuously located on a side of the first encapsulation unit 401 away from the substrate 100 and sealing the communication opening 400b of the first encapsulation unit 401.

Optionally, the second device material layer 10h may be used to form the light emitting unit 220 and the first electrode 230 of the second light emitting device 200b, the light emitting unit material layer 101 of the second device material layer 10h may be used to form the light emitting unit 220 of the second light emitting device 200b, and the first electrode material layer 102 of the second device material layer 10h may be used to form the first electrode 230 of the second light emitting device 200b.

Optionally, the first electrode material layer 102 of the second device material layer 10h being continuously located on a side of the first encapsulation unit 401 away from the substrate 100 and sealing the communication opening 400b of the first encapsulation unit 401 may mean that, the orthographic projection of the first encapsulation unit 100 on the substrate 100 is located within the orthographic projection of the first electrode material layer 102 of the second device material layer 10h on the substrate 100.

Optionally, the size of the communication opening 400b of the first encapsulation unit 401 in the thickness direction of the display panel 10 may be adjusted by the method described in any of the aforementioned embodiments, so as to facilitate that the first electrode material layer 102 of the second device material layer 10h is continuously located on a side of the first encapsulation unit 401 away from the substrate 100 and seals the communication opening 400b of the first encapsulation unit 401.

For example, the minim size of the communication opening 400b of the first encapsulation unit 401 in the thickness direction of the display panel 10 is less than or equal to the product of the sum of the thicknesses of the light emitting unit 220 and the first electrode 230 of the second light emitting device 200b and the corresponding sealing coefficient. That is, the minim size of the communication opening 400b in the first opening 310aa in the thickness direction of the display panel 10 is less than or equal to the product of the sum of the thicknesses of the light emitting unit 220 and the first electrode 230 of the second light emitting device 200b and the corresponding sealing coefficient.

Step S05: as shown in FIG. 68, etching and removing the second encapsulation material layer 10c outside the second opening 310ab by a first etching mode, and then etching and removing the second device material layer 10h by a second etching mode, so as to form a second light emitting device 200b corresponding to the second opening 310 ab and a second encapsulation unit 200b located on a side of the second light emitting device 200b away from the substrate 100.

Optionally, the etching material used in the first etching mode is different from the etching material used in the second etching mode.

In the preparation method of the display panel 10 provided in the embodiments of the present application, in the step of preparing the second device material layer 10h and the second encapsulation material layer 10c in sequence, by setting that the first electrode material layer 102 of the second device material layer 10h is continuously located on a side of the first encapsulation unit 401 away from the substrate 100 and seals the communication opening 400b of the first encapsulation unit 401, when etching and removing the second encapsulation material layer 10c outside the second opening 310ab by the first etching mode, the second device material layer 10h can better cover and protect the first encapsulation unit 401 below, so that the etching material used in the first etching mode is not easy to destroy the first encapsulation unit 401 below, and the etching material used in the first etching mode is not easy to enter into the gap space 400a of the first encapsulation unit 401 through the communication opening 400b, thereby better improving the structural stability of the display panel 10.

Moreover, under a condition that the material of the first encapsulation unit 401 is the same as the material of the second encapsulation unit 402 and the material of the second device material layer 10h is different from the material of the second encapsulation material layer 10c, by setting that the etching material used in the first etching mode is different from the etching material used in the second etching mode, in the process of etching and removing the second device material layer 10h by the second etching mode, the etching material used in the second etching mode is not easy to cause large etching damage to the first encapsulation unit 401, thereby better improving the encapsulation performance of the first encapsulation unit 401.

For example, by setting that the first electrode material layer 102 in the second device material layer 10h is continuous and seals the communication opening 400b of the first encapsulation unit 401, and because that the material of the first electrode material layer 102 is different from the material of the second encapsulation material layer 10c, when patterning by using the first etching mode, the etching material is not easy to cause damage to the first electrode material layer 102. Therefore, the first electrode material layer 102 may better limit the entry of the etching material into the gap space 400a of the first encapsulation unit 401, thereby better reducing the damage of the etching material to the first encapsulation unit 401.

In some optional embodiments, the first encapsulation unit 401 and the second encapsulation unit 402 each include the first sub-portion 410, the second sub-portion 421a and the third sub-portion 421b, the first sub-portion 410, the second sub-portion 421a and the third sub-portion 421b of the second encapsulation unit 402 enclose and form a gap space 400a, and the gap space 400a of the second encapsulation unit 402 has a communication opening 400b, the isolation openings 310a further includes a third opening 310ac. After step S05, the preparation method also includes step S06-S07.

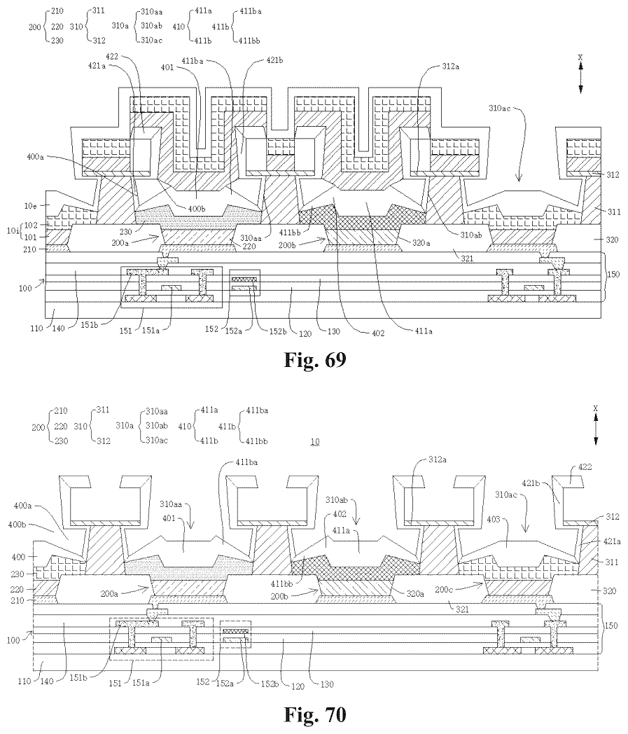

Step S06: as shown in FIG. 69, preparing a third device material layer 10i and a third encapsulation material layer 10e in sequence, the third device material layer 10i including a light emitting unit material layer 101 and a first electrode material layer 102, the first electrode material layer 102 of the third device material layer 10i being continuously located on the side of the first encapsulation unit 401 away from the substrate 100 and sealing the communication opening 400b of the first encapsulation unit 401, and/or, the third device material layer 10i being continuously located on a side of the second encapsulation unit 402 away from the substrate 100 and sealing the communication opening 400b of the second encapsulation unit 402.

Optionally, the third device material layer 10i may be used to form the light emitting unit 220 and the first electrode 230 of the third light emitting device 200c, here, the light emitting unit material layer 101 of the third device material layer 10i may be used to form the light emitting unit 220 of the third light emitting device 200c, and the first electrode material layer 102 of the third device material layer 10i may be used to form the first electrode 230 of the third light emitting device 200c.

Optionally, the first electrode material layer 102 of the third device material layer 10i being continuously located on the side of the first encapsulation unit 401 away from the substrate 100 and sealing the communication opening 400b of the first encapsulation unit 401 may mean that, the orthographic projection of the first encapsulation unit 401 on the substrate 100 is located within the orthographic projection of the first electrode material layer 102 of the third device material layer 10i on the substrate 100.

Optionally, the size of the communication opening 400b of the first encapsulation unit 401 in the thickness direction of the display panel 10 may be adjusted by the method described in any of the aforementioned embodiments, so that the first electrode material layer 102 of the third device material layer 10i is continuously located on the side of the first encapsulation unit 401 away from the substrate 100 and seals the communication opening 400b of the first encapsulation unit 401.

For example, the minim size of the communication opening 400b of the first encapsulation unit 401 in the thickness direction of the display panel 10 is less than or equal to the product of the sum of the thicknesses of the light emitting unit 220 and the first electrode 230 of the third light emitting device 200c and the corresponding sealing coefficient. That is, the minim size of the communication opening 400b in the first opening 310aa in the thickness direction of the display panel 10 is less than or equal to the product of the sum of the thicknesses of the light emitting unit 220 and the first electrode 230 of the third light emitting device 200c and the corresponding sealing coefficient.

Optionally, the first electrode material layer 102 of the third device material layer 10i being continuously located on the side of the second encapsulation unit 402 away from the substrate 100 and sealing the communication opening 400b of the second encapsulation unit 402 may mean that, the orthographic projection of the second encapsulation unit 402 on the substrate 100 is located within the orthographic projection of the first electrode material layer 102 of the third device material layer 10i on the substrate 100.

Optionally, the size of the communication opening 400b of the second encapsulation unit 402 in the thickness direction of the display panel 10 may be adjusted by the method described in any of the aforementioned embodiments, so that the first electrode material layer 102 of the third device material layer 10i is continuously located on the side of the second encapsulation unit 402 away from the substrate 100 and seals the communication opening 400b of the second encapsulation unit 402.

For example, the minim size of the communication opening 400b of the second encapsulation unit 402 in the thickness direction of the display panel 10 is less than or equal to the product of the sum of the thicknesses of the light emitting unit 220 and the first electrode 230 of the third light emitting device 200c and the corresponding sealing coefficient. That is, the minim size of the communication opening 400b in the second opening 310ab in the thickness direction of the display panel 10 is less than or equal to the product of the sum of the thicknesses of the light emitting unit 220 and the first electrode 230 of the third light emitting device 200c and the corresponding sealing coefficient.

Step S07: as shown in FIG. 70, etching and removing the third encapsulation material layer 10e outside the third opening 310ac by the first etching mode, and then etching and removing the third device material layer 10i by the second etching mode, so as to form a third light emitting device 200c corresponding to the third opening 310ac and a third encapsulation unit 403 located on a side of the third light emitting device 200c away from the substrate 100.

In these optional embodiments, in the step of preparing the third device material layer 10i and the third encapsulation material layer 10e in sequence, by setting that the first electrode material layer 102 of the third device material layer 10i is continuously located on the sides of the first encapsulation unit 401 and the second encapsulation unit 402 away from the substrate 100 and seals the communication openings 400b of the first encapsulation unit 401 and the second encapsulation unit 402, when etching and removing the third encapsulation material layer 10e outside the third opening 310ac by the first etching mode, the third device material layer 10i can better cover and protect the first encapsulation unit 401 and the second encapsulation unit 402 below, so that the etching material used in the first etching mode is not easy to destroy the first encapsulation unit 401 and the second encapsulation unit 402 below, and the etching material used in the first etching mode is not easy to enter into the gap spaces 400a of the first encapsulation unit 401 and the second encapsulation unit 402 through the communication openings 400b, thereby better improving the structural stability of the display panel 10.

Moreover, under a condition that the materials of the first encapsulation unit 401, the second encapsulation unit 402 and the third encapsulation unit 403 are the same and the material of the third device material layer 10i is different from the material of the third encapsulation material layer 10e, by setting that the etching material used in the first etching mode is different from the etching material used in the second etching mode, in the process of etching and removing the third device material layer 10i by the second etching mode, the etching material used in the second etching mode is not easy to cause large etching damage to the first encapsulation unit 401 and the second encapsulation unit 402, thereby better improving the encapsulation performance of the first encapsulation unit 401.

For example, by setting that the first electrode material layer 102 in the third device material layer 10i is continuous and seals the communication opening 400b of the first encapsulation unit 401, and because that the material of the first electrode material layer 102 is different from the material of the third encapsulation material layer 10e, when patterning by using the first etching mode, the etching material is not easy to cause damage to the first electrode material layer 102. Therefore, the first electrode material layer 102 may better limit the entry of the etching material into the gap spaces 400a of the first encapsulation unit 401 and the second encapsulation unit 402, thereby better reducing the damage of the etching material to the first encapsulation unit 401 and the second encapsulation unit 402.

The embodiments of a third aspect of the present application provide a display device including the display panel 10 of any of the above embodiments or the display panel 10 prepared by the preparation method of any of the above embodiments. Since the display device provided by the embodiments of the third aspect of the present application includes the display panel 10 of any of the above embodiments of the first aspect and the display panel 10 prepared by the preparation method of any of the above embodiments of the second aspect, the display device provided by the embodiments of the third aspect of the present application may have the beneficial effects of the display panel 10 of any of the above embodiments of the first aspect and the display panel 10 prepared by the preparation method of any of the above embodiments of the second aspect, which will not be repeated here.

The display device in the embodiments of the present application includes, but is not limited to, a mobile phone, a personal digital assistant (PDA), a tablet computer, an e-book, a TV set, an access control, a smart fixed telephone, a console, and other devices with display function.

With respect to the composition and materials of the isolation structure (also called the partition structure), patent or patent application No. PCT/CN2023/134518, 202310771071.0, 202311117143.6, 202310759370.2, 202311499823.9, 202311764506.5, 202310707209.0, 202311346196.5, 202310692671.8, 202310909421.5 recite the relevant technical schemes, which can be made for reference.

Those skilled in the art should understand that the above embodiments are exemplary rather than restrictive. The different technical features appearing in the different embodiments can be combined to achieve beneficial effects. Those skilled in the art should understand and realize embodiments of other variations of the disclosed embodiments on the basis of studying the appended drawings, specification, and claims. In the claims, the term “comprise” does not exclude other devices or steps; the article without a quantifier is intended to include one or more articles and may be used interchangeably with “one or more articles”; and the terms “first”, “second” are used to indicate names rather than to indicate any particular order. Any reference number in the claims shall not be understood as a limitation on the protection scope. The functions of the multiple parts appearing in the claims can be implemented by a single hardware or software module. The fact that certain technical features appear in different dependent claims does not mean that these technical features cannot be combined to achieve a beneficial effect.

What is claimed is:

1. A display panel, comprising:
a substrate;
an isolation structure disposed on a side of the substrate and enclosing and forming a plurality of isolation openings, the isolation structure comprising a first isolation portion and a second isolation portion located on a side of the first isolation portion away from the substrate, the second isolation portion having a protruding portion protruding from the first isolation portion towards the isolation opening;
a plurality of light emitting devices, at least a part of a structure of the light emitting device is located within the isolation opening;
a first encapsulation structure disposed on a side of the light emitting device away from the substrate, the first encapsulation structure comprising a first sub-portion, a second sub-portion and a third sub-portion, the first sub-portion covering on the side of the light emitting device away from the substrate, the second sub-portion covering on a side of the first isolation portion facing the isolation opening, the third sub-portion being at least partially located on a side of the second isolation portion facing the substrate and being at least partially attached on the protruding portion, the first sub-portion, the second sub-portion and the third sub-portion enclosing and forming a gap space, and the third sub-portion being at least partially connected with the first sub-portion to form a connection portion.

2. The display panel of claim 1, wherein an orthographic projection of the connection portion in at least a part of the isolation openings on the substrate is in a ring shape, and the gap space is an enclosed space;
or, the first sub-portion and the third sub-portion in at least a part of the isolation openings are at least partially spaced apart and form a communication opening.

3. The display panel of claim 2, wherein a surface of the first sub-portion away from the substrate and a surface of the third sub-portion close to the isolation opening in at least a part of the isolation openings are at least partially spaced apart and form at least one communication opening,
an orthographic projection of the communication opening in at least a part of the isolation openings on the substrate is in a ring shape;
or, a plurality of communication openings are provided in at least a part of the isolation openings, and the plurality of communication openings are spaced apart.

4. The display panel of claim 3, wherein at least a part of the communication openings is provided with a sealing structure, one side of the sealing structure is connected to the surface of the first sub-portion, and the other side of the sealing structure is connected to the surface of the third sub-portion.

5. The display panel of claim 1, wherein at least a part of the gap space is filled with a support structure; the display panel further comprises a second encapsulation layer disposed on a side of the first encapsulation structure away from the substrate, a surface of the first sub-portion away from the substrate and a surface of the third sub-portion close to the isolation opening in at least a part of the isolation openings are at least partially spaced apart and form a communication opening, and at least a part of the second encapsulation layer is located in the gap space to form the support structure.

6. The display panel of claim 1, wherein a protruding length of the protruding portion disposed corresponding to one part of the isolation openings is greater than a protruding length of the protruding portion disposed corresponding to the other part of the isolation openings.

7. The display panel of claim 1, wherein the display panel further comprises a pixel definition layer disposed on a side of the substrate facing the light emitting device, the pixel definition layer comprises a pixel limiting portion and a pixel opening enclosed and formed by the pixel limiting portion, the isolation structure is disposed on a side of the pixel limiting portion away from the substrate, the pixel opening is correspondingly communicated with the isolation opening,
the first sub-portion comprises a first body sub-portion and a second body sub-portion that are interconnected, the first body sub-portion is located in the pixel opening, and the second body sub-portion is located on the side of the pixel limiting portion away from the substrate,
a first spacing is provided between a surface of the protruding portion facing the substrate and a surface of the pixel limiting portion away from the substrate,
a ratio of a maximum thickness of at least a part of the first body sub-portion to the first spacing is not less than 1.25; or, a ratio of a maximum thickness of at least a part of the second body sub-portion to the first spacing is not less than 1.25;
a size of the first isolation portion in a thickness direction of the display panel is a first height, a ratio of the maximum thickness of at least a part of the first body sub-portion to the first height is not less than 1.4, or, a ratio of the maximum thickness of at least a part of the second body sub-portion to the first height is not less than 1.25.

8. The display panel of claim 1, wherein the isolation openings comprise a first opening and a third opening, the light emitting devices comprise a first light emitting device disposed corresponding to the first opening and a third light emitting device disposed corresponding to the third opening, the gap space in the first opening is an enclosed space;
or, the gap space in the third opening forms at least one communication opening, and the communication opening in the third opening is in a ring shape.

9. The display panel of claim 8, wherein the first encapsulation structure comprises a first encapsulation unit at least partially located in the first opening and a third encapsulation unit at least partially located in the third opening, and a maximum thickness of the first encapsulation unit is greater than a maximum thickness of the third encapsulation unit.

10. The display panel of claim 8, wherein a spacing between the substrate and at least a part of the second isolation portion involved in enclosing and forming the first opening is less than a spacing between the substrate and the second isolation portion involved in enclosing and forming the third opening;
or the protruding portion comprises a first protruding portion corresponding to the first opening and a third protruding portion corresponding to the third opening, and a protruding length of the first protruding portion is less than a protruding length of the third protruding portion.

11. The display panel of claim 8, wherein the isolation openings further comprise a second opening, the light emitting devices comprise a second light emitting device disposed corresponding to the second opening, the gap space in the second opening is an enclosed space;
or, the gap space in the second opening forms at least one communication opening.

12. A display panel, comprising:
a substrate;
an isolation structure disposed on a side of the substrate and enclosing and forming a plurality of isolation openings, the isolation structure comprising a first isolation portion and a second isolation portion located on a side of the first isolation portion away from the substrate, the second isolation portion having a protruding portion protruding from the first isolation portion towards the isolation opening;
a plurality of light emitting devices, at least a part of a structure of the light emitting device is located within the isolation opening, the light emitting device comprising a light emitting unit and a first electrode located on a side of the light emitting unit away from the substrate;
a first encapsulation structure disposed on a side of the light emitting device away from the substrate, the first encapsulation structure comprising a first sub-portion, a second sub-portion and a third sub-portion, the first sub-portion covering on the side of the light emitting device away from the substrate, the second sub-portion covering on a side of the first isolation portion facing the isolation opening, the third sub-portion being at least partially located on a side of the second isolation portion facing the substrate and being at least partially attached on the protruding portion, the first sub-portion, the second sub-portion and the third sub-portion enclosing and forming a gap space, and the first sub-portion and the third sub-portion in at least a part of the isolation openings being at least partially spaced apart and forming a communication opening,
wherein a minimum size of the communication opening in a thickness direction of the display panel is less than or equal to a product of a sum of thicknesses of the light emitting unit and the first electrode of at least a part of the light emitting devices and a sealing coefficient.

13. The display panel of claim 12, wherein the minimum size of the communication opening in the thickness direction of the display panel is less than or equal to an opening size of the light emitting unit and the first electrode of at least a part of the light emitting devices corresponding to the communication opening;
or the minimum size of the communication opening in the thickness direction of the display panel is less than or equal to the sum of the thicknesses of the light emitting unit and the first electrode of at least a part of the light emitting devices.

14. The display panel of claim 12, wherein the isolation openings comprise a first opening, a second opening and a third opening, and the light emitting devices comprise a first light emitting device disposed corresponding to the first opening, a second light emitting device disposed corresponding to the second opening and a third light emitting device disposed corresponding to the third opening,
a side of the third sub-portion in the first opening close to the isolation opening is at least partially connected with a surface of the first sub-portion away from the substrate to form a connection portion, and an orthographic projection of the connection portion in the first opening on the substrate is in a ring shape, and the gap space in the first opening is an enclosed space.

15. The display panel of claim 14, wherein the gap space in the first opening forms at least one communication opening, and a minimum size of the communication opening in the first opening in the thickness direction of the display panel is less than or equal to a product of a sum of thicknesses of the light emitting unit and the first electrode of the second light emitting device and a corresponding sealing coefficient;
or, the minimum size of the communication opening in the first opening in the thickness direction of the display panel is less than or equal to a product of a sum of thicknesses of the light emitting unit and the first electrode of the third light emitting device and a corresponding sealing coefficient.

16. The display panel of claim 15, wherein a size of the communication opening in the first opening in the thickness direction of the display panel is less than or equal to a thickness of the light emitting unit of the second light emitting device;
or, the size of the communication opening in the first opening in the thickness direction of the display panel is less than or equal to a thickness of the light emitting unit of the third light emitting device.

17. The display panel of claim 14, wherein a side of the third sub-portion in the second opening close to the isolation opening is at least partially connected with a surface of the first sub-portion away from the substrate to form a connection portion, and an orthographic projection of the connection portion in the second opening on the substrate is in a ring shape, and the gap space in the second opening is an enclosed gap space.

18. The display panel of claim 17, wherein the gap space in the second opening forms at least one communication opening, and a minimum size of the communication opening in the second opening in the thickness direction of the display panel is less than or equal to a product of a sum of thicknesses of the light emitting unit and the first electrode of the third light emitting device and a corresponding sealing coefficient;
a size of the communication opening in the second opening in the thickness direction of the display panel is less than or equal to a thickness of the light emitting unit of the third light emitting device.

19. A preparation method for a display panel, comprising:
preparing an isolation structure on a substrate, the isolation structure enclosing and forming isolation openings, the isolation openings comprising a first opening and a second opening, the isolation structure comprising a first isolation portion and a second isolation portion located on a side of the first isolation portion away from the substrate, the second isolation portion having a protruding portion protruding from the first isolation portion towards the isolation opening;
preparing a first device material layer and a first encapsulation material layer in sequence;
etching and removing the first encapsulation material layer and the first device material layer outside the first opening, to form a first light emitting device corresponding to the first opening and a first encapsulation unit located on a side of the first light emitting device away from the substrate, the first encapsulation unit comprising a first sub-portion, a second sub-portion and a third sub-portion, the first sub-portion covering on the side of the light emitting device away from the substrate, the second sub-portion covering on a side of the first isolation portion facing the isolation opening, the third sub-portion being at least partially located on a side of the second isolation portion facing the substrate and being at least partially attached on the protruding portion, the first sub-portion, the second sub-portion and the third sub-portion of the first encapsulation unit enclosing and forming a gap space, and the gap space of the first encapsulation unit having a communication opening;
preparing a second device material layer and a second encapsulation material layer in sequence, the second device material layer comprising a light emitting unit material layer and a first electrode material layer, the first electrode material layer of the second device material layer being continuously located on a side of the first encapsulation unit away from the substrate and sealing the communication opening of the first encapsulation unit;
etching and removing the second encapsulation material layer outside the second opening by a first etching mode, and then etching and removing the second device material layer by a second etching mode, so as to form a second light emitting device corresponding to the second opening and a second encapsulation unit located on a side of the second light emitting device away from the substrate.

20. The preparation method of claim 19, wherein the first encapsulation unit and the second encapsulation unit each comprise the first sub-portion, the second sub-portion and the third sub-portion, the first sub-portion, the second sub-portion and the third sub-portion of the second encapsulation unit enclose and form a gap space, and the gap space of the second encapsulation unit has a communication opening, the isolation openings further comprise a third opening, wherein after etching and removing the second encapsulation material layer outside the second opening by the first etching mode, and then etching and removing the second device material layer by the second etching mode, the preparation method further comprises:
preparing a third device material layer and a third encapsulation material layer in sequence, the third device material layer comprising a light emitting unit material layer and a first electrode material layer, the first electrode material layer of the third device material layer being continuously located on the side of the first encapsulation unit away from the substrate and sealing the communication opening of the first encapsulation unit, or, the third device material layer being continuously located on a side of the second encapsulation unit away from the substrate and sealing the communication opening of the second encapsulation unit;
etching and removing the third encapsulation material layer outside the third opening by the first etching mode, and then etching and removing the third device material layer by the second etching mode, so as to form a third light emitting device corresponding to the third opening and a third encapsulation unit located on a side of the third light emitting device away from the substrate.
